(19) United States
(12) Patent Application Publication
(10) Pub. No.: US 2026/0157030 A1
(43) Pub. Date: Jun. 4, 2026

(54) Light-Emitting Device

(71) Applicant: Semiconductor Energy Laboratory Co., Ltd., Kanagawa-ken (JP)

(72) Inventors: Hiromitsu Kido, Atsugi (JP); Nobuharu Ohsawa, Zama (JP); Takeyoshi Watabe, Atsugi (JP); Toshiki Sasaki, Kawasaki (JP)

(73) Assignee: Semiconductor Energy Laboratory Co., Ltd., Kanagawa-ken (JP)

(21) Appl. No.: 19/401,821

(22) Filed: Nov. 26, 2025

(30) Foreign Application Priority Data
Nov. 29, 2024 (JP) 2024-207967
May 2, 2025 (JP) 2025-076887

(51) Int. Cl. H10K 50/16; H10K 50/12; H10K 101/00; H10K 101/30

(52) U.S. Cl. CPC H10K 50/166; H10K 50/12; H10K 2101/30; H10K 2101/80

(57) ABSTRACT

A light-emitting device includes a first electrode over an insulating surface, a second electrode facing the first electrode, and an EL layer between the first electrode and the second electrode. One of the first electrode and the second electrode is an anode, and the other is a cathode. The EL layer includes a light-emitting layer, a first layer, and a second layer. The first layer and the second layer are positioned between the light-emitting layer and the cathode. The first layer is positioned between the first electrode and the second layer. The second layer is positioned between the first layer and the second electrode. The light-emitting layer includes a first light-emitting substance and a second light-emitting substance. The first light-emitting substance is a substance capable of converting triplet excitation energy into light emission. The second light-emitting substance is a fluorescent substance. An emission peak wavelength of the first light-emitting substance is shorter than an emission peak wavelength of the second light-emitting substance. A GSP_Slope of the second layer is larger than a GSP_Slope of the first layer.

### BACKGROUND OF THE INVENTION

### 1. Field of the Invention

One embodiment of the present invention relates to an organic compound, an organic semiconductor element, a light-emitting element, an organic EL element, a photodiode, a display module, a lighting module, a display device, a light-emitting apparatus, an electronic appliance, a lighting device, and an electronic device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Therefore, specific examples of the technical field of one embodiment of the present invention disclosed in this specification include a semiconductor device, a display device, a liquid crystal display device, a light-emitting apparatus, a lighting device, a power storage device, a memory device, an image capturing device, a driving method thereof, and a manufacturing method thereof.

### 2. Description of the Related Art

Light-emitting devices (organic EL elements) including organic compounds and utilizing electroluminescence (EL) have been put into more practical use. In the basic structure of such organic EL elements, an organic compound layer containing a light-emitting material (an EL layer) is sandwiched between a pair of electrodes. Carriers are injected by application of a voltage to the device, and recombination energy of the carriers is used to obtain light emission from the light-emitting material.

Such organic EL elements are of self-luminous type and thus have advantages over liquid crystal displays, such as high visibility and no need for backlight when used as pixels of a display, and are particularly suitable for flat panel displays. Displays including such organic EL elements are also highly advantageous in that they can be thin and lightweight. Another feature of such organic EL elements is that they have an extremely fast response speed.

Since a continuous and planar light-emitting layer can be formed in such organic EL elements, planar light emission can be achieved. This feature is difficult to realize with point light sources typified by incandescent lamps and LEDs or linear light sources typified by fluorescent lamps; thus, such organic EL elements also have great potential as planar light sources, which can be used for lighting devices and the like.

Displays or lighting devices including organic EL elements are suitably used in a variety of electronic appliances as described above, and research and development of organic EL elements have progressed for more favorable characteristics.

### REFERENCE

### Non-Patent Document

[Non-Patent Document 1]Y. Noguchi et al., “Spontaneous Orientation Polarization of Polar Molecules and Interface Properties of Organic Electronic Devices”, Journal of the Vacuum Society of Japan, 2015, Vol. 58, No. 3.

### SUMMARY OF THE INVENTION

An object of one embodiment of the present invention is to provide a highly reliable light-emitting device. Another object of one embodiment of the present invention is to provide a light-emitting device having high emission efficiency. Another object of one embodiment of the present invention is to provide any of a highly reliable light-emitting apparatus, a highly reliable electronic appliance, and a highly reliable display device.

Another object of one embodiment of the present invention is to provide a blue-light-emitting device with high reliability. Another object of one embodiment of the present invention is to provide a blue-light-emitting device having high emission efficiency.

Note that the description of these objects does not preclude the existence of other objects. In one embodiment of the present invention, there is no need to achieve all of these objects. Other objects will be apparent from and can be derived from the description of the specification, the drawings, the claims, and the like.

One embodiment of the present invention is a light-emitting device including a first electrode over an insulating surface, a second electrode facing the first electrode, and an EL layer between the first electrode and the second electrode. In the light-emitting device, the EL layer includes a light-emitting layer, a hole-transport layer, a first electron-transport layer, and a second electron-transport layer; the first electron-transport layer is between the first electrode and the second electron-transport layer; the light-emitting layer is between the hole-transport layer and the first and the second electron-transport layers; the light-emitting layer includes a first light-emitting substance and a second light-emitting substance; the first light-emitting substance is a substance capable of converting triplet excitation energy into light emission; the second light-emitting substance is a fluorescent substance; a peak wavelength in an emission spectrum of the first light-emitting substance is shorter than a peak wavelength in an emission spectrum of the second light-emitting substance; and a GSP_Slope (mV/nm) of the second electron-transport layer is larger than a GSP_Slope (mV/nm) of the first electron-transport layer.

Another embodiment of the present invention is a light-emitting device having the above-described structure, in which the second electron-transport layer is positioned between the first electron-transport layer and the second electrode and in which a GSP_Slope (mV/nm) of the light-emitting layer is larger than the GSP_Slope (mV/nm) of the first electron-transport layer.

Another embodiment of the present invention is a light-emitting device having the above-described structure, in which a GSP_Slope (mV/nm) of the light-emitting layer is larger than a GSP_Slope (mV/nm) of the hole-transport layer.

Another embodiment of the present invention is a light-emitting device including a first electrode over an insulating surface, a second electrode facing the first electrode, and an EL layer between the first electrode and the second electrode. In the light-emitting device, the EL layer includes a light-emitting layer, a hole-transport layer, a first electron-transport layer, and a second electron-transport layer; the first electron-transport layer is between the first electrode and the second electron-transport layer; the light-emitting layer is between the hole-transport layer and the first and the second electron-transport layers; the light-emitting layer includes a first light-emitting substance and a second light-emitting substance; the first light-emitting substance is a substance capable of converting triplet excitation energy into light emission; the second light-emitting substance is a fluorescent substance; a peak wavelength in an emission spectrum of the first light-emitting substance is shorter than a peak wavelength in an emission spectrum of the second light-emitting substance; the first electron-transport layer includes a first organic compound; the second electron-transport layer includes a second organic compound; each of the first organic compound and the second organic compound independently has a π-electron deficient heteroaromatic ring; and a GSP_Slope (mV/nm) of a vapor deposited film of the second organic compound is larger than a GSP_Slope (mV/nm) of a vapor deposited film of the first organic compound.

Another embodiment of the present invention is a light-emitting device including a first electrode over an insulating surface, a second electrode facing the first electrode, and an EL layer between the first electrode and the second electrode. In the light-emitting device, the EL layer includes a light-emitting layer, a hole-transport layer, a first electron-transport layer, and a second electron-transport layer; the first electron-transport layer is between the light-emitting layer and the second electron-transport layer; the second electron-transport layer is between the first electron-transport layer and the second electrode; the light-emitting layer is between the hole-transport layer and the first electron-transport layer; the light-emitting layer includes a first light-emitting substance and a second light-emitting substance; the first light-emitting substance is a substance capable of converting triplet excitation energy into light emission; the second light-emitting substance is a fluorescent substance; a peak wavelength in an emission spectrum of the first light-emitting substance is shorter than a peak wavelength in an emission spectrum of the second light-emitting substance; the first electron-transport layer includes a first organic compound; the second electron-transport layer includes a second organic compound and a first substance; each of the first organic compound and the second organic compound independently has a π-electron deficient heteroaromatic ring; and a GSP_Slope (mV/nm) of a vapor deposited film of the second organic compound is larger than a GSP_Slope (mV/nm) of a vapor deposited film of the first organic compound.

Another embodiment of the present invention is a light-emitting device including a first electrode over an insulating surface, a second electrode facing the first electrode, and an EL layer between the first electrode and the second electrode. In the light-emitting device, the EL layer includes a light-emitting layer, a hole-transport layer, a first electron-transport layer, and a second electron-transport layer; the first electron-transport layer is between the light-emitting layer and the second electron-transport layer; the second electron-transport layer is between the first electron-transport layer and the second electrode; the light-emitting layer is between the hole-transport layer and the first electron-transport layer; the light-emitting layer includes a first light-emitting substance and a second light-emitting substance; the first light-emitting substance is a substance capable of converting triplet excitation energy into light emission; the second light-emitting substance is a fluorescent substance; a peak wavelength in an emission spectrum of the first light-emitting substance is shorter than a peak wavelength in an emission spectrum of the second light-emitting substance; the first electron-transport layer includes a first organic compound; the second electron-transport layer includes a second organic compound and a first substance; each of the first organic compound and the second organic compound independently has a π-electron deficient heteroaromatic ring; and in the case where a mixing ratio of the second organic compound to the first substance is x:y in the second electron-transport layer, a GSP_Slope (mV/nm) of a vapor deposited film of the second organic compound is larger than (x+y)x times a GSP_Slope (mV/nm) of a vapor deposited film of the first organic compound.

Another embodiment of the present invention is a light-emitting device having the above-described structure, where y is greater than or equal to x.

Another embodiment of the present invention is a light-emitting device having the above-described structure, in which the second electron-transport layer is between the first electron-transport layer and the second electrode; the light-emitting layer includes a host material; and a GSP_Slope (mV/nm) of a vapor deposited film of the host material is larger than the GSP_Slope (mV/nm) of the vapor deposited film of the first organic compound.

Another embodiment of the present invention is a light-emitting device having the above-described structure, in which the GSP_Slope (mV/nm) of the vapor deposited film of the second organic compound is larger than the GSP_Slope (mV/nm) of the vapor deposited film of the host material.

Another embodiment of the present invention is a light-emitting device having the above-described structure, in which the hole-transport layer includes a third organic compound and a GSP_Slope (mV/nm) of the light-emitting layer is larger than or equal to a GSP_Slope (mV/nm) of a vapor deposited film of the third organic compound.

Another embodiment of the present invention is a light-emitting device having the above-described structure, in which a HOMO level of the host material is lower than a HOMO level of the first light-emitting substance.

Another embodiment of the present invention is a light-emitting device having the above-described structure, in which the HOMO level of the first light-emitting substance is lower than a HOMO level of the second light-emitting substance.

Another embodiment of the present invention is a light-emitting device having the above-described structure, in which the hole-transport layer includes a third organic compound and the GSP_Slope (mV/nm) of the vapor deposited film of the host material is larger than or equal to a GSP_Slope (mV/nm) of a vapor deposited film of the third organic compound.

Another embodiment of the present invention is a light-emitting device having the above-described structure, in which the host material includes a first material and a second material and the first material and the second material are organic compounds that form an exciplex in combination.

Another embodiment of the present invention is a light-emitting device having the above-described structure, in which a HOMO level of the first material and a HOMO level of the second material are lower than a HOMO level of the first light-emitting substance.

Another embodiment of the present invention is a light-emitting device having the above-described structure, in which the HOMO level of the first material and the HOMO level of the second material are lower than a HOMO level of the second light-emitting substance.

Another embodiment of the present invention is a light-emitting device having the above-described structure, in which the first material is an organic compound including a π-electron deficient heteroaromatic ring and the second material is an organic compound including a π-electron rich heteroaromatic ring or an aromatic amine.

Another embodiment of the present invention is a light-emitting device having the above-described structure, in which the first substance is a metal complex.

Another embodiment of the present invention is a light-emitting device having the above-described structure, in which the metal complex is an organic complex containing an alkali metal.

Another embodiment of the present invention is a light-emitting device having the above-described structure, in which the first light-emitting substance is a phosphorescent substance.

Another embodiment of the present invention is a light-emitting device having the above-described structure, in which the second light-emitting substance emits light by application of a voltage between the first electrode and the second electrode.

Another embodiment of the present invention is a light-emitting device having the above-described structure, in which the peak wavelength in the emission spectrum of the second light-emitting substance is greater than or equal to 450 nm and less than or equal to 520 nm.

Another embodiment of the present invention is a light-emitting device having the above-described structure, in which an energy difference between a lowest triplet excitation energy level of the first material and a lowest triplet excitation energy level of the second material is less than or equal to 0.20 eV.

Another embodiment of the present invention is a light-emitting device having the above-described structure, in which a wavelength of an absorption edge on the long wavelength side in an absorption spectrum of the second light-emitting substance is longer than a wavelength of an emission edge on the short wavelength side in the emission spectrum of the first light-emitting substance. Another embodiment of the present invention is a light-emitting device having the above-described structure, in which a wavelength of an absorption edge on the long wavelength side in an absorption spectrum of the second light-emitting substance is longer than a wavelength of an absorption edge on the long wavelength side in an absorption spectrum of the first light-emitting substance. Another embodiment of the present invention is a light-emitting device having the above-described structure, in which a wavelength of an emission edge on the short wavelength side in a phosphorescence spectrum of the first material and a wavelength of an emission edge on the short wavelength side in a phosphorescence spectrum of the second material are each shorter than a wavelength of an emission edge on the short wavelength side in the emission spectrum of the first light-emitting substance.

Another embodiment of the present invention is a light-emitting device having the above-described structure, in which the proportion of the first light-emitting substance is higher than the proportion of the second light-emitting substance in the light-emitting layer.

Another embodiment of the present invention is a light-emitting device having the above-described structure, in which the second light-emitting substance includes a luminophore and a protecting group, where the luminophore is a fused aromatic ring or a fused heteroaromatic ring and the protecting group includes any one of an alkyl group having 1 to 10 carbon atoms, a substituted or unsubstituted cycloalkyl group having 3 to 10 carbon atoms, and a trialkylsilyl group having 3 to 10 carbon atoms. Another embodiment of the present invention is a light-emitting device having the above-described structure, in which the second light-emitting substance includes a luminophore and five or more protecting groups, where the luminophore is a fused aromatic ring or a fused heteroaromatic ring and each of the protecting groups independently includes any one of an alkyl group having 1 to 10 carbon atoms, a substituted or unsubstituted cycloalkyl group having 3 to 10 carbon atoms, and a trialkylsilyl group having 3 to 10 carbon atoms.

Another embodiment of the present invention is a light-emitting device having the above-described structure, in which the first light-emitting substance includes any one of an alkyl group having 3 to 10 carbon atoms, a substituted or unsubstituted cycloalkyl group having 3 to 10 carbon atoms, and a trialkylsilyl group having 3 to 10 carbon atoms.

Note that in one embodiment of the present invention, the GSP_Slope (mV/nm) is represented by ΔV/Δd, where ΔV (mV) is an amount of change in surface potential and Δd (nm) is an amount of change in thickness.

With one embodiment of the present invention, a highly reliable light-emitting device can be provided. With another embodiment of the present invention, a light-emitting device having high emission efficiency can be provided. With one embodiment of the present invention, any of a highly reliable light-emitting apparatus, a highly reliable electronic appliance, and a highly reliable display device can be provided.

With one embodiment of the present invention, a blue-light-emitting device with high reliability can be provided. With another embodiment of the present invention, a blue-light-emitting device having high emission efficiency can be provided.

Note that the description of these effects does not preclude the existence of other effects. One embodiment of the present invention does not necessarily have all of these effects. Other effects will be apparent from and can be derived from the description of the specification, the drawings, the claims, and the like.

### BRIEF DESCRIPTION OF THE DRAWINGS

FIGS. 1A and 1B each illustrate a structure of a light-emitting device of an embodiment.

FIGS. 2A and 2B each illustrate a structure of a light-emitting device of an embodiment.

FIGS. 3A and 3B each illustrate a structure of a light-emitting layer in a light-emitting device of one embodiment of the present invention.

FIGS. 4A to 4D are conceptual diagrams of energy transfer between compounds included in a light-emitting layer of a light-emitting device of one embodiment of the present invention.

FIG. 5 shows capacity-voltage characteristics of a measurement device 1.

FIG. 6 shows current density-voltage characteristics of the measurement device 1.

FIGS. 7A and 7B each illustrate a structure of a light-emitting device of an embodiment.

FIGS. 8A and 8B are a top view and a cross-sectional view, respectively, of a light-emitting apparatus.

FIGS. 9A and 9B are perspective views illustrating a structure example of a display module.

FIGS. 10A and 10B are cross-sectional views each illustrating a structure example of a display device.

FIG. 11 is a perspective view illustrating a structure example of a display device.

FIG. 12 is a cross-sectional view illustrating a structure example of a display device.

FIG. 13 is a cross-sectional view illustrating a structure example of a display device.

FIG. 14 is a cross-sectional view illustrating a structure example of a display device.

FIGS. 15A to 15D illustrate examples of electronic appliances.

FIGS. 16A to 16F illustrate examples of electronic appliances.

FIGS. 17A to 17G illustrate examples of electronic appliances.

FIG. 18 shows absorption spectra and PL spectra of PtON-TBBI and 1,6mmtBuDPhAPrn.

FIG. 19 shows luminance-current density characteristics of light-emitting devices 1-1 and 1-2 and comparative light-emitting devices 1-1, 1-2, and 1-3.

FIG. 20 shows luminance-voltage characteristics of the light-emitting devices 1-1 and 1-2 and the comparative light-emitting devices 1-1, 1-2, and 1-3.

FIG. 21 shows current efficiency-current density characteristics of the light-emitting devices 1-1 and 1-2 and the comparative light-emitting devices 1-1, 1-2, and 1-3.

FIG. 22 shows current density-voltage characteristics of the light-emitting devices 1-1 and 1-2 and the comparative light-emitting devices 1-1, 1-2, and 1-3.

FIG. 23 shows external quantum efficiency-current density characteristics of the light-emitting devices 1-1 and 1-2 and the comparative light-emitting devices 1-1, 1-2, and 1-3.

FIG. 24 shows electroluminescence spectra of the light-emitting devices 1-1 and 1-2 and the comparative light-emitting devices 1-1, 1-2, and 1-3.

FIG. 25 shows time dependence of normalized luminance of the light-emitting devices 1-1 and 1-2 and the comparative light-emitting devices 1-1, 1-2, and 1-3.

FIG. 26 shows the time LT90 of the light-emitting devices 1-1 and 1-2 and the comparative light-emitting devices 1-1, 1-2, and 1-3.

FIG. 27 shows luminance-current density characteristics of a light-emitting device 2 and a comparative light-emitting device 2.

FIG. 28 shows luminance-voltage characteristics of the light-emitting device 2 and the comparative light-emitting device 2.

FIG. 29 shows current efficiency-current density characteristics of the light-emitting device 2 and the comparative light-emitting device 2.

FIG. 30 shows current density-voltage characteristics of the light-emitting device 2 and the comparative light-emitting device 2.

FIG. 31 shows blue index-current density characteristics of the light-emitting device 2 and the comparative light-emitting device 2.

FIG. 32 shows external quantum efficiency-current density characteristics of the light-emitting device 2 and the comparative light-emitting device 2.

FIG. 33 shows electroluminescence spectra of the light-emitting device 2 and the comparative light-emitting device 2.

FIG. 34 is a chromaticity diagram of the light-emitting device 2 and the comparative light-emitting device 2.

FIG. 35 shows time dependence of normalized luminance of the light-emitting device 2 and the comparative light-emitting device 2.

FIG. 36 shows absorption spectra and PL spectra of Pt(mmtBubOcz35dm4ppy-d₆) and 1,6mmtBuDPhAPrn in a solution state.

FIGS. 37A and 37B show the results of the low-temperature PL measurement of SiTrzCz2 and PSiCzCz.

FIG. 38 shows PL spectra of a thin film of SiTrzCz2, a thin film of PSiCzCz, and a thin film of SiTrzCz2 and PSiCzCz mixed at 1:1.

FIG. 39 shows luminance-current density characteristics of a light-emitting device 3 and a comparative light-emitting device 3.

FIG. 40 shows luminance-voltage characteristics of the light-emitting device 3 and the comparative light-emitting device 3.

FIG. 41 shows current efficiency-current density characteristics of the light-emitting device 3 and the comparative light-emitting device 3.

FIG. 42 shows current density-voltage characteristics of the light-emitting device 3 and the comparative light-emitting device 3.

FIG. 43 shows blue index-current density characteristics of the light-emitting device 3 and the comparative light-emitting device 3.

FIG. 44 shows external quantum efficiency-current density characteristics of the light-emitting device 3 and the comparative light-emitting device 3.

FIG. 45 shows electroluminescence spectra of the light-emitting device 3 and the comparative light-emitting device 3.

FIG. 46 shows time dependence of normalized luminance of the light-emitting device 3 and the comparative light-emitting device 3.

FIGS. 47A and 47B show the results of the low-temperature PL measurement of SiTrzCz2-d16 and PSiCzCz-d15.

FIG. 48 shows PL spectra of a thin film of SiTrzCz2-d16, a thin film of PSiCzCz-d15, and a thin film of SiTrzCz2-d16 and PSiCzCz-d15 mixed at 1:1.

FIG. 49 shows the results of transient EL measurement performed on the light-emitting device 1-1, the comparative light-emitting device 1-3, and the light-emitting device 1-3.

### DETAILED DESCRIPTION OF THE INVENTION

Embodiments of the present invention will be described in detail below with reference to the drawings. Note that the present invention is not limited to the following description, and the modes and details of the present invention can be modified in various ways without departing from the spirit and scope of the present invention. Thus, the present invention should not be construed as being limited to the description in the following embodiments.

Note that the position, size, range, or the like of each component illustrated in the drawings and the like is not accurately represented in some cases for easy understanding. Therefore, the disclosed invention is not necessarily limited to the position, size, range, or the like disclosed in the drawings and the like.

Ordinal numbers such as “first” and “second” in this specification and the like are used for convenience and do not limit the number or the order of components. The order of components includes, for example, the order of steps or the stacking order of layers. That is, the ordinal numbers used in Embodiments of this specification are not necessarily the same as the ordinal numbers used in the scope of claims in some cases. In addition, the ordinal numbers used in Examples of this specification are not necessarily the same as the ordinal numbers used in the scope of claims in some cases. Furthermore, the ordinal numbers used in Embodiments of this specification are not necessarily the same as the ordinal numbers used in Examples of this specification in some cases.

In the description of structures of the invention in this specification and the like with reference to the drawings, the same components in different drawings are denoted by the same reference numeral in some cases.

In this specification and the like, the terms “film” and “layer” can be interchanged with each other. For example, the term “conductive layer” can be changed into the term “conductive film” in some cases. For another example, the term “insulating film” can be changed into the term “insulating layer” in some cases.

Note that in this specification and the like, a photoluminescence (PL) spectrum refers to a spectrum obtained by separating light emitted from a sample irradiated with excitation light into different wavelengths and measuring the emission intensity distribution of each wavelength while an excitation wavelength of excitation light is fixed in a fluorometry. Such a spectrum is also referred to as an emission spectrum in some cases. Note that an emission spectrum may include a fluorescence component and a phosphorescence component. In this specification and the like, an emission spectrum including a fluorescence component is particularly referred to as a fluorescence spectrum, and an emission spectrum including a phosphorescence component is particularly referred to as a phosphorescence spectrum in some cases.

### Embodiment 1

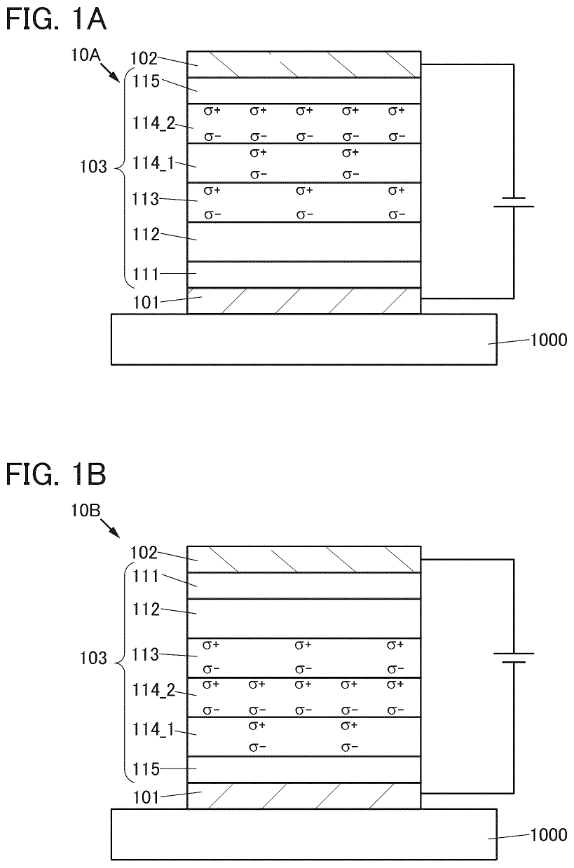

In this embodiment, a light-emitting device 10A and a light-emitting device 10B each of which is a light-emitting device of one embodiment of the present invention are described with reference to FIGS. 1A and 1B.

As illustrated in FIGS. 1A and 1B, the light-emitting devices 10A and 10B are each positioned over a substrate 1000. The light-emitting devices 10A and 10B each include a first electrode 101 positioned over an insulating surface, a second electrode 102 facing the first electrode 101, and an EL layer 103 positioned between the first electrode 101 and the second electrode 102. As illustrated in FIGS. 1A and 1B, the EL layer 103 includes at least a light-emitting layer 113, a first electron-transport layer 114_1, and a second electron-transport layer 114_2. The first electron-transport layer 114_1 and the second electron-transport layer 114_2 have a function of transporting, to the light-emitting layer 113, electrons injected from either one of the first electrode 101 and the second electrode 102 to the EL layer 103. Note that the first electron-transport layer 114_1 is positioned between the first electrode 101 and the second electron-transport layer 114_2.

As illustrated in FIGS. 1A and 1B, in the light-emitting devices 10A and 10B, the first electrode 101 is formed over the substrate 1000. In other words, the first electrode 101 is provided between the second electrode 102 and the substrate 1000. That is, the first electrode 101 is provided earlier than the second electrode 102. Note that in the case where the substrate 1000 is provided with a transistor, the first electrode 101 is electrically connected to the transistor through a wiring. Alternatively, the first electrode 101 is provided over an insulating layer provided with an external connection electrode used as, for example, a terminal to which an FPC or the like is attached. Alternatively, an end portion of the first electrode 101 is covered with an insulating film.

The light-emitting device 10A illustrated in FIG. 1A and the light-emitting device 10B illustrated in FIG. 1B differ in the functions of the first electrode 101 and the second electrode 102. In the light-emitting device 10A, the first electrode 101 and the second electrode 102 function as an anode and a cathode, respectively. In this specification and the like, in some cases, a light-emitting device like the light-emitting device 10A in which the first electrode on the substrate side functions as an anode is referred to as an orderly stacked light-emitting device. Meanwhile, in the light-emitting device 10B, the first electrode 101 and the second electrode 102 function as a cathode and an anode, respectively. In this specification and the like, in some cases, a light-emitting device like the light-emitting device 10B in which the first electrode on the substrate side functions as a cathode is referred to as a reversely stacked light-emitting device.

The orderly stacked light-emitting device 10A emits light when holes injected from the first electrode 101 functioning as an anode into the EL layer 103 and then transported through a hole-transport layer 112 are recombined with, in the light-emitting layer 113, electrons injected from the second electrode 102 functioning as a cathode into the EL layer 103 and then transported through an electron-transport layer 114. Thus, in the light-emitting device 10A, the hole-transport layer 112 is positioned between the first electrode 101 and the light-emitting layer 113, and the electron-transport layer 114 is positioned between the second electrode 102 and the light-emitting layer 113.

The reversely stacked light-emitting device 10B emits light when electrons injected from the first electrode 101 functioning as a cathode into the EL layer 103 and then transported through the electron-transport layer 114 are recombined with, in the light-emitting layer 113, holes injected from the second electrode 102 functioning as an anode into the EL layer 103 and then transported through the hole-transport layer 112. Thus, in the light-emitting device 10B, the hole-transport layer 112 is positioned between the second electrode 102 and the light-emitting layer 113, and the electron-transport layer 114 is positioned between the first electrode 101 and the light-emitting layer 113.

In each of the light-emitting devices 10A and 10B, the electron-transport layer has a stacked-layer structure (a stack of the first electron-transport layer 114_1 and the second electron-transport layer 114_2). The hole-transport layer 112 may have a single-layer structure or a stacked-layer structure. Note that the first electron-transport layer 114_1 and the second electron-transport layer 114_2 are collectively referred to as an electron-transport layer 114 in some cases.

The light-emitting devices 10A and 10B each preferably include the hole-transport layer 112 between the anode and the light-emitting layer 113, and further preferably include a hole-injection layer 111 between the anode and the hole-transport layer 112. The light-emitting devices 10A and 10B each further preferably include an electron-injection layer 115 between the cathode and the electron-transport layer 114.

In the orderly stacked light-emitting device 10A illustrated in FIG. 1A, the hole-injection layer 111, the hole-transport layer 112, the light-emitting layer 113, the electron-transport layer 114, the electron-injection layer 115, and the second electrode 102 functioning as the cathode are stacked in this order over the first electrode 101 functioning as the anode. In the reversely stacked light-emitting device 10B illustrated in FIG. 1B, the electron-injection layer 115, the electron-transport layer 114, the light-emitting layer 113, the hole-transport layer 112, the hole-injection layer 111, and the second electrode 102 functioning as the anode are stacked in this order over the first electrode 101 functioning as the cathode.

Note that the structures of the light-emitting devices 10A and 10B are not limited to those illustrated in FIGS. 1A and 1B. For example, the hole-transport layer may have a two-layer structure, or one or both of the hole-transport layer and the electron-transport layer may have a layered structure of three or more layers.

The present inventors have found that the light-emitting device 10A and the light-emitting device 10B, in each of which the light-emitting layer includes a substance capable of converting triplet excitation energy into light emission and a fluorescent substance and the electron-transport layer has a stacked-layer structure, can have higher reliability when materials used for the layers of the electron-transport layer are selected in consideration of the slope of the giant surface potential (GSP) of the electron-transport layer.

Specifically, a light-emitting device which includes a substance capable of converting triplet excitation energy into light emission and a fluorescent substance in a light-emitting layer and includes an electron-transport layer having a stacked-layer structure of the first electron-transport layer 114_1 formed earlier and the second electron-transport layer 114_2 formed later can have high reliability when the slope of GSP (GSP_Slope (mV/nm)) of the second electron-transport layer 114_2 is larger than the GSP_Slope of the first electron-transport layer 114_1.

Alternatively, a light-emitting device which includes a substance capable of converting triplet excitation energy into light emission and a fluorescent substance in a light-emitting layer and includes an electron-transport layer having a stacked-layer structure of the first electron-transport layer 114_1 formed earlier and the second electron-transport layer 114_2 formed later can have high reliability when the slope of GSP (GSP_Slope (mV/nm)) of a film of an organic compound having a π-electron deficient heteroaromatic ring included in the second electron-transport layer 114_2 is larger than the GSP_Slope of a film of an organic compound having a π-electron deficient heteroaromatic ring included in the first electron-transport layer 114_1.

Note that GSP is a phenomenon due to spontaneous orientation polarization (SOP) caused by deviation in the thickness direction of permanent electric dipole moment orientation of a vapor deposited film.

The surface potential of a vapor deposited film in which GSP is generated changes linearly with increasing thickness without saturation. For example, the surface potential of a vapor deposited film of tris(8-quinolinolato)aluminum (abbreviation: Alq₃) reaches approximately 28 V at a thickness of 560 nm. The electric field strength reaches 5×10⁵ V/cm, which is approximately the same level as electric field strength during driving of a general light-emitting device.

The slope of GSP (GSP_Slope) is represented by ΔV/Δd, where ΔV (mV) is the amount of change in the surface potential of a film whose GSP changes in proportion to the thickness and Δd (nm) is the amount of change in the thickness of the film. Note that the GSP_Slope of a film whose surface potential increases with increasing thickness is positive, and the GSP_Slope of a film whose surface potential decreases with increasing thickness is negative. It can be said that Alq₃ described above is a material with a positive GSP_Slope. The potential of a layer with a positive GSP_Slope is lower on the substrate side, and the potential of a layer with a negative GSP_Slope is higher on the substrate side.

As described above, GSP is a phenomenon due to SOP caused by deviation in the thickness direction of permanent electric dipole moment orientation. That is, the following phenomena can be regarded as occurring: in a layer with a positive GSP_Slope, negative polarization charge is induced on the substrate side and positive polarization charge is induced on the second electrode side; in a similar manner, in a layer with a negative GSP_Slope, positive polarization charge is induced on the substrate side and negative polarization charge is induced on the second electrode side. Thus, GSP originates in such induction of polarization charge. Note that FIGS. 1A and 1B illustrate, with use of symbols σ⁺ and σ⁻, SOP caused by deviation in the thickness direction of permanent electric dipole moment orientation of each vapor deposited layer. Note that the symbol σ⁺ and the symbol σ⁻ represent a positive polarization and a negative polarization, respectively. Among the layers, the layer having a larger number of symbols σ⁺ or σ⁻ in the vicinity of the interface has a larger spontaneous orientation polarization.

Vapor deposited films of most organic compounds have positive GSP_Slopes. In that case, when a second layer is deposited over and in contact with a first layer, the GSP_Slopes of the first layer and the second layer are denoted by the same positive sign; and negative polarization charge can be regarded as being induced on the substrate side and positive polarization charge can be regarded as being induced on the second electrode side in each of the first and second layers. In this case, negative polarization charge of the second layer on the first layer side is canceled out by positive polarization charge of the first layer on the second layer side, and only remaining charge can be regarded as interface charge (fixed charge) at the interface between the first layer and the second layer. Note that virtual charge that can be regarded as interface charge is sometimes referred to as interface charge in this specification and the like.

FIG. 1A illustrates the orderly stacked light-emitting device 10A, and FIG. 1B illustrates the reversely stacked light-emitting device 10B. In the light-emitting device, the electron-transport layer 114 has a stacked-layer structure of the first electron-transport layer 114_1 and the second electron-transport layer 114_2. The light-emitting layer of the light-emitting device includes the substance capable of converting triplet excitation energy into light emission and the fluorescent substance. Note that the second electron-transport layer 114_2 is provided closer to the second electrode 102 than the first electron-transport layer 114_1 is. In the light-emitting device of one embodiment of the present invention, the GSP_Slope of the second electron-transport layer 114_2 is preferably larger than the GSP_Slope of the first electron-transport layer 114_1. Alternatively, in the light-emitting device of one embodiment of the present invention, the GSP_Slope of the vapor deposited film of the second organic compound having a π-electron deficient heteroaromatic ring included in the second electron-transport layer 114_2 is preferably larger than the GSP_Slope of the vapor deposited film of the first organic compound having a π-electron deficient heteroaromatic ring included in the first electron-transport layer 114_1.

In the light-emitting device of one embodiment of the present invention having such a structure, negative interface charge is generated at the interface between the second electron-transport layer 114_2 and the first electron-transport layer 114_1, which inhibits injection of electrons from the second electrode 102 or the electron-injection layer 115 to the second electron-transport layer 114_2 (in the case of orderly stacking in FIG. 1A) or injection of electrons from the first electrode 101 or the electron-injection layer 115 to the first electron-transport layer 114_1 (in the case of reverse stacking in FIG. 1B). This can prevent the light-emitting layer 113 from having excess electrons, thereby preventing the recombination region from shifting to the hole-transport layer 112 side in the light-emitting layer 113 and inhibiting deterioration of the light-emitting layer 113 and the hole-transport layer 112 (or an electron-blocking layer). Accordingly, the light-emitting device of one embodiment of the present invention can have high reliability.

Note that in the orderly stacked light-emitting device 10A in FIG. 1A, the second electron-transport layer 114_2 may include a first substance in addition to the second organic compound. The first substance is preferably a metal complex, in particular, an organic complex containing an alkali metal. As the organic complex containing an alkali metal, 8-quinolinolato-lithium (abbreviation: Liq), 8-quinolinolato-sodium (abbreviation: Naq), 8-quinolinolato-potassium (abbreviation: Kq), a derivative thereof, or the like can be specifically used. When the second electron-transport layer 114_2 includes such a substance, the electron-transport property of the second electron-transport layer 114_2 can be controlled, and moreover the recombination region can be prevented from shifting to the hole-transport layer 112 side in the light-emitting layer 113, whereby the light-emitting device can have improved reliability.

In the case where the mixing ratio (weight ratio) of the second organic compound to the first substance is x:y in the second electron-transport layer 114_2, the GSP_Slope (mV/nm) of the film of the second organic compound is preferably larger than (x+y)/x times the GSP_Slope (mV/nm) of the film of the first organic compound. With this structure, even in the case where the GSP_Slope of the film of the first substance is smaller than that of the film of the second organic compound, the GSP_Slope (mV/nm) of the second electron-transport layer 114_2 becomes larger than that of the first electron-transport layer 114_1, in which case negative interface charge can be generated and the electron-injection property can be lowered, which is preferable. Furthermore, y is preferably larger than x, in which case the proportion of the second organic compound taking part in electron transport is lowered and the electron-transport property is lowered.

In the reversely stacked light-emitting device 10B in FIG. 1B, the first electron-transport layer 114_1 may include the first substance in addition to the first organic compound. The first substance is preferably a metal complex, in particular, an organic complex containing an alkali metal. When the first electron-transport layer 114_1 includes such a substance, the electron-transport property of the first electron-transport layer 114_1 can be controlled, and moreover the recombination region can be prevented from shifting to the hole-transport layer 112 side in the light-emitting layer 113, whereby the light-emitting device can have improved reliability.

Here, as described above, the light-emitting layer 113 preferably includes at least the substance capable of converting triplet excitation energy into light emission and the fluorescent substance and has a structure in which the fluorescent substance emits light. Furthermore, the fluorescent substance preferably emits light using the substance capable of converting triplet excitation energy into light emission as an energy donor. Note that it is preferable that the light-emitting layer 113 further include a host material.

When the light-emitting layer has the above-described structure, the light-emitting device of one embodiment of the present invention can have higher reliability.

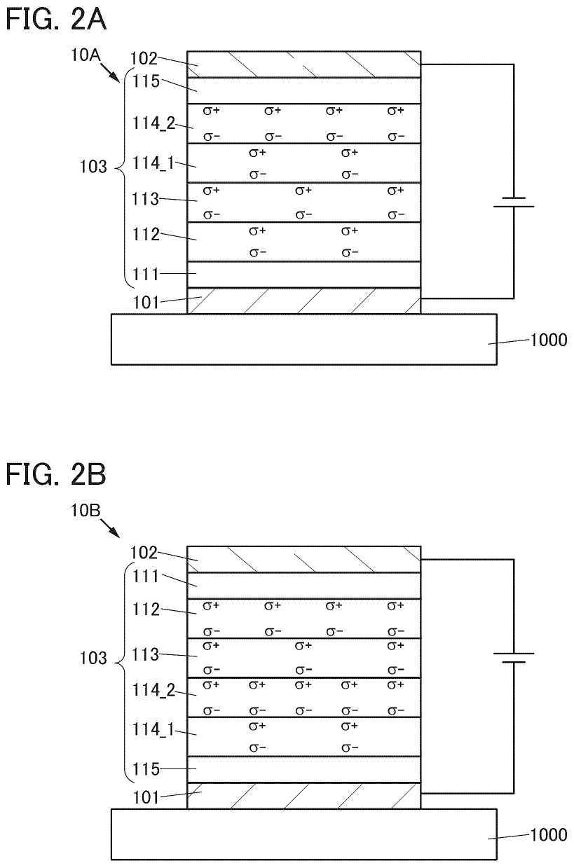

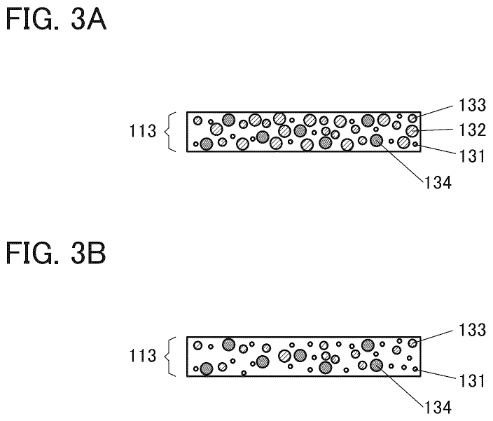

The structure of the light-emitting layer 113 included in the light-emitting device of one embodiment of the present invention will be described in detail below. FIGS. 3A and 3B are each an example of a schematic cross-sectional view of the light-emitting layer 113 illustrated in FIG. 1A to FIG. 2B. The light-emitting layer 113 illustrated in FIG. 3A includes a compound 131, a compound 132, a compound 133, and a compound 134. The light-emitting layer 113 illustrated in FIG. 3B includes the compound 131, the compound 133, and the compound 134. Note that the compound 131 and the compound 132 each serve as the host material. The compound 133 is the substance capable of converting triplet excitation energy into light emission. The compound 134 is the fluorescent substance. Light emission derived from the compound 134 being the fluorescent substance can be obtained from the light-emitting layer 113.

### Structure Example 1 of Light-Emitting Layer

First, a specific structure example 1 of the light-emitting layer 113 is described. In this structure example, the light-emitting layer 113 includes the compounds 131, 132, 133, and 134, as illustrated in FIG. 3A. In this structure example, a case where the compound 133 that is the substance capable of converting triplet excitation energy into light emission is a phosphorescent substance is described. The phosphorescent substance preferably contains a heavy atom such as an Ir, Pt, Os, Ru, or Pd atom, and is preferably an organometallic complex containing any of these heavy atoms.

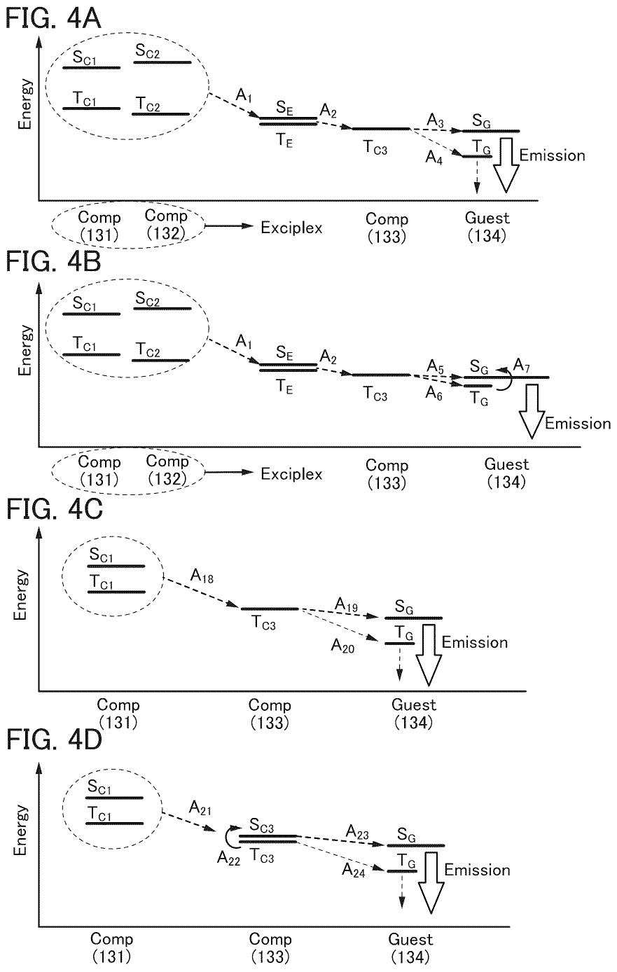

FIG. 4A illustrates an example of the correlation of energy levels in the light-emitting layer 113 in this structure example. The following explains what terms and numerals in FIG. 4A represent.
Comp (131): the compound 131;
Comp (132): the compound 132;
Comp (133): the compound 133;
Guest (134): the compound 134;
S_{C1}: the S₁ level of the compound 131;
T_{C1}: the T₁ level of the compound 131;
S_{C2}: the S₁ level of the compound 132;
T_{C2}: the T₁ level of the compound 132;
S_{E}: the S₁ level of an exciplex;
T_{E}: the T₁ level of the exciplex;
T_{C3}: the T₁ level of the compound 133;
S_{G}: the S₁ level of the compound 134; and
T_{G}: the T₁ level of the compound 134.

It is preferable that a combination of the compounds 131 and 132 each serving as a host material form an exciplex; it is further preferable that one of them be a compound having a hole-transport property and the other be a compound having an electron-transport property. In that case, a donor-acceptor exciplex is easily formed, enabling efficient exciplex formation. When the compounds 131 and 132 are a combination of a compound having a hole-transport property and a compound having an electron-transport property, the carrier balance can be easily controlled depending on the mixing ratio. Specifically, the weight ratio of the compound having a hole-transport property to the compound having an electron-transport property is preferably within a range of 1:9 to 9:1. Since the carrier balance can be easily controlled with the above composition, a carrier recombination region can also be controlled easily.

Specific examples of the compound having a hole-transport property include a compound having one or both of a π-electron rich heteroaromatic ring and an aromatic amine skeleton, and specific examples of the compound having an electron-transport property include a compound having a π-electron deficient heteroaromatic ring.

For the combination of host materials enabling efficient exciplex formation, it is preferable that the HOMO level of one of the compounds 131 and 132 be higher than that of the other compound and the LUMO level of the one of the compounds be higher than that of the other compound. Note that the HOMO level of the compound 131 may be equivalent to that of the compound 132, or the LUMO level of the compound 131 may be equivalent to that of the compound 132.

The LUMO levels and the HOMO levels of the compounds can be derived from the electrochemical characteristics (the reduction potentials and the oxidation potentials) of the compounds that are measured by cyclic voltammetry (CV) or the like.

As illustrated in FIG. 4A, the S₁ level (S_{E}) and the T₁ level (T_{E}) of the exciplex formed by the compounds 131 and 132 are energy levels adjacent to each other (see Route A₁ in FIG. 4A).

Since the excitation energy levels (S_{E} and T_{E}) of the exciplex formed by the compounds 131 and 132 are lower than the S₁ levels (S_{C1} and S_{C2}) of the substances (the compounds 131 and 132) forming the exciplex, an excited state can be formed with lower excitation energy. Accordingly, the driving voltage of the light-emitting device can be reduced.

The correlation of energy levels of the compounds 131 and 132 is not limited to that shown in FIG. 4A. That is, the singlet excitation energy level (S_{C1}) of the compound 131 may be higher or lower than the singlet excitation energy level (S_{C2}) of the compound 132. The triplet excitation energy level (T_{C1}) of the compound 131 may be higher or lower than the triplet excitation energy level (T_{C2}) of the compound 132.

Since the compound 133 is a phosphorescent substance, both the singlet excitation energy and the triplet excitation energy are rapidly transferred from the S₁ level (S_{E}) and the T₁ level (T_{E}) of the exciplex formed by the compounds 131 and 132 to the T₁ level (T_{C3}) of the compound 133 (Route A₂). At this time, T_{E}≥T_{C3} is preferably satisfied. In Route A₂, the exciplex serves as an energy donor and the compound 133 serves as an energy acceptor. Furthermore, in that case, the triplet excitation energy level (T_{C1}) of the compound 131 and the triplet excitation energy level (T_{C2}) of the compound 132 are preferably higher than the T₁ level (T_{C3}) of the compound 133. Specifically, T_{C1}≥T_{C3} and T_{C2}≥T_{C3} are preferably satisfied, where T_{C1} is energy with a wavelength of the line obtained by extrapolating a tangent to the phosphorescence spectrum of the compound 131 at a tail on the short wavelength side, T_{C2} is energy with a wavelength of the line obtained by extrapolating a tangent to the phosphorescence spectrum of the compound 132 at a tail on the short wavelength side, and T_{C3} is energy with a wavelength of the line obtained by extrapolating a tangent to the emission spectrum (the phosphorescence spectrum) of the compound 133 at a tail on the short wavelength side. In other words, it is preferable that the wavelength of the emission edge on the short wavelength side in the phosphorescence spectrum of the compound 131 and the wavelength of the emission edge on the short wavelength side in the phosphorescence spectrum of the compound 132 be shorter than the wavelength of the emission edge on the short wavelength side in the emission spectrum (the phosphorescence spectrum) of the compound 133.

The triplet excitation energy of the compound 133 is converted into the excitation energy of the compound 134 which is the fluorescent substance (Route A₃ and Route A₄). At this time, it is preferable that T_{E}≥T_{C3}≥S_{G} be satisfied as illustrated in FIG. 4A in order to efficiently transfer energy from the compound 133 to the compound 134. Specifically, T_{C3}≥S_{G} is preferably satisfied, where T_{C3} is energy with a wavelength of the line obtained by extrapolating a tangent to the phosphorescence spectrum of the compound 133 at a tail on the short wavelength side, and S_{G} is energy with a wavelength of the absorption edge of the absorption spectrum of the compound 134. In other words, it is preferable that the wavelength of the absorption edge on the long wavelength side in the absorption spectrum of the compound 134 is preferably longer than the wavelength of the emission edge on the short wavelength side in the emission spectrum (the phosphorescence spectrum) of the compound 133. In Routes A₃ and A₄, the compound 133 serves as an energy donor and the compound 134 serves as an energy acceptor. Furthermore, T_{C3}≥S_{G} is preferably satisfied, where T_{C3} is energy with a wavelength of the absorption edge of the absorption spectrum of the compound 133, and S_{G} is energy with a wavelength of the absorption edge of the absorption spectrum of the compound 134. In other words, it is preferable that the wavelength of the absorption edge on the long wavelength side in the absorption spectrum of the compound 134 is preferably longer than the wavelength of the absorption edge on the long wavelength side in the absorption spectrum of the compound 133.

Here, the excitation energy transferred from the triplet excitation energy of the compound 133 to T_{G} (the energy transferred through Route A₄) cannot contribute to light emission because the compound 134 is the fluorescent substance. Thus, energy transfer through Route A₄ causes a decrease in the emission efficiency of the light-emitting device.

In general, as mechanisms of the intermolecular energy transfer, the Forster mechanism (dipole-dipole interaction) and the Dexter mechanism (electron exchange interaction) are known. Since the compound 134 serving as an energy acceptor is the fluorescent substance, energy transfer through Route A₃ occurs by the Forster mechanism and energy transfer through both Route A₃ and Route A₄ occurs by the Dexter mechanism. In order to inhibit energy transfer through Route A₄ that causes non-radiative deactivation, it is effective to inhibit energy transfer by the Dexter mechanism.

The energy transfer by the Dexter mechanism becomes dominant when the distance between the compound serving as an energy donor and the compound serving as an energy acceptor is less than or equal to 1 nm. Therefore, in order to inhibit the energy transfer through Route A₄, it is preferable to make the distance between the energy donor (the compound 133) and the energy acceptor (the compound 134) long enough not to cause the energy transfer by the Dexter mechanism.

As an example of a general method of lengthening the distance between an energy donor and an energy acceptor, lowering the concentration of the energy acceptor in the mixed film can be given. However, lowering the concentration of the energy acceptor inhibits not only energy transfer from the energy donor to the energy acceptor based on the Dexter mechanism but also energy transfer based on the Forster mechanism. This causes problems such as a decrease in emission efficiency or reliability of the light-emitting device occur.

Here, the T₁ level (T_{G}) of the compound 134 serving as an energy acceptor is derived from the luminophore included in the compound 134 in many cases. In other words, the energy transfer through Route A₄ can be inhibited also by lengthening the distance between the luminophore included in the compound 134 and the compound 133.

Thus, it is preferable that the compound 134 being the energy acceptor include a luminophore and a protecting group in part of its structure and that the protecting group have a function of lengthening the distance between the luminophore and another energy donor. In the case where such a compound is used as the compound 134 in the structure, the distance between the compound 133 and the compound 134 can be long even when the concentration of the compound 134 is increased; accordingly, the rate of energy transfer by the Forster mechanism can be increased while energy transfer by the Dexter mechanism is inhibited. In other words, with the use of the compound as the compound 134, triplet excitation energy transfer (Route A₃) from the compound 133 to the S₁ level (S_{G}) of the compound 134 is more likely to occur while triplet excitation energy transfer (Route A₄: energy transfer by the Dexter mechanism) from the compound 133 to the T₁ level (T_{G}) of the compound 134 is less likely to occur. Thus, a decrease in emission efficiency due to energy transfer through Route A₄ can be inhibited while the emission efficiency of the light-emitting device can be improved. Furthermore, the reliability of the light-emitting device can be improved.

As described above, when the distance between the energy donor and the energy acceptor is less than or equal to 1 nm, the Dexter mechanism is dominant, and when the distance is greater than or equal to 1 nm and less than or equal to 10 nm, the Förster mechanism is dominant. For this reason, the protecting group is preferably a bulky substituent ranging from 1 nm to 10 nm from the luminophore of the compound 134.

In this structure example, by increasing the concentration of the compound 134 serving as an energy acceptor, the rate of energy transfer by the Forster mechanism can be increased while the energy transfer by the Dexter mechanism is inhibited. By increasing the rate of energy transfer by the Forster mechanism, the excitation lifetime of the energy acceptor in the light-emitting layer is shortened, leading to an improvement in reliability of the light-emitting device. Specifically, the concentration of the compound 134 in the light-emitting layer 113 is preferably greater than or equal to 2 wt % and less than or equal to 50 wt %, further preferably greater than or equal to 5 wt % and less than or equal to 30 wt %, still further preferably greater than or equal to 5 wt % and less than or equal to 20 wt % of the concentration of the compound 133 serving as an energy donor. Alternatively, the concentration of the compound 134 in the light-emitting layer 113 is preferably greater than or equal to 2 vol % and less than or equal to 50 vol %, further preferably greater than or equal to 5 vol % and less than or equal to 30 vol %, still further preferably greater than or equal to 5 vol % and less than or equal to 20 vol % of the concentration of the compound 133 serving as an energy donor.

### Structure Example 2 of Light-Emitting Layer

Next, a specific structure example 2 of the light-emitting layer 113 is described. In this structure example, the light-emitting layer 113 includes the compounds 131, 132, 133, and 134, as illustrated in FIG. 3A. In this structure example, a case where the compound 133 that is the substance capable of converting triplet excitation energy into light emission is a phosphorescent substance and the compound 134 that is the fluorescent substance is a thermally activated delayed fluorescence (TADF) material is described. Note that a TADF material is a material having a function of converting both singlet excitation energy and triplet excitation energy into light emission. FIG. 4B illustrates an example of the correlation of energy levels in the light-emitting layer 113 in this structure example. Note that the terms, numerals, and Routes A₁ and A₂ in FIG. 4B are the same as those in FIG. 4A and thus the description thereof is omitted.

The triplet excitation energy transferred from the exciplex formed by the compounds 131 and 132 to the compound 133 through Route A₂ illustrated in FIG. 4B is converted into singlet excitation energy of the compound 134 that is the TADF material (Route A₅). At this time, it is preferable that T_{E}≥T_{C3}≥S_{G} be satisfied as illustrated in FIG. 4B in order to efficiently transfer energy from the compound 133 to the compound 134. Specifically, T_{C3}≥S_{G} is preferably satisfied, where T_{C3} is energy with a wavelength of the line obtained by extrapolating a tangent to the phosphorescence spectrum of the compound 133 at a tail on the short wavelength side, and S_{G} is energy with a wavelength of the absorption edge of the absorption spectrum of the compound 134.

In addition to the above routes, there might be a route through which the triplet excitation energy of the compound 133 is transferred to the T₁ level of the compound 134 (Route A₆ in FIG. 4B) in the light-emitting layer 113 in the light-emitting device of this structure example. In this structure example, the compound 134 is a TADF material and thus has a function of converting triplet excitation energy into singlet excitation energy by upconversion. The triplet excitation energy converted through Route A₆ is converted into singlet excitation energy by upconversion (Route A₇ in FIG. 4B), so that thermally activated delayed fluorescence is exhibited. Thus, the compound 134 can efficiently exhibit light emission from the singlet excited state, improving the emission efficiency of the light-emitting device. In Routes A₅ and A₆, the compound 133 serves as an energy donor and the compound 134 serves as an energy acceptor.

Although the light-emitting layer 113 includes four compounds (the compounds 131, 132, 133, and 134) in the structure examples 1 and 2, one embodiment of the present invention is not limited thereto. In the structure examples 3 and 4, the light-emitting layer 113 includes three compounds (the compounds 131, 133, and 134).

### Structure Example 3 of Light-Emitting Layer

A specific structure example 3 of the light-emitting layer 113 is described. In this structure example, the light-emitting layer 113 includes the compounds 131, 133, and 134, as illustrated in FIG. 3B. In this structure example, a case where the compound 133 that is the substance capable of converting triplet excitation energy into light emission is a phosphorescent substance and the compound 134 is a fluorescent substance is described. FIG. 4C illustrates an example of the correlation of energy levels in the light-emitting layer 113 in this structure example. The following explains what terms and numerals in FIG. 4C represent.
Comp (131): the compound 131;
Comp (133): the compound 133;
Guest (134): the compound 134;
S_{C1}: the S₁ level of the compound 131;
T_{C1}: the T₁ level of the compound 131;
T_{C3}: the T₁ level of the compound 133;
T_{G}: the T₁ level of the compound 134; and
S_{G}: the S₁ level of the compound 134.

In this structure example, carrier recombination occurs mainly in the compound 131, whereby singlet excitons and triplet excitons are generated. When a phosphorescent substance having a relation T_{C3}≤T_{C1} is selected as the compound 133, singlet excitation energy and triplet excitation energy generated in the compound 131 can be transferred to the T_{C3} level of the compound 133 (Route A₁₈ in FIG. 4C). Some of the carriers can be recombined also in the compound 133.

The triplet excitation energy of the compound 133 is converted into the excitation energy of the compound 134 which is the fluorescent substance (Route A₁₉ and Route A₂₀). At this time, it is preferable that T_{C3}≥S_{G} be satisfied as illustrated in FIG. 4C in order to efficiently transfer energy from the compound 133 to the compound 134. Specifically, T_{C3}≥S_{G} is preferably satisfied, where T_{C3} is energy with a wavelength of the line obtained by extrapolating a tangent to the phosphorescence spectrum of the compound 133 at a tail on the short wavelength side, and S_{G} is energy with a wavelength of the absorption edge of the absorption spectrum of the compound 134. In Routes A₁₉ and A₂₀, the compound 133 serves as an energy donor and the compound 134 serves as an energy acceptor.

Here, the excitation energy transferred from the triplet excitation energy of the compound 133 to T_{G} (the energy transferred through Route A₂₀) cannot contribute to light emission because the compound 134 is the fluorescent substance. Thus, energy transfer through Route A₂₀ causes a decrease in the emission efficiency of the light-emitting device.

In order to inhibit such energy transfer (Route A₂₀), as described in the structure example 1, it is important that the distance between the compound 133 and the compound 134, that is, the distance between the compound 133 and the luminophore included in the compound 134 be long. Thus, it is preferable that the compound 134 being the energy acceptor include a luminophore and a protecting group in part of its structure and that the protecting group have a function of lengthening the distance between the luminophore and another energy donor. This can inhibit energy transfer through Route A₂₀.

### Structure Example 4 of Light-Emitting Layer

In this structure example, the light-emitting layer 113 in the light-emitting device includes the compounds 131, 134, and 133, as illustrated in FIG. 3B. A case where the compound 133 being the substance capable of converting triplet excitation energy into light emission is a TADF material is described. FIG. 4D illustrates an example of the correlation of energy levels in the light-emitting layer 113 in this structure example. Note that terms and numerals in FIG. 4D are similar to those in FIG. 4C and the other term and numeral are as follows.
S_{C3}: the S₁ level of the compound 133.

In this structure example, carrier recombination occurs mainly in the compound 131, whereby singlet excitons and triplet excitons are generated. When a TADF material having a relation S_{C3}≤S_{C1} and T_{C3}≤T_{C1} is selected as the compound 133, singlet excitation energy and triplet excitation energy generated in the compound 131 can be both transferred to the S_{C3} and T_{C3} levels of the compound 133 (Route A₂₁ in FIG. 4D). Some of the carriers can be recombined also in the compound 133.

Since the compound 133 is the TADF material, the compound 133 has a function of converting triplet excitation energy into singlet excitation energy by upconversion (Route A₂₂ in FIG. 4D). The singlet excitation energy of the compound 133 can be rapidly transferred to the compound 134 (Route A₂₃ in FIG. 4D). At this time, S_{C3}≥S_{G} is preferably satisfied. Specifically, S_{C3}≥S_{G} is preferably satisfied, where S_{C3} is energy with a wavelength of the line obtained by extrapolating a tangent to the fluorescence spectrum of the compound 133 at a tail on the short wavelength side, and S_{G} is energy with a wavelength of the absorption edge of the absorption spectrum of the compound 134.

Therefore, in the light-emitting layer 113 of the light-emitting device in this structure example, triplet excitation energy generated in the compound 133 can be converted into fluorescence of the compound 134 by passing through Routes A₂₁, A₂₂, and A₂₃ in FIG. 4D. In Route A₂₃, the compound 133 serves as an energy donor and the compound 134 serves as an energy acceptor. Note that in the light-emitting layer 113 in the light-emitting device of this structure example, the above routes might compete with a route through which the triplet excitation energy of the compound 133 is transferred to the T₁ level of the compound 134 (Route A₂₄ in FIG. 4D). When such energy transfer (Route A₂₄) occurs, the compound 134 that is the fluorescent substance cannot make the triplet excitation energy contribute to light emission, which reduces the emission efficiency of the light-emitting device.

In order to inhibit such energy transfer (Route A₂₄), as described in the structure example 1, it is important that the distance between the compound 133 and the compound 134, that is, the distance between the compound 133 and the luminophore included in the compound 134 be long.

The compound of one embodiment of the present invention includes a luminophore and a protecting group in part of its structure. In the case where the compound of one embodiment of the present invention serves as the energy acceptor in the light-emitting layer 113, the protecting group has a function of lengthening the distance between another energy donor and the luminophore. Thus, in the case where the compound of one embodiment of the present invention is used as the compound 134 in this structure example, the distance between the compound 133 and the compound 134 can be long even when the concentration of the compound 134 is increased; accordingly, the rate of energy transfer by the Forster mechanism can be increased while energy transfer by the Dexter mechanism can be suppressed. In other words, with the use of the compound of one embodiment of the present invention as the compound 134, triplet excitation energy transfer (Route A₂₃) from the compound 133 to the S₁ level (S_{G}) of the compound 134 can be likely to occur while triplet excitation energy transfer (Route A₂₄: energy transfer by the Dexter mechanism) from the compound 133 to the T₁ level (T_{G}) of the compound 134 can be less likely to occur. Thus, the emission efficiency of the light-emitting device can be improved while a decrease in emission efficiency due to energy transfer through Route A₂₄ can be inhibited. Furthermore, the reliability of the light-emitting device can be improved.

The exciplex formed by the compounds 131 and 132 serves as an energy donor in Route A₂ of the structure examples 1 and 2 of the light-emitting layer, and the compound 133 serves as an energy donor in Route A₃ of the structure example 1 and Routes A₅ and A₆ of the structure example 2 as described above, whereby the light-emitting device can have high efficiency. In the structure example 3 of the light-emitting layer, the compound 131 serves as an energy donor in Route A₁₈ and the compound 133 serves as an energy donor in Route A₁₉, whereby the light-emitting device can have high efficiency. In the structure example 4 of the light-emitting layer, the compound 131 serves as an energy donor in Route A₂₁ and the compound 133 serves as an energy donor in Route A₂₃, whereby the light-emitting device can have high efficiency.

Preferably, deuterium is included in at least any one, further preferably any two, most preferably all of the compounds 131, 132, and 133 each serving as an energy donor in the light-emitting layer. A reason for this is that a compound including deuterium is more stabilized and less likely to deteriorate than a non-deuterated compound because the bond dissociation energy of a bond between carbon and deuterium is higher than the bond dissociation energy of a bond between carbon and protium and thus the bond between carbon and deuterium is stable and difficult to break. When deuterium is included in at least any one, preferably any two, most preferably all of the compounds 131, 132, and 133, the stability of the compound(s) can be increased and deterioration of the energy donor can be inhibited. Thus, it is possible to inhibit a decrease in the efficiency of energy transfer to the compound 134 over time, so that the light-emitting device can be highly reliable.

In the case where the compounds 131, 132, and 133 each include deuterium, they may each be a compound including both hydrogen and deuterium or a compound including deuterium without hydrogen.

In each of the compounds 131 and 132, all hydrogen in the molecule may be replaced by deuterium, but a group or a skeleton where the lowest triplet excitation energy level is localized is preferably deuterated. This enables the compounds 131 and 132 to be obtained at low cost as compared with the case where all hydrogen in the molecule is replaced by deuterium.

In the compound 133, all hydrogen in the molecule may be replaced by deuterium, but a group that is relatively readily cleaved is preferably deuterated. For example, in the case where an organometallic complex including an alkyl group such as a methyl group in at least one of ligands is used as the compound 133, the alkyl group is preferably deuterated. This enables the compound 133 to be obtained at low cost as compared with the case where all hydrogen in the molecule is replaced by deuterium. The reliability of the light-emitting device can thus be increased.

In this specification and the like, “including deuterium” means that the proportion of deuterium in an organic compound including hydrogen and deuterium is much higher than, specifically, more than or equal to 500 times the natural abundance of deuterium, and a “deuterated compound” refers to an organic compound where the proportion of deuterium in an organic compound including hydrogen and deuterium is much higher than, specifically, more than or equal to 500 times the natural abundance of deuterium. The proportion is not a proportion in one molecule, but is an average proportion in a plurality of target compounds in a certain area.

In the above-described structure, the compound 134 serving as an energy acceptor in the light-emitting layer further preferably includes deuterium. Since a compound including deuterium is stabilized and less likely to deteriorate than a non-deuterated compound as described above, the compound 134 can have increased stability by including deuterium. Thus, when the compound 134 includes deuterium, it is possible to inhibit a decrease in the emission efficiency of the light-emitting device over time, so that the light-emitting device can be highly reliable.

In the case where the compound 134 is a fluorescent substance including deuterium, all hydrogen in the molecule may be replaced by deuterium, but the protecting group in the fluorescent substance is preferably deuterated. This enables the compound 134 to be obtained at low cost as compared with the case where all hydrogen in the molecule is replaced by deuterium. The reliability of the light-emitting device can thus be increased. In the case where the protecting group is an alkyl group having 3 to 10 carbon atoms, a substituted or unsubstituted cycloalkyl group having 3 to 10 carbon atoms, or a trialkylsilyl group having 3 to 10 carbon atoms, in particular, deterioration of the group that originates from hydrogen can be inhibited.

When deuterium is included in at least any one, further preferably any two, most preferably all of the compounds 131, 132, and 133 each serving as an energy donor in the light-emitting layer, the reliability of the light-emitting device can be increased. Another reason for this is that the energy transfer efficiency can be improved when the phosphorescence lifetime or delayed fluorescence lifetime of the deuterated compound is longer than the phosphorescence lifetime or delayed fluorescence lifetime of a non-deuterated compound. This is because the intramolecular vibration in the lowest triplet excited state (T₁ state) of the deuterated compound is inhibited more than the intramolecular vibration of a non-deuterated compound and accordingly non-radiative transition from the T₁ state to the more stable state is inhibited.

In the case where the compound 131 and the compound 132 form an exciplex, the energy difference between the T₁ levels of the compounds 131 and 132 is preferably small, in which case uneven distribution of excitation energy in the compounds is less likely to occur and significant deterioration of either one of the compounds can be prevented; accordingly, the reliability of the light-emitting device is increased. Specifically, the energy difference between the T₁ levels of the compounds 131 and 132 is preferably less than or equal to 0.20 eV, further preferably less than or equal to 0.15 eV, still further preferably less than or equal to 0.10 eV.

In particular, in the case of the structure where the compound 131 and the compound 132 form an exciplex and the compound 131 and the compound 132 contain deuterium, i.e., the structure where the reliability is improved in accordance with the extension of the lifetime of a triplet exciton due to inhibition of non-radiative deactivation of triplet excitation energy caused by inhibition of vibration due to deuteration, the effect of deterioration of one of the compounds due to deviation of excitation energy is large. Thus, in the case of the structure where the compound 131 and the compound 132 form an exciplex and the compound 131 and the compound 132 contain deuterium, the energy difference between the T₁ level of the compound 131 and the T₁ level of the compound 132 is preferably less than or equal to 0.20 eV, further preferably less than or equal to 0.15 eV, still further preferably less than or equal to 0.10 eV.

Among organic EL devices, blue-light-emitting devices have been required to have higher efficiency and higher reliability. This is because among highly efficient phosphorescent devices, a blue phosphorescent device has lower reliability than the other phosphorescent devices. The structure of the light-emitting layer 113 in the light-emitting device of this embodiment is expected to enable a blue-light-emitting device with high efficiency and high reliability.

In one embodiment of the present invention, when the fluorescent substance (the compound 134), which is a substance that emits light, is a blue fluorescent substance, in order to efficiently utilize excitation energy obtained from the energy donor, the substance (the compound 133) that serves as an energy donor and can convert triplet excitation energy into light emission is preferably a substance that emits blue light, particularly blue phosphorescent light.

Meanwhile, in the case where a blue phosphorescent substance having a high excitation energy level is used for the light-emitting layer 113, the band gap of the host material is large and it is difficult to control carrier balance; thus, in many cases, a light-emitting device including a blue phosphorescent substance has a structure in which the light-emitting layer 113 easily enters a state of electron excess. In the light-emitting layer 113 containing the substance capable of converting triplet excitation energy into light emission and the fluorescent substance, in the case where the fluorescent substance is a blue-light-emitting substance, the substance capable of converting triplet excitation energy into light emission is preferably a blue phosphorescent substance; thus, it can be said that in such a light-emitting device, the carrier balance of the light-emitting layer 113 is difficult to control and the light-emitting layer 113 easily enters a state of excess electrons.

When the light-emitting layer 113 is in a state of excess electrons, the recombination region tends to be deviated toward the anode side. As a result, the density of excitons generated after the recombination increases on the anode side; accordingly, an interaction between excitons or an interaction between excitons and holes in the electron-blocking layer is likely to occur, so that excitons or holes with extremely high energy are likely to be generated. The high-energy excitons or holes promote deterioration of the light-emitting layer 113 and the hole-transport layer 112 or the electron-blocking layer adjacent to the light-emitting layer 113.

However, in the light-emitting device of one embodiment of the present invention, the GSP_Slope of the second electron-transport layer can be larger than that of the first electron-transport layer and the electron-injection property can be controlled. Thus, the application of this structure to the light-emitting device including the light-emitting layer 113 having the above-described structure can inhibit the light-emitting layer 113 from entering a state of excess electrons, resulting in a significant improvement in reliability.

In the aforementioned light-emitting layer 113 including the substance capable of converting triplet excitation energy into light emission and the fluorescent substance, in the case where the HOMO level of the fluorescent substance is equivalent to or higher than the HOMO level of the substance capable of converting triplet excitation energy into light emission, the light-emitting layer 113 is more likely to enter the state of excess electrons. In the case where the light-emitting layer 113 has such a structure, the light-emitting device of one embodiment of the present invention can have a higher effect of improving reliability.

As examples of the substance capable of converting triplet excitation energy into light emission, a substance that emits thermally activated delayed fluorescence (TADF) and a phosphorescent substance can be given. A phosphorescent substance in this specification and the like is a compound that emits phosphorescent light but does not emit fluorescent light at a temperature higher than or equal to a low temperature (e.g., 77 K) and lower than or equal to room temperature (i.e., higher than or equal to 77 K and lower than or equal to 313 K). The phosphorescent substance preferably contains a metal element with large spin-orbit interaction, specifically, a transition metal element. It is particularly preferable that the phosphorescent substance contain a platinum group element (ruthenium (Ru), rhodium (Rh), palladium (Pd), osmium (Os), iridium (Ir), or platinum (Pt)), especially iridium or platinum, in which case the probability of direct transition between a singlet ground state and a triplet excited state can be increased.

Specific examples of the phosphorescent substance include organic compounds that emit blue phosphorescent light having emission peaks in the wavelength range of 450 nm to 520 nm inclusive. The following are specific examples of organic compounds: (2-{3-[3-(3,5-di-tert-butylphenyl)benzimidazol-1-yl-2-ylidene-κC²]phenoxy-κC²}-9-[5-(methyl-d₃)-4-phenyl-2-pyridinyl-κN]carbazole-2,1-diyl-κC)platinum(II) (abbreviation: Pt(mmtBubOcz5m4ppy-d₃)) represented by Structural Formula (400); (2-{3-[3-(3,5-di-tert-butylphenyl)benzimidazol-1-yl-2-ylidene-κC2]phenoxy-κC²}-9-(4-tert-butyl-2-pyridinyl-κN)-6-(5-cyano-2-methylphenyl)carbazole-2,1-diyl-κC)platinum(II) (abbreviation: Pt(mmtBubOm5CPcztBupy)) represented by Structural Formula (401); {[9-(4-tert-butyl-2-pyridinyl-κN)-[3,9′-bi-9H-carbazole]-2,1-diyl-κC]oxy-9-(4-tert-butyl-2-pyridinyl-κN)carbazole-2,1-diyl-κC}platinum(II) (abbreviation: Pt(cztBucpyOtBucpy)) represented by Structural Formula (402); {[9-(4-tert-butyl-2-pyridinyl-κN)carbazole-2,1-diyl-κC]oxy-9-(4-tert-butyl-2-pyridinyl-κN)carbazole-2,1-diyl-κC}platinum(II) (abbreviation: Pt(tBucpy2O)) represented by Structural Formula (403); {[9-(2-pyridinyl-κN)carbazole-2,1-diyl-κC]oxy-9-(2-pyridinyl-κN)carbazole-2,1-diyl-κC}platinum(II) (abbreviation: PtNON) represented by Structural Formula (404); (2-{4-methyl-3-[3-(3,5-di-tert-butylphenyl)benzimidazol-1-yl-2-ylidene-κC²]phenoxy-κC²}-9-[3,5-di(methyl-d₃)-4-phenyl-2-pyridinyl-κN]carbazole-2,1-diyl-κC)platinum(II) (abbreviation: Pt(Me-mmtBubOcz35dm4ppy-d₆)) represented by Structural Formula (405); {[3-(3,5-di-tert-butylphenyl)-9-(4-tert-butyl-2-pyridinyl-κN)carbazole-2,1-diyl-κC]oxy-9-(4-tert-butyl-2-pyridinyl-κN)carbazole-2,1-diyl-κC}platinum(II) (abbreviation: Pt(mmtBuptBucpyOtBucpy)) represented by Structural Formula (406); (2-{3-[3-(3,5-di-tert-butylphenyl)benzimidazol-1-yl-2-ylidene-κC²]phenoxy-κC²}-9-[3,5-di(methyl-d₃)-4-phenyl-2-pyridinyl-κN]carbazole-2,1-diyl-κC)platinum(II) (abbreviation: Pt(mmtBubOcz35dm4ppy-d₆)) represented by Structural Formula (407); (2-{5-tert-butyl-3-[3-(3,5-di-tert-butylphenyl)benzimidazol-1-yl-2-ylidene-κC²]phenoxy-κC²}-9-[3,5-di(methyl-d₃)-4-phenyl-2-pyridinyl-κN]carbazole-2,1-diyl-κC)platinum(II) (abbreviation: Pt(tBu-mmtBubOcz35dm4ppy-d₆)) represented by Structural Formula (408); {2-(3-{3-[2,6-di(phenyl-d₅)phenyl]benzimidazol-1-yl-2-ylidene-κC²}phenoxy-κC²)-9-[3,5-di(methyl-d₃)-4-phenyl-2-pyridinyl-κN]carbazole-2,1-diyl-κC¹}platinum(II) (abbreviation: Pt(mTPbOcz35dm4ppy-d₆)) represented by Structural Formula (409); and (2-{3-[3-(3,5-di-tert-butylphenyl)benzimidazol-1-yl-2-ylidene-κC²]phenoxy-κC²}-9-[4-tert-butylphenyl-3,5-di(methyl-d₃)-2-pyridinyl-κN]carbazole-2,1-diyl-κC)platinum(II) (abbreviation: Pt(mmtBubOcz35dm4tBuppy-d₆)) represented by Structural Formula (410). Other examples include PtON1 represented by Structural Formula (411), PtON7 represented by Structural Formula (412), PtON1-Me represented by Structural Formula (413), PtON1-tBu represented by Structural Formula (414), PtON1-NMe2 represented by Structural Formula (415), PtON6-tBu represented by Structural Formula (416), PtON7-dtb represented by Structural Formula (417), PtN1N represented by Structural Formula (418), PtN1pyCl represented by Structural Formula (419), PtON7-tBu represented by Structural Formula (420), Pt(ppzOczpy) represented by Structural Formula (421), Pt(ppzOczpy-m) represented by Structural Formula (422), Pt(ppzOczpy-2m) represented by Structural Formula (423), PdN1N represented by Structural Formula (424), PdN1N-dm represented by Structural Formula (425), and PdN6N represented by Structural Formula (426). Among these, the phosphorescent substance serving as an energy donor preferably has any one of an alkyl group having 3 to 10 carbon atoms, a substituted or unsubstituted cycloalkyl group having 3 to 10 carbon atoms, and a trialkylsilyl group having 3 to 10 carbon atoms, in which case the distance between the phosphorescent substance and the fluorescent substance serving as an energy acceptor can be long. In the case where the phosphorescent substance is used, the distance between the phosphorescent substance and the fluorescent substance can be increased even when the concentration of the phosphorescent substance is increased; thus, the rate of energy transfer by the Forster mechanism can be increased while energy transfer by the Dexter mechanism can be suppressed.

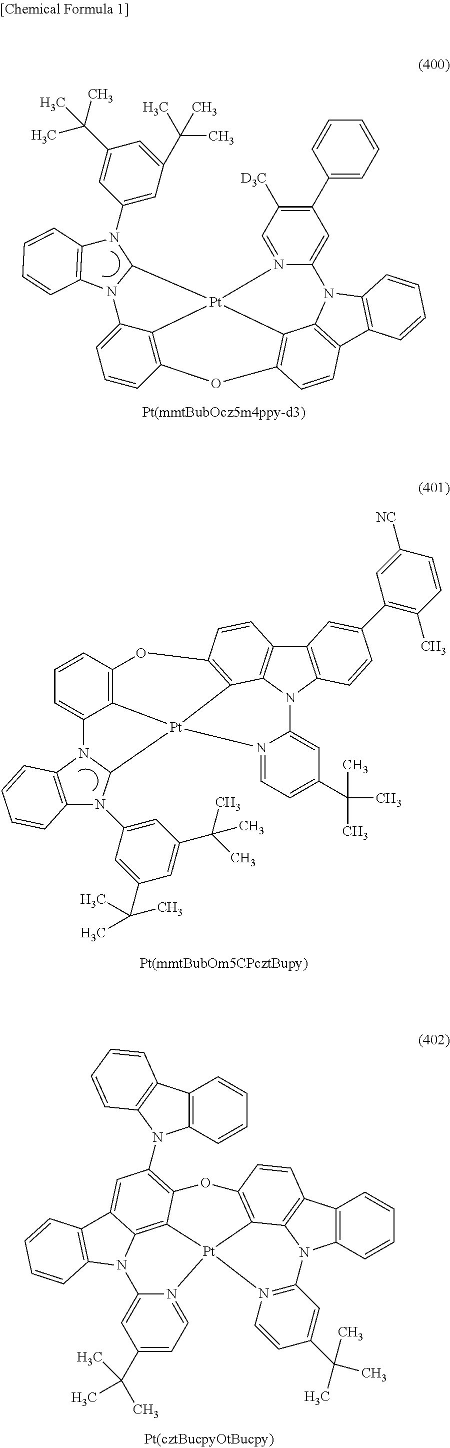

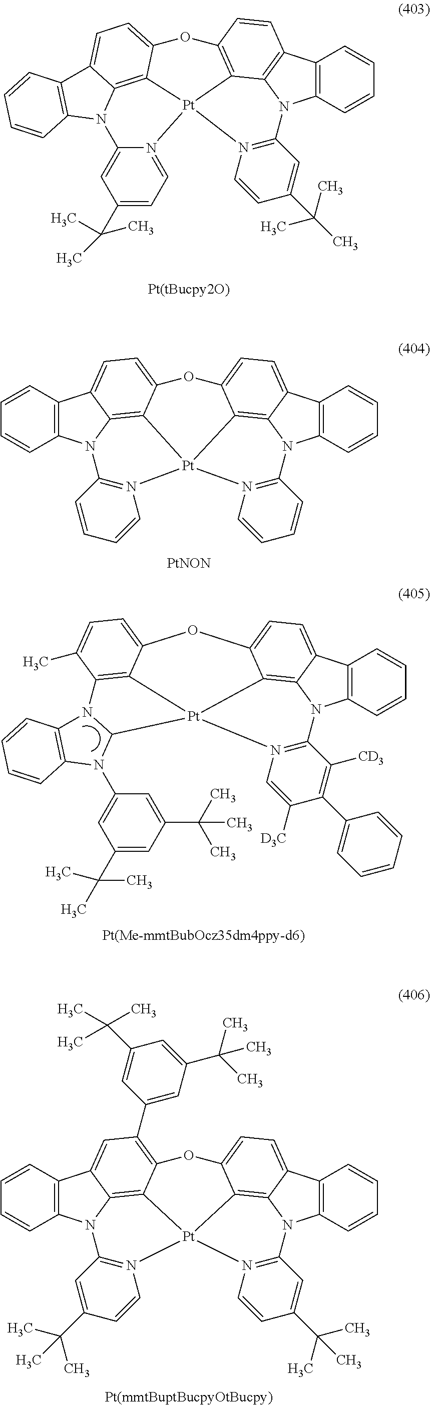

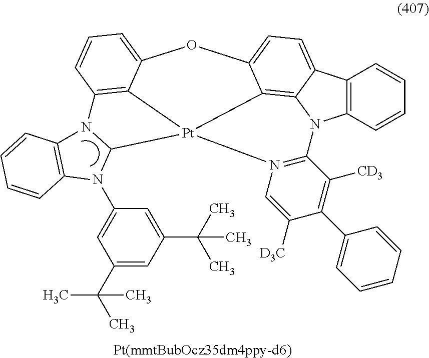

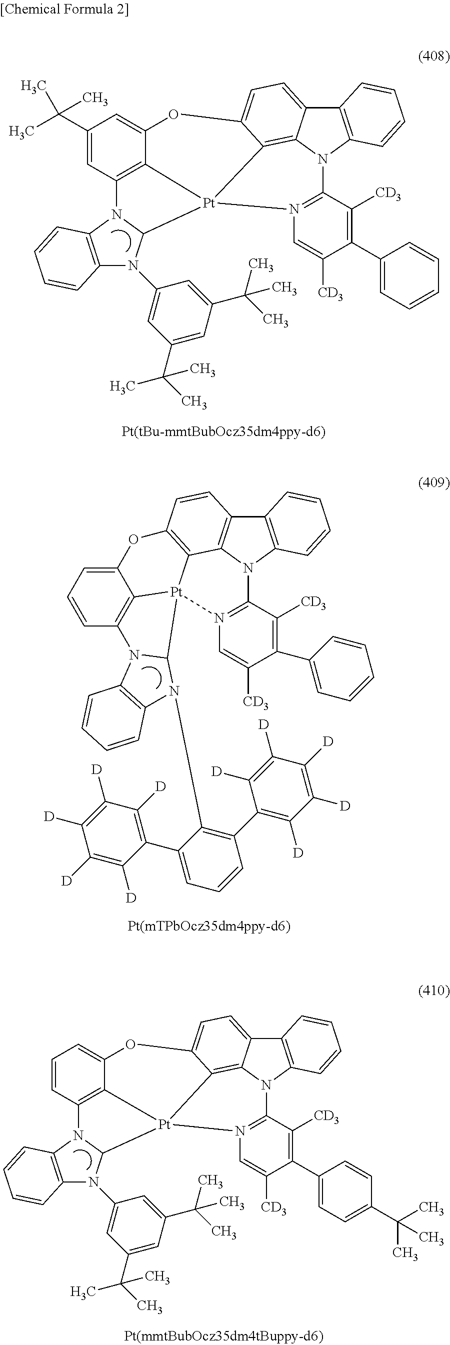

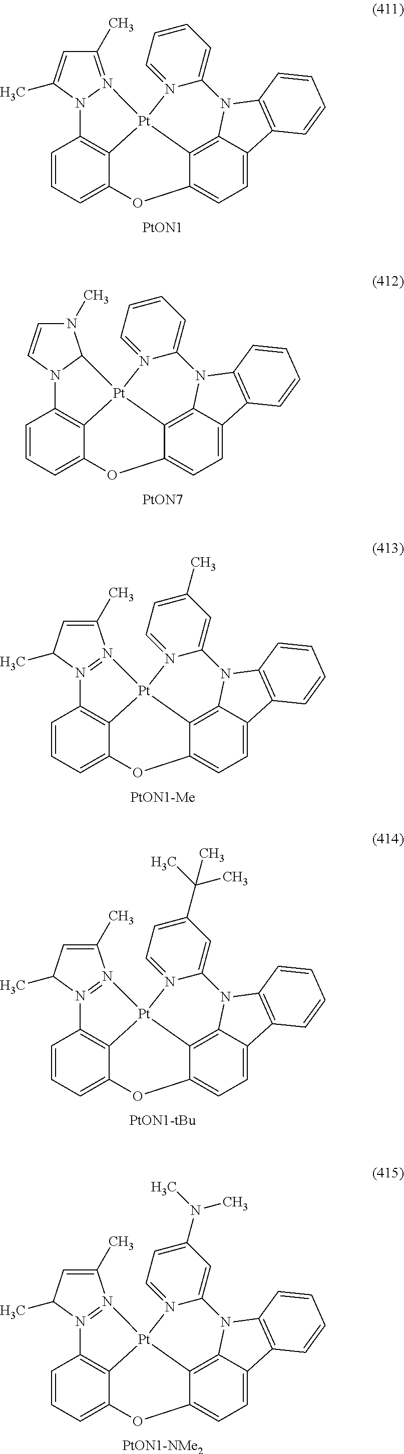

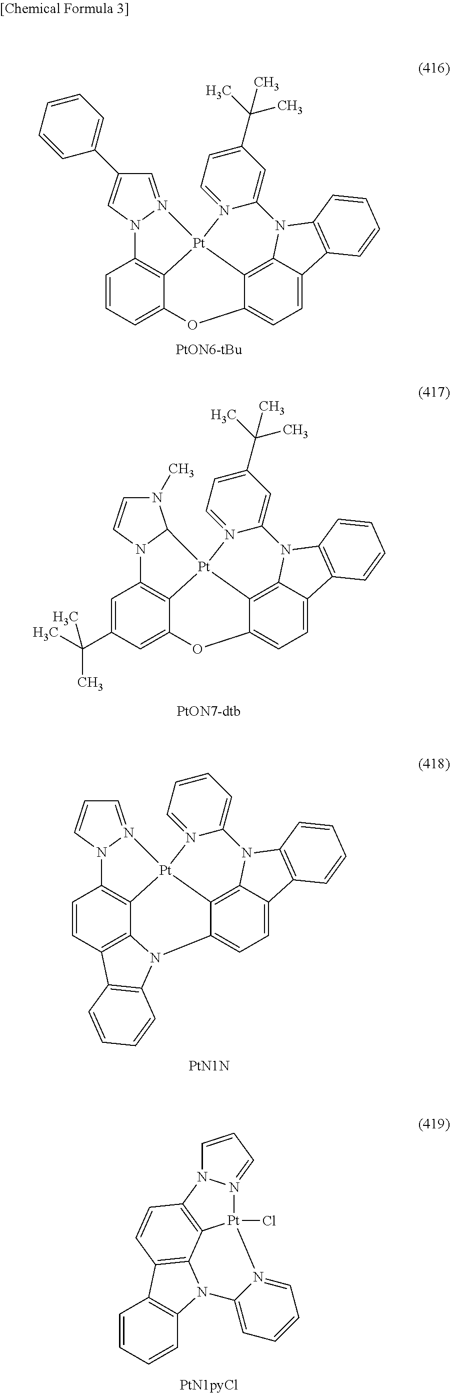

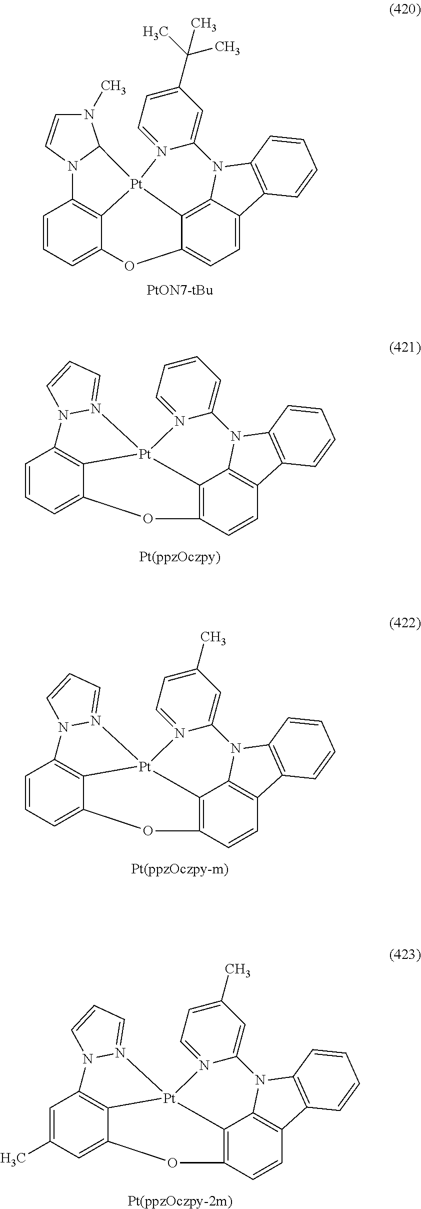

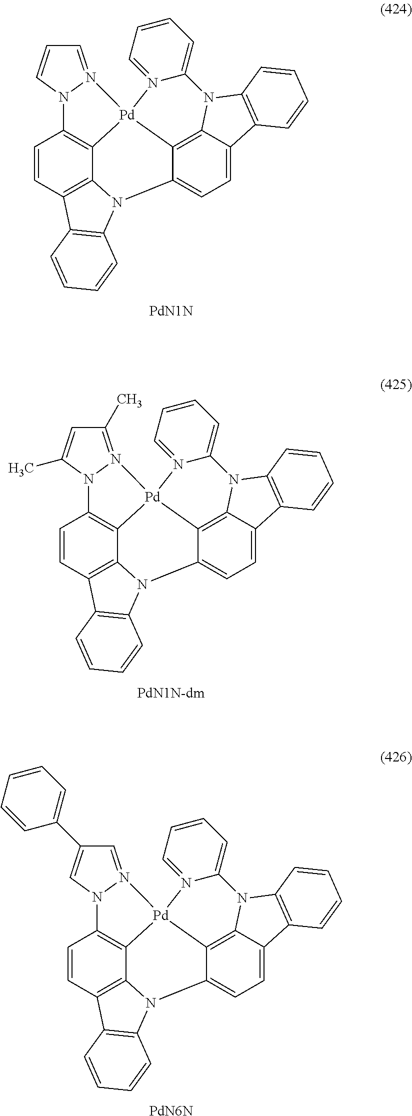

The other examples include organometallic iridium complexes having a 4H-triazole skeleton, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), and tris(5-methyl-3,4-diphenyl-4H-1,2,4-triazolato)iridium(Ill) (abbreviation: [Ir(Mptz)₃]); organometallic iridium complexes having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(Ill) (abbreviation: [Ir(Prptz1-Me)₃]); organometallic iridium complexes having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2f]phenanthridinato]iridium(III) (abbreviation: [Ir(dmpimpt-Me)₃]), and tris(2-(1-[2,6-bis(1-methylethyl)phenyl]-1H-imidazol-2-yl-κN³)-4-cyanophenyl-κC)iridium(III) (abbreviation: CNImIr); organometallic complexes having a benzimizazolidene skeleton, such as tris[(6-tert-butyl-3-phenyl-2H-imidazo[4,5-b]pyrazin-1-yl-κC²)phenyl-κC]iridium(III) (abbreviation: [Ir(cb)₃]); organometallic iridium complexes in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C²]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIracac); and platinum complexes such as (2-{3-[3-(3,5-di-tert-butylphenyl)benzimidazol-1-yl-2-ylidene-κC²]phenoxy-κC²}-9-(4-tert-butyl-2-pyridinyl-κN)carbazole-2,1-diyl-κC¹)platinum(II) (abbreviation: PtON-TBBI).

Alternatively, any of phosphorescent substances described in Embodiment 2 can be used as the phosphorescent substance.

Another example of the substance capable of converting triplet excitation energy into light emission is a TADF material. Note that a TADF material is a material having a small energy difference between the S₁ level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. An exciplex whose excited state is formed of two kinds of substances has an extremely small energy difference between the S₁ level and the T₁ level and functions as a TADF material capable of converting triplet excitation energy into singlet excitation energy.

A phosphorescence spectrum observed at a low temperature (e.g., 10 K) is used for an index of the T₁ level. When the level of energy with a wavelength of the line obtained by extrapolating a tangent to the fluorescence spectrum at a tail on the short wavelength side is the S₁ level and the level of energy with a wavelength of the line obtained by extrapolating a tangent to the phosphorescence spectrum at a tail on the short wavelength side is the T₁ level, the energy difference between the S₁ level and the T₁ level of the TADF material is preferably less than or equal to 0.2 eV.

Specific examples of the TADF material include 2-(biphenyl-4-yl)-4,6-bis(12-phenylindolo[2,3-a]carbazol-11-yl)-1,3,5-triazine (abbreviation: PIC-TRZ), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), and 10-phenyl-10H,10′H-spiro[acridin-9,9′-anthracen]-10′-one (abbreviation: ACRSA). The heterocyclic compound is preferable because of its high electron-transport and hole-transport properties due to the π-electron rich heteroaromatic ring and the π-electron deficient heteroaromatic ring contained therein. Among skeletons having the π-electron deficient heteroaromatic ring, a diazine skeleton (a pyrimidine skeleton, a pyrazine skeleton, or a pyridazine skeleton) and a triazine skeleton are particularly preferable because of their high stability and high reliability. Among skeletons having the π-electron rich heteroaromatic ring, an acridine skeleton, a phenoxazine skeleton, a thiophene skeleton, a furan skeleton, and a pyrrole skeleton have high stability and high reliability; therefore, one or more of these skeletons are preferably included. As the pyrrole skeleton, an indole skeleton, a carbazole skeleton, or a 3-(9-phenyl-9H-carbazol-3-yl)-9H-carbazole skeleton is particularly preferable. It is particularly preferable that the π-electron rich heteroaromatic ring be directly bonded to the π-electron deficient heteroaromatic ring, in which case the donor property of the π-electron rich heteroaromatic ring and the acceptor property of the π-electron deficient heteroaromatic ring are both increased and the energy difference between the singlet excitation energy level and the triplet excitation energy level becomes small. The TADF material serving as an energy donor preferably has any one of an alkyl group having 3 to 10 carbon atoms, a substituted or unsubstituted cycloalkyl group having 3 to 10 carbon atoms, and a trialkylsilyl group having 3 to 10 carbon atoms, in which case the distance between the phosphorescent substance and the fluorescent substance serving as an energy acceptor can be long. In the case where the TADF material is used, the distance between the phosphorescent substance and the fluorescent substance can be increased even when the concentration of the TADF material is increased; thus, the rate of energy transfer by the Forster mechanism can be increased while energy transfer by the Dexter mechanism can be suppressed.

A fused heteroaromatic compound containing nitrogen and boron, especially a compound having a diaza-boranaphtho-anthracene skeleton, exhibits a narrow emission spectrum, emits blue light with high color purity and can thus is preferably used as the TADF material. Specific examples of the compound having a diaza-boranaphtho-anthracene skeleton include 5,9-diphenyl-5H,9H-[1,4]benzazaborino[2,3,4-kl]phenazaborine (abbreviation: DABNA-1), 9-(diphenyl-3-yl)-N,N,5,11-tetraphenyl-5,9-dihydro-5,9-diaza-13b-boranaphtho[3,2,1-de]anthracene-3-amine (abbreviation: DABNA-2), 2,12-di(tert-butyl)-5,9-di(4-tert-butylphenyl)-N,N-diphenyl-5H,9H-[1,4]benzazaborino[2,3,4-kl]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-kl][1,4]benzazaborino[4′,3′,2′:4,5][1,4]benzazaborino[3,2-b]phenazaborine-7,13-diamine (abbreviation: v-DABNA), and 2-(4-tert-butylphenyl)benz[5,6]indolo[3,2,1-jk]benzo[b]carbazole (abbreviation: tBuPBibc).

Besides the above compounds, a compound having an indole skeleton, such as 9,10,11-tris[3,6-bis(1,1-dimethylethyl)-9H-carbazolyl-9-yl]-2,5,15,18-tetrakis(1,1-dimethylethyl)indolo[3,2,1-de]indolo[3′,2′,1′: 8,1][1,4]benzazaborino[2,3,4-k]phenazaborine (abbreviation: BBCz-G) or 9,11-bis[3,6-bis(1,1-dimethylethyl)-9H-carbazolyl-9-yl]-2,5,15,18-tetrakis(1,1-dimethylethyl)indolo[3,2,1-de]indolo[3′,2′,1′: 8,1][1,4]benzazaborino[2,3,4-kl]phenazaborine (abbreviation: BBCz-Y) can be suitably used as the TADF material.

The TADF material has a small energy difference between the triplet excitation energy level and the singlet excitation energy level and a function of converting energy from a triplet excited state to a singlet excited state by reverse intersystem crossing. Thus, a TADF material enables up-conversion (reverse intersystem crossing) from a triplet excited state to a singlet excited state using a little thermal energy and efficiently exhibit light emission (fluorescence) from the singlet excited state. The thermally activated delayed fluorescence is efficiently obtained under the condition where the difference in energy between the triplet excitation energy level and the singlet excitation energy level is preferably larger than 0 eV and smaller than or equal to 0.20 eV, further preferably larger than 0 eV and smaller than or equal to 0.10 eV.

The TADF material is not limited to the above-described materials, and any of TADF materials listed in Embodiment 2 can be used.

An example of the substance capable of converting triplet excitation energy into light emission is a nano-structure of a transition metal compound having a perovskite structure. In particular, a nano-structure of a metal halide perovskite material is preferable. The nano-structure is preferably a nanoparticle or a nanorod.

It is preferable that the fluorescent substance be a compound including a luminophore and a protecting group in part of its structure and that the protecting group have a function of lengthening the distance between the luminophore and another energy donor.

The luminophore refers to an atomic group (skeleton) that causes light emission in a fluorescent material. The luminophore generally has a π bond and preferably includes an aromatic ring and further preferably includes a fused aromatic ring or a fused heteroaromatic ring. As another embodiment, the luminophore can be regarded as an atomic group (skeleton) including an aromatic ring having a transition dipole vector on a ring plane. In the case where one fluorescent material has a plurality of fused aromatic rings or fused heteroaromatic rings, a skeleton having the lowest S₁ level among the plurality of fused aromatic rings or fused heteroaromatic rings may be considered as a luminophore of the fluorescent material. In other cases, a skeleton having an absorption edge on the longest wavelength side among the plurality of fused aromatic rings or fused heteroaromatic rings may be considered as the luminophore of the fluorescent material. The luminophore of the fluorescent material can be presumed from the shapes of the emission spectra of the plurality of fused aromatic rings or fused heteroaromatic rings in some cases.

Examples of such a luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent material having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferred because of its high fluorescence quantum yield.

A substituent used as the protecting group needs to have a triplet excitation energy level higher than the T₁ level of each of the luminophore and the host material. Thus, a saturated hydrocarbon group is preferably used. That is because a substituent having no π bond has a high triplet excitation energy level. In addition, a substituent having no π bond has a poor function of transporting carriers (electrons or holes). Thus, a saturated hydrocarbon group can make the luminophore and the host material away from each other with substantially no influence on the excited state or the carrier-transport property of the host material. In an organic compound including a substituent having no π bond and a substituent having a π-conjugated system, frontier orbitals (the highest occupied molecular orbital (HOMO) and the lowest unoccupied molecular orbital (LUMO)) are present on the side of the substituent having a π-conjugated system in many cases; in particular, the luminophore tends to have frontier orbitals. As described later, the overlap of the HOMOs of the energy donor and the energy acceptor and the overlap of the LUMOs of the energy donor and the energy acceptor are important for energy transfer by the Dexter mechanism. Therefore, the use of saturated hydrocarbon groups as the protecting groups enables a large distance between the frontier orbitals of the host material, which serves as an energy donor, and the frontier orbitals of the guest material, which serves as an energy acceptor, and thus, energy transfer by the Dexter mechanism can be inhibited.

A specific example of the protecting group is an alkyl group having 1 to 10 carbon atoms. In addition, the protecting group is preferably a bulky substituent because it needs to make the luminophore and the host material away from each other. Thus, an alkyl group having 3 to 10 carbon atoms, a substituted or unsubstituted cycloalkyl group having 3 to 10 carbon atoms, or a trialkylsilyl group having 3 to 10 carbon atoms can be suitably used. In particular, the alkyl group is preferably a bulky branched-chain alkyl group. Furthermore, the substituent particularly preferably has quaternary carbon to be bulky.

As described above, it is further preferable that the protecting group be deuterated. In the case where the protecting group includes deuterium, specific examples of the protecting group that can be suitably used include an alkyl group having 3 to 10 carbon atoms that includes deuterium, a substituted or unsubstituted cycloalkyl group having 3 to 10 carbon atoms that includes deuterium, and a trialkylsilyl group having 3 to 10 carbon atoms that includes deuterium.

Five or more protecting groups are preferably included for one luminophore. With such a structure, the luminophore can be entirely covered with the protecting groups, so that the distance between the host material and the luminophore can be appropriately adjusted. It is preferable that the protecting groups be not directly bonded to the luminophore. For example, the protecting groups may each be bonded to the luminophore via a substituent with a valence of 2 or more, such as an arylene group or an amino group. Bonding of each of the protecting groups to the luminophore via the substituent can effectively make the luminophore away from the host material. Thus, in the case where the protecting groups are not directly bonded to the luminophore, four or more protecting groups for one luminophore help effectively inhibit energy transfer by the Dexter mechanism.

Specific examples of the fluorescent substance including a luminophore and a protecting group having a function of lengthening the distance between the luminophore and another energy donor include N,N′-(2-phenylanthracene-9,10-diyl)-N,N,N′,N′-tetrakis(3,5-di-tert-butylphenyl)diamine (abbreviation: 2Ph-mmtBuDPhA2Anth), 2,2′,6,6′-tetrakis(3,5-di-tert-butylphenyl)-N,N,N′,N′-tetrakis(3,5-di-tert-butylphenyl)-[9,9′-bianthracene]-10,10′-diamine (abbreviation: 22′66′mmtBuPh-mmtBuDPhA2BANT), N,N′-bis[3,5-bis(1-adamantyl)phenyl]-N,N′-bis(3,5-di-tert-butylphenyl)-2-phenylanthracene-9,10-diamine (abbreviation: 2Ph-mmAdtBuDPhA2Anth-03), N,N′-bis(3,5-di-tert-butylphenyl)-N,N′-bis(3,5-bis[4-(1-adamantyl)phenyl]phenyl)-2,6-diphenylanthracene-9,10-diamine (abbreviation: 2,6Ph-mmAdPtBuDPhA2Anth), N,N′-bis(3,5-di-tert-butylphenyl)-N,N′-bis(3,5-bis[4-(1-adamantyl)phenyl]phenyl)-2-phenylanthracene-9,10-diamine (abbreviation: 2Ph-mmAdPtBuDPhA2Anth), N,N′-bis(3,5-bis(tricyclo[5.2.1.0^{2,6}]decan-8-yl)phenyl)-N,N′-bis(3,5-di-tert-butylphenyl)-2-phenylanthracene-9,10-diamine (abbreviation: 2Ph-mmTCDtBuDPhA2Anth), N,N′-bis(3,5-bis(2-bicyclo[2.2.1]heptyl)phenyl)-N,N′-bis(3,5-di-tert-butylphenyl)-2-phenylanthracene-9,10-diamine (abbreviation: 2Ph-mmnbtBuDPhA2Anth), N,N′-bis[3,5-bis(2-adamantyl)phenyl]-N,N′-bis[3,5-bis(3,5-di-tert-butylphenyl)phenyl]-2-phenylanthracene-9,10-diamine (abbreviation: 2Ph-mmAdtBuDPhA2Anth-02), N,N′-bis[3,5-bis(2-adamantyl)phenyl]-N,N′-bis(3,5-di-tert-butylphenyl)-2-phenylanthracene-9,10-diamine (abbreviation: 2Ph-mmAdtBuDPhA2Anth), N,N′-(2-trimethylsilylanthracene-9,10-diyl)-N,N,N′,N′-tetrakis(3,5-di-tert-butylphenyl)diamine (abbreviation: 2TMS-mmtBuDPhA2Anth), N,N′-(pyrene-1,6-diyl)bis[N-(2-methylphenyl)-6-cyclohexylbenzo[b]naphtho[1,2-d]furan-8-amine](abbreviation: 1,6oMechBnfAPrn), N,N′-(pyrene-1,6-diyl)bis(N-phenyl-6-trimethylsilylbenzo[b]naphtho[1,2-d]furan-8-amine) (abbreviation: 1,6TMSBnfAPrn), N,N′-(3,8-dicyclohexylpyrene-1,6-diyl)bis[N-phenyl-(6-cyclohexylbenzo[b]naphtho[1,2-d]furan)-8-amine](abbreviation: ch-1,6chBnfAPrn), N,N′-bis[9-(3,5-di-tert-butylphenyl)-9H-carbazol-2-yl]-N,N′-diphenyl-naphtho[2,3-b;6,10-b′]bisbenzofuran-3,10-diamine (abbreviation: 3,10mmtBuPCA2Nbf(IV)-02), and N,N,N′,N′-tetrakis(3,5-di-tert-butylphenyl)pyrene-1,6-diamine (abbreviation: 1,6mmtBuDPhAPrn).

The fluorescent substance is not limited to the above-described substances, and any of fluorescent substances listed in Embodiment 2 can be used.

In the case where the orderly stacked light-emitting device of one embodiment of the present invention includes the hole-transport layer 112 as illustrated in FIG. 2A, the GSP_Slope (mV/nm) of the light-emitting layer 113 is preferably larger than the GSP_Slope (mV/nm) of the hole-transport layer 112 or the GSP_Slope (mV/nm) of a vapor deposited film of a third organic compound having a π-electron rich heteroaromatic ring or an aromatic amine included in the hole-transport layer 112. Alternatively, the GSP_Slope (mV/nm) of a vapor deposited film of the host material is preferably larger than the GSP_Slope (mV/nm) of the vapor deposited film of the third organic compound having a π-electron rich heteroaromatic ring or an aromatic amine included in the hole-transport layer 112.

Furthermore, in the case where the reversely stacked light-emitting device of one embodiment of the present invention includes the hole-transport layer 112 as illustrated in FIG. 2B, the GSP_Slope (mV/nm) of the light-emitting layer 113 is preferably smaller than the GSP_Slope (mV/nm) of the hole-transport layer 112 or the GSP_Slope (mV/nm) of the vapor deposited film of the third organic compound having a π-electron rich heteroaromatic ring or an aromatic amine included in the hole-transport layer 112. Alternatively, the GSP_Slope (mV/nm) of the vapor deposited film of the host material is preferably smaller than the GSP_Slope (mV/nm) of the vapor deposited film of the third organic compound having a π-electron rich heteroaromatic ring or an aromatic amine included in the hole-transport layer 112.

In the light-emitting device of one embodiment of the present invention having this structure, the effect of negative interface charge derived from a difference in GSP_Slope between two adjacent layers promotes hole injection, which effectively causes hole injection to the light-emitting layer, improves carrier balance, and extends the recombination region. Thus, the light-emitting layer 113 and the hole-transport layer 112 can be inhibited from deteriorating.

As illustrated in FIG. 1A, in the orderly stacked light-emitting device of one embodiment of the present invention, the GSP_Slope (mV/nm) of the light-emitting layer 113 is preferably larger than the GSP_Slope (mV/nm) of the first electron-transport layer 114_1. Alternatively, the GSP_Slope (mV/nm) of the vapor deposited film of the host material is preferably larger than the GSP_Slope (mV/nm) of the vapor deposited film of the first organic compound.

As illustrated in FIG. 1B, in the reversely stacked light-emitting device of one embodiment of the present invention, the GSP_Slope (mV/nm) of the light-emitting layer 113 is preferably smaller than the GSP_Slope (mV/nm) of the second electron-transport layer 1142. Alternatively, the GSP_Slope (mV/nm) of the vapor deposited film of the host material is preferably smaller than the GSP_Slope (mV/nm) of the vapor deposited film of the second organic compound.

In the light-emitting device of one embodiment of the present invention having this structure, electron injection from the second electron-transport layer 1142 to the first electron-transport layer 114_1 is promoted owing to the effect of positive interface charge derived from the difference in GSP_Slope between the two adjacent layers. Thus, the light-emitting device of one embodiment of the present invention does not cause a significant increase in driving voltage even when electron injection from the first electrode 101 or the electron-injection layer 115 to the second electron-transport layer 1142 is inhibited, so that the light-emitting device can have favorable characteristics.

As illustrated in FIG. 1A, in the orderly stacked light-emitting device of one embodiment of the present invention, the GSP_Slope (mV/nm) of the second electron-transport layer 1142 is preferably larger than the GSP_Slope (mV/nm) of the light-emitting layer 113. Alternatively, the GSP_Slope (mV/nm) of the vapor deposited film of the second organic compound is preferably larger than the GSP_Slope (mV/nm) of the vapor deposited film of the host material.

As illustrated in FIG. 1B, in the reversely stacked light-emitting device of one embodiment of the present invention, the GSP_Slope (mV/nm) of the first electron-transport layer 114_1 is preferably smaller than the GSP_Slope (mV/nm) of the light-emitting layer 113. Alternatively, the GSP_Slope (mV/nm) of the vapor deposited film of the first organic compound is preferably smaller than the GSP_Slope (mV/nm) of the vapor deposited film of the host material.

In the light-emitting device of one embodiment of the present invention having this structure, the charge at the interface between the first electron-transport layer 114_1 and the second electron-transport layer 114_2 has a negative value which is smaller than the value of the charge at the interface between the light-emitting layer 113 and the first electron-transport layer 1141. This effect inhibits electron injection to the light-emitting layer and promotes hole injection to the light-emitting layer; thus, the carrier balance is improved and the recombination region can be extended, so that deterioration of the light-emitting layer 113 and the hole-transport layer 112 can be inhibited.

Note that in the case where the light-emitting layer 113 includes a host material, the host material preferably contains a first material and a second material. When the host material is formed of a plurality of materials, the carrier balance can be easily adjusted and the reliability can be improved. Alternatively, the formation of an exciplex by the first material and the second material can increase the efficiency of energy transfer to the light-emitting substance, decrease the driving voltage, and improve the reliability, for example. One of the first material and the second material is preferably an organic compound having a π-electron deficient heteroaromatic ring, and the other is preferably an organic compound having a π-electron rich heteroaromatic ring or an aromatic amine, in which case the carrier balance can be more easily adjusted.

In the case where the host material contains a plurality of materials, the GSP_Slope (mV/nm) of a mixed film formed by co-evaporation of the first material and the second material at 1:1 can be used as the GSP_Slope (mV/nm) of the film of the host material. Alternatively, the GSP_Slope (mV/nm) of a vapor deposited film of one of the first material and the second material that is contained at a higher proportion can be regarded as the GSP_Slope (mV/nm) of the film of the host material.

### <Method for Obtaining GSP_Slope>

Here, a method for obtaining the GSP_Slope of an organic compound film formed by a vacuum evaporation method will be described.

A phenomenon in which the surface potential of a vapor deposited film increases in proportion to the thickness of the film is called the giant surface potential as described above. In general, a slope of a plot of the surface potential of a vapor deposited film in the thickness direction by Kelvin probe measurement is assumed as the level of the giant surface potential, that is, GSP_Slope (mV/nm); in the case where two different layers are stacked, a change in the density of charges (mC/m²) accumulated at the interface, which is in association with GSP, can be utilized to estimate the GSP_Slope.

Non-Patent Document 1 discloses that the following equations hold when a voltage is applied to a stack of organic thin films with different spontaneous orientation polarizations (a thin film 1 positioned closer to the anode and a thin film 2 positioned closer to the cathode; the anode is positioned closer to the substrate) and carriers accumulated at the interface are holes.

$$[ Equation 1 ]$$

$${σ}_{acc} = ( {V}_{th} - {V}_{inj} ) \frac{{ε}_{1}}{{d}_{1}} = - {σ}_{i n t} \qquad ( 1 )$$

$$[ Equation 2 ]$$

$${σ}_{i n t} = {P}_{1} - {P}_{2} = \frac{{ε}_{1} {V}_{1}}{{d}_{1}} - \frac{{ε}_{2} {V}_{2}}{{d}_{2}} \qquad ( 2 )$$

In Equation (1), σ_{acc} is an accumulated charge density, σᵢₙₜ is an interface charge density, Vᵢₙⱼ is a hole-injection voltage, Vₜₕ is a threshold voltage, d₂ is a thickness of the thin film 2, and ε₂ is a dielectric constant of the thin film 2. Note that Vᵢₙⱼ and Vₜₕ can be estimated from the capacity-voltage characteristics of a device. The square of an ordinary refractive index nₒ (at a wavelength of 633 nm) can be used as the dielectric constant. As described above, according to Equation (1), the interface charge density al, can be calculated using Vᵢₙⱼ and Vₜₕ estimated from the capacity-voltage characteristics, the dielectric constant 62 of the thin film 2 calculated from the refractive index, and the thickness d₂ of the thin film 2.

Next, in Equation (2), Pₙ is spontaneous orientation polarization of a thin film n (n is 1 or 2) in the substrate normal direction, εₙ is a dielectric constant of the thin film n, Vₙ is a potential of the surface of the film, and dₙ is a thickness of the thin film n. By dividing the potential of the film surface (Vₙ) by the thickness (dₙ), a GSP_Slope can be obtained. Since the interface charge density σᵢₙₜ can be obtained from Equation (1) above, the use of a substance with known GSP_Slope for the thin film 2 and an appropriate dielectric constant enables the GSP_Slope of the thin film 1 to be estimated.

The following is an example of obtaining the GSP_Slope of a film of 4,4′-bis[N-(1-naphthyl)-N-phenylamino]biphenyl (abbreviation: NPB) in a measurement device 1 fabricated using tris(8-quinolinolato)aluminum (abbreviation: Alq₃) whose GSP_Slope is known (48 (mV/nm)) for the thin film 2.

Table 1 shows a device structure of the measurement device 1. Note that layers 1_1 to 4_1 and a cathode in the measurement device 1 were formed from the anode side by a vacuum evaporation method under the conditions where the substrate temperature was room temperature and the deposition rate was within the range of 0.2 nm/s to 0.6 nm/s. Vapor deposition was not interrupted during formation of each of the layers. In the measurement device 1, the layer 2_1 corresponds to the thin film 1 and the layer 3_1 corresponds to the thin film 2. Note that OCHD-003 is an organic compound with an electron-accepting property.

In fabrication of the measurement device, the deposition rate of each layer is preferably within the range of 3 nm/min to 600 nm/min. The thickness of each layer in the measurement device is preferably greater than or equal to 3 nm and less than or equal to 500 nm, further preferably greater than or equal to 50 nm and less than or equal to 300 nm.

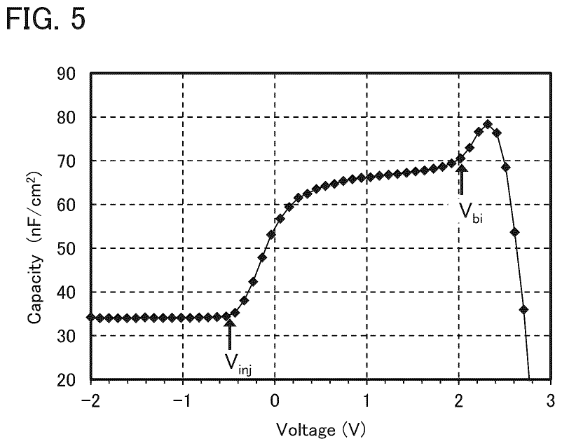

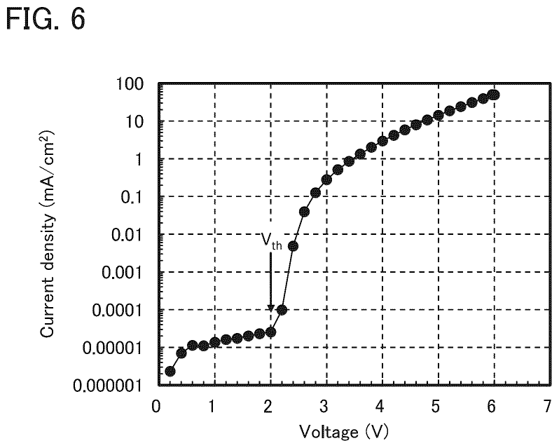

FIG. 5 shows the capacity-voltage characteristics of the measurement device 1. Note that the capacity-voltage characteristics were measured at room temperature at a frequency of 10 Hz with a potentio/galvanostat (SP-300, manufactured by BioLogic Science Instruments in France).

TABLE 1

| | Thickness | | Measurement device 1 |
|---|---|---|---|
| Cathode | 200 | nm | Al |
| Layer 4_1 | 1 | nm | LiF |
| Layer 3_1 | 60 | nm | Alq₃ |
| Layer 2_1 | 80 | nm | NPB |
| Layer 1_1 | 10 | nm | NPB:OCHD-003 (1:0.1) |
| Anode | 70 | nm | ITSO |

Table 2 shows the hole-injection voltage Vᵢₙⱼ, the threshold voltage Vₜₕ, the interface charge density σᵢₙₜ, the SOP, and the GSP_Slope of the measurement device 1 that were obtained from FIG. 5 and Equations (1) and (2) and the refractive indexes nₒ of the materials used in the calculation. The refractive indexes were measured with a spectroscopic ellipsometer (M-2000U, manufactured by J.A. Woollam Japan Corp.).

TABLE 2

Measurement device 1

| | | |
|---|---|---|
| Hole-injection voltage Vᵢₙⱼ | −0.53 | V |
| Threshold voltage Vₜₕ | 2.02 | V |
| Interface charge density σᵢₙₜ | −1.1 | mC/m² |
| Ordinary refractive index nₒ of Alq₃ | 1.71 | (@ 633 nm) |
| Ordinary refractive index nₒ of NPB | 1.77 | (@ 633 nm) |
| SOP of NPB | 0.14 | mC/m² |
| GSP_Slope of NPB | 5.2 | mV/nm |

Note that a measurement device 2 having substantially the same structures as the measurement device 1 except that the thickness of Alq₃ is 80 nm was fabricated. It was confirmed that the hole-injection voltage of the measurement device 2 shifted to a lower voltage side than that of the measurement device 1. That is, it is presumed that holes are injected first and charges are accumulated at the interface with Alq₃ in such a device. Furthermore, the GSP_Slope was estimated for the measurement device 2 in a manner similar to that for the measurement device 1, and the same results as those of the measurement device 1 were obtained.

In the case where the threshold voltage Vₜₕ is difficult to estimate from the capacity-voltage characteristics, the threshold voltage may be estimated from the current density-voltage characteristics.

FIG. 6 shows current density-voltage characteristics of the device 1.

Vₜₕ estimated from the current density-voltage characteristics is 2.0 V, which is the same as the value estimated from the capacity-voltage characteristics.

In this manner, by fabricating a device in which a film of Alq₃ with known GSP_Slope and an organic compound film whose GSP_Slope is to be obtained are stacked and measuring the capacity-voltage characteristics, the GSP_Slope of the organic compound can be estimated.

The above is the description of the method for calculating the GSP_Slope of the case where holes are carriers accumulated at the interface. In the case where electrons are carriers accumulated at the interface, the GSP_Slope of an organic film can be calculated in a similar manner using Equation (3) shown below.

$$[ Equation 3 ]$$

$${σ}_{acc} = ( {V}_{th} - {V}_{inj} ) \frac{{ε}_{1}}{{d}_{1}} = {σ}_{i n t} \qquad ( 3 )$$

Organic compounds used for layers of a light-emitting device are preferably selected in consideration of the GSP_Slopes of vapor deposited films of the organic compounds, which are measured in advance by the above measurement method.

Note that the structures described in this embodiment can be used in combination with any of the structures described in the other embodiments as appropriate.

### Embodiment 2

In this embodiment, light-emitting devices of one embodiment of the present invention will be described in detail.

FIGS. 1A to 2B are each a schematic view of a light-emitting device of one embodiment of the present invention. The light-emitting device includes the first electrode 101 over the substrate 1000 of an insulator, and the EL layer 103 between the first electrode 101 and the second electrode 102. The EL layer 103 includes the light-emitting layer 113, and the light-emitting layer 113 contains a light-emitting substance that emits light when voltage is applied between the first electrode 101 and the second electrode 102.

The EL layer 103 includes at least the first electron-transport layer 114_1 and the second electron-transport layer 1142 in addition to the light-emitting layer 113 and has such a structure as described in Embodiment 1. The light-emitting device having the above structure of one embodiment of the present invention can have favorable characteristics, particularly high reliability.

Furthermore, the EL layer 103 preferably includes other functional layers such as the hole-injection layer 111, the hole-transport layer 112, and the electron-injection layer 115, as illustrated in FIGS. 1A to 2B. Note that the EL layer 103 may include functional layers other than the above functional layers, such as a hole-blocking layer, an electron-blocking layer, an exciton-blocking layer, and a charge-generation layer. Alternatively, any of the above layers may be omitted.

The first electrode 101 and the second electrode 102 each have a single-layer structure or a stacked-layer structure. In the case of the stacked-layer structure, a layer in contact with the EL layer 103 serves as an anode or a cathode. In the case where the electrodes each have the stacked-layer structure, there is no limitation on work functions of materials for layers other than the layer in contact with the EL layer 103, and the materials can be selected in accordance with required properties such as a resistance value, processing easiness, reflectivity, light-transmitting property, and stability.

The anode is preferably formed using a metal, an alloy, a conductive compound, or a mixture thereof each having a high work function (specifically, higher than or equal to 4.0 eV), for example. Specific examples include indium oxide-tin oxide (ITO: indium tin oxide), indium oxide-tin oxide containing silicon or silicon oxide (ITSO: indium tin silicon oxide), indium oxide-zinc oxide, and indium oxide containing tungsten oxide and zinc oxide (IWZO). Films of such conductive metal oxides are usually formed by a sputtering method, but may be formed by a sol-gel method or the like. For example, a film of indium oxide-zinc oxide is formed by a sputtering method using a target in which 1 wt % to 20 wt % zinc oxide is added to indium oxide. Furthermore, a film of indium oxide containing tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), titanium (Ti), aluminum (Al), a nitride of a metal material (e.g., titanium nitride), or the like can be used for the anode. The anode may be a stack of layers formed using any of these materials. For example, a film in which Al, Ti, and ITSO are stacked in this order over Ti is preferable because the film has high efficiency owing to high reflectivity and enables a high resolution of several thousand ppi. Graphene can also be used for the anode. When a composite material that can be included in the hole-injection layer 111 described later is used for a layer (typically, the hole-injection layer) in contact with the anode, an electrode material can be selected regardless of its work function.

The hole-injection layer 111 is provided in contact with the anode and has a function of facilitating injection of holes into the EL layer 103. The hole-injection layer 111 can be formed using phthalocyanine (abbreviation: H₂Pc), a phthalocyanine-based compound or a phthalocyanine-based complex compound such as copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N-(3-methylphenyl)-N′-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS), for example.

The hole-injection layer 111 may be formed using a substance having an electron-acceptor property. Examples of the substance having an acceptor property include organic compounds having an electron-withdrawing group (e.g., a halogen group or a cyano group), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylene-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-acceptor property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, a transition metal oxide such as molybdenum oxide, vanadium oxide, ruthenium oxide, tungsten oxide, or manganese oxide can be used, other than the above-described organic compounds.

The hole-injection layer 111 is preferably formed using a composite material containing any of the aforementioned materials having an acceptor property and an organic compound having a hole-transport property.

As the organic compound having a hole-transport property that is used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the organic compound having a hole-transport property that is used in the composite material preferably has a hole mobility higher than or equal to 1×10⁻⁶ cm²Vs. The organic compound having a hole-transport property that is used in the composite material preferably has a condensed aromatic hydrocarbon ring or a π-electron rich heteroaromatic ring. As the condensed aromatic hydrocarbon ring, an anthracene ring, a naphthalene ring, or the like is preferable. As the π-electron rich heteroaromatic ring, a condensed aromatic ring having at least one of a pyrrole skeleton, a furan skeleton, and a thiophene skeleton in the ring is preferable; specifically, a carbazole ring, a dibenzothiophene ring, or a ring in which an aromatic ring or a heteroaromatic ring is further condensed to a carbazole ring or a dibenzothiophene ring is preferable.

Such an organic compound having a hole-transport property further preferably has at least one of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the organic compound having a hole-transport property preferably has an N,N-bis(4-biphenyl)amino group to enable fabricating a light-emitting device having a long lifetime.

Specific examples of the organic compound having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAONB), 4-[4-(2-naphthyl)phenyl]-4′,4″-diphenyltriphenylamine (abbreviation: BBAβNBi), 4,4′-diphenyl-4″-([2,1′-binaphthyl]-6-yl)triphenylamine (abbreviation: BBAαNβNB), 4,4′-diphenyl-4″-([2,1′-binaphthyl]-7-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-([2,2′-binaphthyl]-6-yl)triphenylamine (abbreviation: BBA(ON2)B), 4,4′-diphenyl-4″-([2,2′-binaphthyl]-7-yl)triphenylamine (abbreviation: BBA(ON2)B-03), 4,4′-diphenyl-4″-([1,2′-binaphthyl]-4-yl)triphenylamine (abbreviation: BBAβNαNB), 4,4′-diphenyl-4″-([1,2′-binaphthyl]-5-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

Examples of the aromatic amine compounds that can be used as the material with a hole-transport property include N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B). The organic compounds represented by General Formulae (G1) to (G6) in Embodiment 1 can also be suitably used. In the case where any of the organic compounds represented by General Formulae (G1) to (G6) in Embodiment 1 is used, a light-emitting device with high emission efficiency can be obtained because the organic compounds are each a material capable of forming a film with a low refractive index.

The formation of the hole-injection layer 111 can improve the hole-injection property, which allows the light-emitting device to be driven at a low voltage.

Among substances having an acceptor property, an organic compound having an acceptor property is easy to use because the organic compound is easily deposited by evaporation as a film.

The hole-transport layer 112 is formed using an organic compound having a hole-transport property. The organic compound having a hole-transport property preferably has a hole mobility of 1×10⁻⁶ cm²/Vs or higher. The hole-transport layer 112 may be a single layer or may have a stacked-layer structure. The hole-transport layer in contact with the light-emitting layer preferably has a function of an electron-blocking layer.

Examples of the aforementioned material having a hole-transport property include the following compounds: compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: ONCCP), 9-(3-biphenyl)-9′-(2-naphthyl)-3,3′-bi-9H-carbazole (abbreviation: ONCCmBP), 9-(4-biphenyl)-9′-(2-naphthyl)-3,3′-bi-9H-carbazole (abbreviation: ONCCBP), 9,9′-di-2-naphthyl-3,3′-9H,9′H-bicarbazole (abbreviation: BispNCz), 9-(2-naphthyl)-9′-[1,1′:4′,1″-terphenyl]-3-yl-3,3′-9H,9′H-bicarbazole, 9-(2-naphthyl)-9′-[1,1′: 3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′: 3′,1″-terphenyl]-4-yl-3,3′-9H,9′H-bicarbazole, and 9-[3-(triphenylsilyl)phenyl]-3,9′-bi-9H-carbazole (abbreviation: PSiCzCz); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above compounds, the compound having an aromatic amine skeleton and the compound having a carbazole skeleton are preferable because these compounds are highly reliable and have a high hole-transport property to contribute to a reduction in driving voltage. Note that any of the substances given as examples of the material having a hole-transport property that is used for the composite material for the hole-injection layer 111 can also be suitably used as the material contained in the hole-transport layer 112. An organic compound having an amine skeleton and a fluorene skeleton is further preferably used. The organic compound having an amine skeleton and a fluorene skeleton is preferable because its high reliability and high hole-transport property enable power consumption of a light-emitting device to be reduced.

Note that when the GSP_Slope of the hole-transport layer 112 is smaller than the GSP_Slope of the light-emitting layer 113, negative charge can be set at at least any one of the interfaces existing between the hole-transport layer and the light-emitting layer. This facilitates hole injection from the anode or the hole-injection layer to the vicinity of the interface with the light-emitting layer, so that the light-emitting device can have a low driving voltage.

The light-emitting device of one embodiment of the present invention includes at least a substance capable of converting triplet excitation energy into light emission and a fluorescent substance in a light-emitting layer. A phosphorescent substance is preferable as the substance capable of converting triplet excitation energy into light emission. Examples of the fluorescent substance include a substance exhibiting thermally activated delayed fluorescence (TADF). Note that the present invention can be suitably applied to a light-emitting device using a blue-light-emitting substance, particularly a blue phosphorescent substance because the light-emitting layer 113 tends to have excess electrons.

Examples of the material that can be used as a fluorescent substance in the light-emitting layer areas follows. The fluorescent substances listed in Embodiment 1 can also be used. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-diphenyl-N,N′-(1,6-pyrene-diyl)bis[(6-phenylbenzo[b]naphtho[1,2-d]furan)-8-amine](abbreviation: 1,6BnfAPrn-03), N,N′-diphenyl-N,N′-bis(9-phenyl-9H-carbazol-2-yl)naphtho[2,3-b;6,7-b′]bisbenzofuran-3,10-diamine (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

A condensed heteroaromatic compound containing nitrogen and boron, especially a compound having a diaza-boranaphtho-anthracene skeleton, exhibits a narrow emission spectrum, emits blue light with high color purity, and can thus be used suitably. Examples of the compound include 5,9-diphenyl-5H,9H-[1,4]benzazaborino[2,3,4-kl]phenazaborine (abbreviation: DABNA-1), 9-(diphenyl-3-yl)-N,N,5,11-tetraphenyl-5,9-dihydro-5,9-diaza-13b-boranaphtho[3,2,1-de]anthracen-3-amine (abbreviation: DABNA-2), 2,12-di(tert-butyl)-5,9-di(4-tert-butylphenyl)-N,N-diphenyl-5H,9H-[1,4]benzazaborino[2,3,4-kl]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-kl][1,4]benzazaborino[4′,3′,2′:4,5][1,4]benzazaborino[3,2-b]phenazaborine-7,13-diamine (abbreviation: v-DABNA), and 2-(4-tert-butylphenyl)benz[5,6]indolo[3,2,1-jk]benzo[b]carbazole (abbreviation: tBuPBibc).

Besides the above compounds, a compound having an indole skeleton, such as 9,10,11-tris[3,6-bis(1,1-dimethylethyl)-9H-carbazol-9-yl]-2,5,15,18-tetrakis(1,1-dimethylethyl)indolo[3,2,1-de]indolo[3′,2′,1′: 8,1][1,4]benzazaborino[2,3,4-k]phenazaborine (abbreviation: BBCz-G), 9,11-bis[3,6-bis(1,1-dimethylethyl)-9H-carbazol-9-yl]-2,5,15,18-tetrakis(1,1-dimethylethyl)indolo[3,2,1-de]indolo[3′,2′,1′: 8,1][1,4]benzazaborino[2,3,4-kl]phenazaborine (abbreviation: BBCz-Y), or the like can be suitably used.

Examples of the phosphorescent substance are as follows.

The examples include organometallic iridium complexes having a 4H-triazole skeleton, such as tris{2-[5-(2-methylphenyl)-4-(2,6-dimethylphenyl)-4H-1,2,4-triazol-3-yl-κN]phenyl-κC}iridium(III) (abbreviation: [Ir(mpptz-dmp)₃]), and tris(5-methyl-3,4-diphenyl-4H-1,2,4-triazolato)iridium(III)(abbreviation: [Ir(Mptz)₃]); organometallic iridium complexes having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); organometallic iridium complexes having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), and tris(2-{1-[2,6-bis(1-methylethyl)phenyl]-1H-imidazol-2-yl-κN³}-4-cyanophenyl-κC)iridium(III) (abbreviation: CNImIr); organometallic complexes having a benzimizazolidene skeleton, such as tris[(6-tert-butyl-3-phenyl-2H-imidazo[4,5-b]pyrazin-1-yl-κC²)phenyl-κC]iridium(III) (abbreviation: [Ir(cb)₃]); organometallic iridium complexes in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIracac); and platinum complexes such as (2-{3-[3-(3,5-di-tert-butylphenyl)benzimidazol-1-yl-2-ylidene-κC²]phenoxy-κC²}-9-(4-tert-butyl-2-pyridinyl-κN)carbazole-2,1-diyl-κC¹)platinum(II) (abbreviation: PtON-TBBI). These compounds emit blue phosphorescent light and have an emission peak in the wavelength range from 450 nm to 520 nm. Any of the phosphorescent substances described in Embodiment 1 can also be used as the blue phosphorescent substance. Alternatively, a compound obtained by substituting deuterium for part of hydrogen in any of these compounds can also be used.

Other examples include organometallic iridium complexes having a pyrimidine skeleton, such as tris(4-methyl-6-phenylpyrimidinato)iridium(Ill) (abbreviation: [Ir(mppm)₃]), tris(4-t-butyl-6-phenylpyrimidinato)iridium(Ill) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes having a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(Ill) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(I) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: [Ir(5mppy-d₃)₂(mbfpypy-d₃)]), {2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-κN]phenyl-κC}iridium(III) (abbreviation: Ir(5mtpy-d₆)(mbfpypy-iPr-d₄)), [2-(methyl-d₃)-8-(2-pyridinyl-κN)benzofuro[2,3-b]pyridine-κC]bis[2-(2-pyridinyl-κN)phenyl-κC]iridium(III) (abbreviation: Ir(ppy)₂(mbfpypy-d₃)), [2-(4-methyl-5-phenyl-2-pyridinyl-κN)phenyl-κC]bis[2-(2-pyridinyl-κN)phenyl-κC]iridium(III) (abbreviation: [Ir(ppy)₂(mdppy)]), [2-(4-d₃-methyl-5-phenyl-2-pyridinyl-κN²)phenyl-κC]bis[2-(5-d₃-methyl-2-pyridinyl-κN²)phenyl-κC]iridium(III) (abbreviation: [Ir(5mppy-d₃)₂(mdppy-d₃)]), [2-methyl-8-(2-pyridinyl-κN)benzofuro[2,3-b]pyridine-κC]bis[2-(2-pyridinyl-κN)phenyl-κC]iridium(III) (abbreviation: Ir(ppy)₂(mbfpypy)), and tris{2-[5-(methyl-d₃)-4-phenyl-2-pyridinyl-κN]phenyl-κC}iridium(III) (abbreviation: Ir(5m4dppy-d₃)₃); rare earth metal complexes such as tris(acetylacetonatoxmonophenanthroline)terbium(III) (abbreviation: [Tb(acac)₃(Phen)]); and organometallic platinum complexes such as (2-{1-(5-tert-butylbiphenyl-2-yl)-4-[3-tert-butyl-5-(4-phenyl-2-pyridinyl-κN)phenyl-κC⁶]-2-benzimidazolyl-κN³}-4,6-di-tert-butylphenolato-κO)platinum(II) (abbreviation: Pt(tBudppymmtBubiz-tBubp)) and [2-(4-(3,5-di-tert-butylphenyl)-6-(3-[4-(5′-tert-butyl[1,1′:3′,1″-terphenyl]-2′-yl)-2-pyridinyl-κN]phenyl-κC²)-2-pyridinyl-κN)phenolato-κO]platinum(II) (abbreviation: Pt(4tButpppypyp-mmtBup)). These compounds mainly emit green phosphorescent light and have an emission peak in the wavelength range from 500 nm to 600 nm. Note that organometallic iridium complexes having a pyrimidine skeleton have distinctively high reliability or emission efficiency and thus are particularly preferable. A compound obtained by substituting deuterium for part of hydrogen in any of these compounds can also be used.

Other examples include organometallic iridium complexes having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(d1npm)₂(dpm)]); organometallic iridium complexes having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinatoxdipivaloylmethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)₂(acac)]); organometallic iridium complexes having a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-κN]phenyl-κC]iridium(III), and (3,7-diethyl-4,6-nonanedionato-κO⁴,κO⁶)bis[2,4-dimethyl-6-[5-(1-methylethyl)-2-quinolinyl-κN]phenyl-κC]iridium(III); platinum complexes such as 2,3,7,8,12,13,17,18-octaethyl-21H,23H-porphyrinplatinum(II) (abbreviation: PtOEP); and rare earth metal complexes such as tris(1,3-diphenyl-1,3-propanedionatoxmonophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]). These compounds emit red phosphorescent light and have an emission peak in the wavelength range from 600 nm to 700 nm. Furthermore, the organometallic iridium complexes having a pyrazine skeleton can provide red light emission with favorable chromaticity. A compound obtained by substituting deuterium for part of hydrogen in any of these compounds can also be used.

Besides the above phosphorescent compounds, known phosphorescent compounds may be selected and used.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

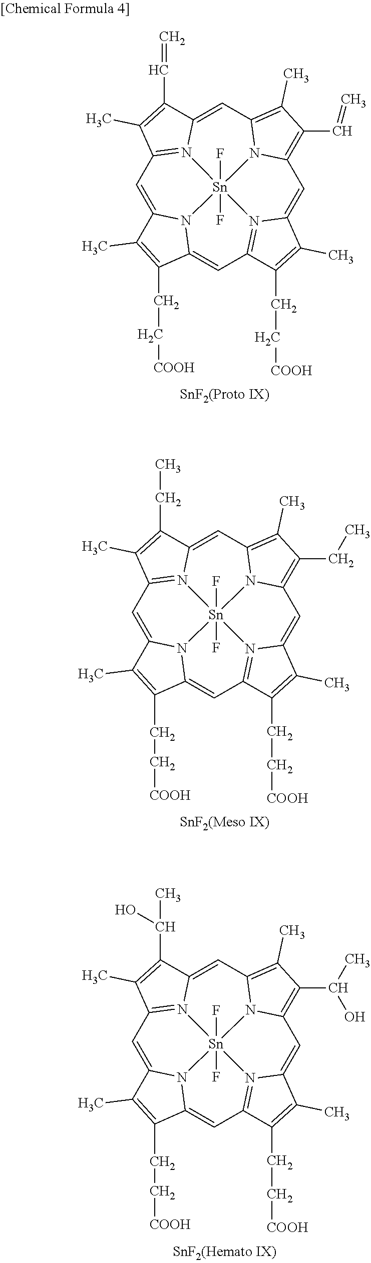

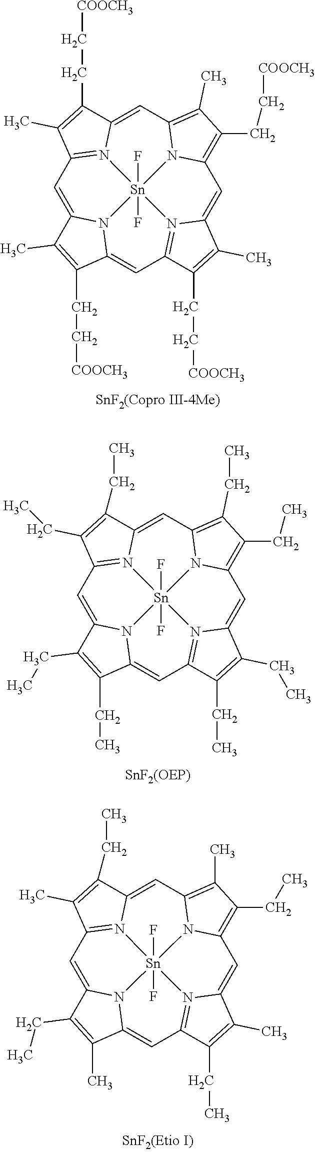

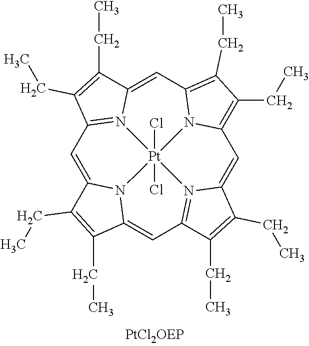

Alternatively, it is possible to use a heterocyclic compound having one or both of a π-electron rich heteroaromatic ring and a π-electron deficient heteroaromatic ring that is represented by any of the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Such a heterocyclic compound is preferable because of having high electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-acceptor property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton including boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

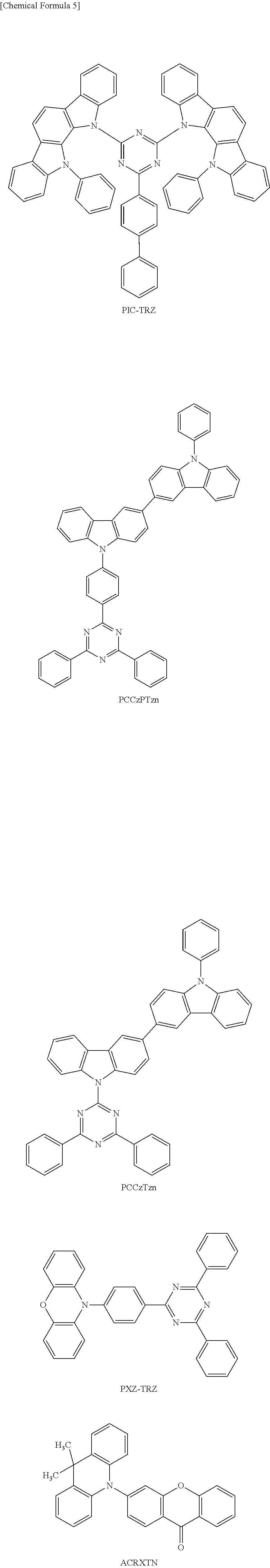 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; CC1(C)c2ccccc2N(c2ccc3c(=O)c4ccccc4oc3c2)c2ccccc21]

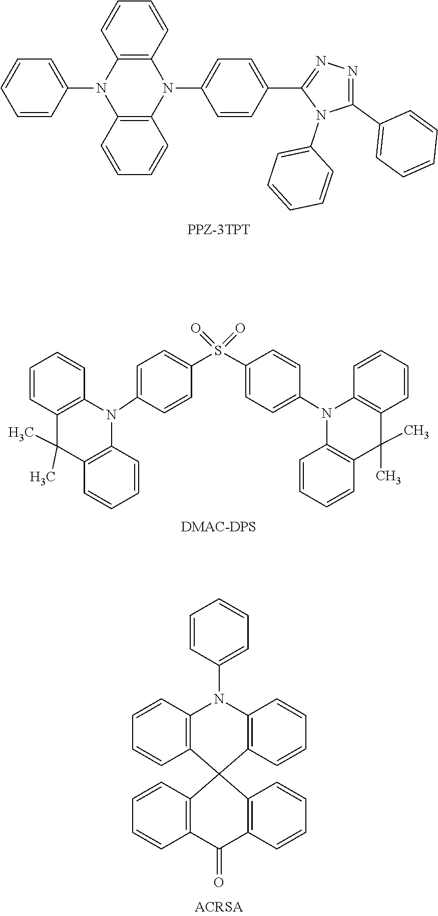

Note that a TADF material is a material having a small energy difference between the S₁ level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small energy difference between the S₁ level and the T₁ level and functions as a TADF material capable of converting triplet excitation energy into singlet excitation energy.

A phosphorescence spectrum observed at a low temperature (e.g., 77 K to 10 K) is used for an index of the T₁ level. When the level of energy with a wavelength of a line obtained by extrapolating a tangent to the fluorescence spectrum at a tail on the shorter wavelength side is the S₁ level and the level of energy with a wavelength of a line obtained by extrapolating a tangent to the phosphorescence spectrum at a tail on the shorter wavelength side is the T₁ level, the energy difference between the S₁ level and the T₁ level of the TADF material is preferably less than or equal to 0.3 eV, further preferably less than or equal to 0.2 eV.

When the TADF material is used as a light-emitting substance, the S₁ level of the host material is preferably higher than that of the TADF material, and the T₁ level of the host material is preferably higher than that of the TADF material.

As the host material in the light-emitting layer, any of various carrier-transport materials such as materials having an electron-transport property and/or materials having a hole-transport property, and the TADF materials can be used.

The material having a hole-transport property is preferably an organic compound having an amine skeleton or a π-electron rich heteroaromatic ring skeleton, for example. As the π-electron rich heteroaromatic ring, a condensed aromatic ring having at least one of an acridine skeleton, a phenoxazine skeleton, a phenothiazine skeleton, a furan skeleton, a thiophene skeleton, and a pyrrole skeleton in the ring is preferable; specifically, a carbazole ring, a dibenzothiophene ring, or a ring in which an aromatic ring or a heteroaromatic ring is further condensed to a carbazole ring or a dibenzothiophene ring is preferable.

Such an organic compound having a hole-transport property further preferably has at least one of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the organic compound having a hole-transport property preferably has an N,N-bis(4-biphenyl)amino group to enable fabricating a light-emitting device having a long lifetime.

Examples of such an organic compound include compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N′,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole)(abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: ONCCP), 9-(3-biphenyl)-9′-(2-naphthyl)-3,3′-bi-9H-carbazole (abbreviation: ONCCmBP), 9-(4-biphenyl)-9′-(2-naphthyl)-3,3′-bi-9H-carbazole (abbreviation: ONCCBP), 9,9′-di-2-naphthyl-3,3′-9H,9′H-bicarbazole (abbreviation: BispNCz),9-(2-naphthyl)-9′-[1,1′:4′,1″-terphenyl]-3-yl-3,3′-9H,9′H-bicarbazole, 9-(2-naphthyl)-9′-[1,1′: 3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′: 3′,1″-terphenyl]-4-yl-3,3′-9H,9′H-bicarbazole, and 9-[3-(triphenylsilyl)phenyl]-3,9′-bi-9H-carbazole (abbreviation: PSiCzCz); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. In addition, the organic compounds given as examples of the material having a hole-transport property that can be used for the hole-transport layer can also be used. An organic compound having an amine skeleton and a fluorene skeleton is further preferably used. The organic compound having an amine skeleton and a fluorene skeleton is preferable because its high reliability and high hole-transport property enable power consumption of a light-emitting device to be reduced.

The material having an electron-transport property preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has an electron-transport property higher than a hole-transport property.

As the material having an electron-transport property, for example, a metal complex such as tris(8-quinolinolato)aluminum (abbreviation: Alq₃), bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq),bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring is preferably used. Examples of the organic compound having a π-electron deficient heteroaromatic ring skeleton include an organic compound that has a heteroaromatic ring having an azole skeleton, an organic compound that has a heteroaromatic ring having a pyridine skeleton, an organic compound that has a heteroaromatic ring having a diazine skeleton, and an organic compound that has a heteroaromatic ring having a triazine skeleton.

Among the above materials, the organic compound that has a heteroaromatic ring having a diazine skeleton (a pyrimidine skeleton, a pyrazine skeleton, or a pyridazine skeleton), the organic compound that has a heteroaromatic ring having a pyridine skeleton, and the organic compound that has a heteroaromatic ring having a triazine skeleton have high reliability and thus are preferable. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high acceptor properties and high reliability.

Examples of the organic compound having a π-electron deficient heteroaromatic ring skeleton include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), 4,4′-bis(5-methylbenzoxazol-2-yl)stilbene (abbreviation: BzOs), or 2-{4-[9,10-di(2-naphthyl)-2-anthryl]phenyl}-1-phenyl-1H-benzimidazole (abbreviation: ZADN); an organic compound that has a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthryl)-1-naphthyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′: 4,5]furo[3,2-d]pyrimidine (abbreviation: 8mDBtBPNfpm), 8-([2,2′-binaphthalen]-6-yl)-4-[3-(dibenzothiophen-4-yl)phenyl]-[1]benzofuro[3,2-d]pyrimidine (abbreviation: 8(ON2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis(4-[4-(2-naphthyl)phenyl]-6-phenylpyrimidine) (abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), 8-(biphenyl-4-yl)-4-[3′-(dibenzothiophen-4-yl)biphenyl-3-yl]-[1]benzofuro[3,2-d]pyrimidine (abbreviation: 8BP-4mDBtBPBfpm), 8-(p-terphenyl-3-yl)-4-[3-(dibenzothiophen-4-yl)phenyl]-[1]benzofuro[3,2-d]pyrimidine (abbreviation: 8mpTP-4mDBtPBfpm), or 7-[4-(9-phenyl-9H-carbazol-2-yl)quinazolin-2-yl]-7H-dibenzo[c,g]carbazole (abbreviation: PC-cgDBCzQz); and an organic compound that has a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-(3-[3-(benzo[b]naphtho[1,2-d]furan-8-yl)phenyl]phenyl)-4,6-diphenyl-1,3,5-triazine (abbreviation: mBnfBPTzn), 2-(3-[3-(benzo[b]naphtho[1,2-d]furan-6-yl)phenyl]phenyl)-4,6-diphenyl-1,3,5-triazine (abbreviation: mBnfBPTzn-02), 2-(4-[3-(N-phenyl-9H-carbazol-3-yl)-9H-carbazol-9-yl]phenyl)-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-(3-[3-(dibenzothiophen-4-yl)phenyl]phenyl)-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthryl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-[8-([1,1′: 4′,1″-terphenyl]-4-yl)-1-dibenzofuranyl]-1,3,5-triazine (abbreviation: mBP-TPDBfTzn), 2-(3″,5′,5″-tri-t-butyl-[1,1′: 3′,1″-terphenyl]-4-yl-4,6-diphenyl-1,3,5-triazine (abbreviation: mmtBumTPTzn-04), 2,4,6-tris[3′-(pyridin-3-yl)-5′-tert-butyl-biphenyl-3-yl]-1,3,5-triazine (abbreviation: tBu-TmPPPyTz), 2,4,6-tris[3′-(pyridin-3-yl)-5′-tert-butyl-biphenyl-4-yl]-1,3,5-triazine (abbreviation: tBu-TmPPPyTz-02), 2-(3″,5′,5″-tri-t-butyl-[1,1′: 3′,1″-terphenyl]-5-yl)-4,6-diphenyl-1,3,5-triazine (abbreviation: mmtBumTPTzn-03), or 2-{3-(2,6-dimethylpyridin-3-yl)-5-[(3,5-di-tert-butyl)phenyl]phenyl}-4,6-diphenyl-1,3,5-triazine (abbreviation: mmtBuPh-mDMePyPTzn). The organic compound that has a heteroaromatic ring having a diazine skeleton, the organic compound that has a heteroaromatic ring having a pyridine skeleton, and the organic compound that has a heteroaromatic ring having a triazine skeleton have high reliability and thus are preferable. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. Among the above organic compounds, 8BP-4mDBtBPBfpm, 4,6mDBTP2Pm-II, 8mpTP-4mDBtPBfpm, TPBI, ZADN, BP-ICz(II)Tzn, mmtBumTPTzn-04, tBu-TmPPPyTz, tBu-TmPPPyTz-02, mmtBumTPTzn-03, mmtBuPh-mDMePyPTzn, and 4,8mDBtP2Bfpm as well as Alq₃ each have a large GSP_Slope in an evaporated film state and thus can be suitably used as a material for the second electron-transport layer in the light-emitting device of the present invention.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

Note that the host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property may be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

These mixed materials may form an exciplex. These mixed materials are preferably selected so as to form an exciplex that exhibits light emission whose wavelength overlaps with the wavelength of the lowest-energy-side absorption band of the light-emitting substance, in which case energy can be transferred smoothly and light emission can be obtained efficiently. The use of such a structure is preferable because the driving voltage can also be reduced.

Note that at least one of the materials forming an exciplex may be a phosphorescent substance. In this case, triplet excitation energy can be efficiently converted into singlet excitation energy by reverse intersystem crossing.

In order to form an exciplex efficiently, a material having an electron-transport property is preferably combined with a material having a hole-transport property and a HOMO level higher than or equal to that of the material having an electron-transport property. In addition, the LUMO level of the material having a hole-transport property is preferably higher than or equal to that of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by a phenomenon in which the emission spectrum of the mixed film in which the material having a hole-transport property and the material having an electron-transport property are mixed is shifted to the long wavelength side than the emission spectrum of each of the materials (or has another peak on the long wavelength side) observed by comparison of the emission spectra of the material having a hole-transport property, the material having an electron-transport property, and the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of transient PL of the material having a hole-transport property, the material having an electron-transport property, and the mixed film of these materials. The transient PL can be rephrased as transient electroluminescence (EL). That is, the formation of an exciplex can also be confirmed by a difference in transient response observed by comparison of the transient EL of the material having a hole-transport property, the material having an electron-transport property, and the mixed film of these materials.

The electron-transport layer 114 contains a material having an electron-transport property. The material having an electron-transport property preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has an electron-transport property higher than a hole-transport property. The above organic compound is preferably an organic compound that has a c-electron deficient heteroaromatic ring. The organic compound that has a π-electron deficient heteroaromatic ring is preferably one or more of an organic compound that has a heteroaromatic ring having an azole skeleton, an organic compound that has a heteroaromatic ring having a pyridine skeleton, an organic compound that has a heteroaromatic ring having a diazine skeleton, and an organic compound that has a heteroaromatic ring having a triazine skeleton.

As the organic compound having an electron-transport property that can be used in the electron-transport layer 114, any of the organic compounds that can be used as the organic compound having an electron-transport property in the light-emitting layer 113 can be similarly used. Among the above organic compounds, the organic compound that has a heteroaromatic ring having a diazine skeleton, the organic compound that has a heteroaromatic ring having a pyridine skeleton, and the organic compound that has a heteroaromatic ring having a triazine skeleton are especially preferable because of having high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. In particular, an organic compound having a phenanthroline skeleton such as mTpPPhen, PnNPhen, or mPPhen2P is preferable, and an organic compound having a phenanthroline dimer structure such as mPPhen2P is further preferable because of high stability.

Note that the electron-transport layer 114 may have a stacked-layer structure. A layer in the stacked-layer structure of the electron-transport layer 114, which is in contact with the light-emitting layer 113, may function as a hole-blocking layer. In the case where the electron-transport layer in contact with the light-emitting layer functions as a hole-blocking layer, the electron-transport layer is preferably formed using a material having a lower HOMO level than a material contained in the light-emitting layer 113 by greater than or equal to 0.5 eV.

A layer that contains a compound or a complex of an alkali metal or an alkaline earth metal, such as 8-quinolinolato-lithium (abbreviation: Liq), 1,1′-pyridine-2,6-diyl-bis(1,3,4,6,7,8-hexahydro-2H-pyrimido[1,2-a]pyrimidine)(abbreviation: hpp2Py), or the like may be provided as the electron-injection layer 115. As the electron-injection layer 115, an alkali metal, an alkaline earth metal, or a compound thereof may be contained in a layer formed using a substance having an electron-transport property.

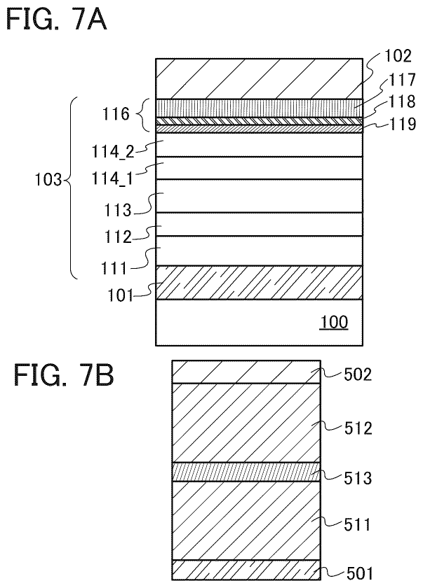

Instead of the electron-injection layer 115, a charge-generation layer 116 may be provided (FIG. 7A). The charge-generation layer 116 refers to a layer capable of injecting holes into a layer in contact with the cathode side of the charge-generation layer 116 and electrons into a layer in contact with the anode side thereof when a potential is applied. The charge-generation layer 116 includes at least a p-type layer 117. The p-type layer 117 is preferably formed using any of the composite materials given above as examples of materials that can be used for the hole-injection layer 111. The p-type layer 117 maybe formed by stacking a film containing the above-described acceptor material as a material included in the composite material and a film containing a hole-transport material. When a potential is applied to the p-type layer 117, electrons are injected into the electron-transport layer 114 and holes are injected into the cathode; thus, the light-emitting device operates. Since the organic compound of one embodiment of the present invention has a low refractive index in a film state, using the organic compound for the p-type layer 117 enables the light-emitting device to have high external quantum efficiency.

Note that the charge-generation layer 116 preferably includes one or both of an electron-relay layer 118 and an electron-injection buffer layer 119 in addition to the p-type layer 117.

The electron-relay layer 118 contains at least a substance having an electron-transport property and has a function of preventing an interaction between the electron-injection buffer layer 119 and the p-type layer 117 and smoothly transferring electrons. The LUMO level of the substance having an electron-transport property that is contained in the electron-relay layer 118 is preferably between the LUMO level of the acceptor substance in the p-type layer 117 and the LUMO level of a substance contained in a layer of the electron-transport layer 114 that is in contact with the charge-generation layer 116. As a specific value of the energy level, the LUMO level of the substance having an electron-transport property in the electron-relay layer 118 is preferably higher than or equal to −5.0 eV, further preferably higher than or equal to −5.0 eV and lower than or equal to −3.0 eV. Note that as the substance having an electron-transport property in the electron-relay layer 118, a phthalocyanine-based material or a metal complex having a metal-oxygen bond and an aromatic ligand is preferably used.

The electron-injection buffer layer 119 can be formed using a substance having a high electron-injection property, e.g., an alkali metal, an alkaline earth metal, a rare earth metal, or a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)).

In the case where the electron-injection buffer layer 119 contains a substance having an electron-transport property and a donor substance, the donor substance can be an organic compound such as tetrathianaphthacene (abbreviation: TTN), nickelocene, or decamethylnickelocene, as well as an alkali metal, an alkaline earth metal, a rare earth metal, or a compound thereof (e.g., an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)). As the substance having an electron-transport property, a material similar to the above-described material for the electron-transport layer 114 can be used.

The second electrode 102 includes the cathode. The second electrode 102 may have a stacked-layer structure, in which case a layer in contact with the EL layer 103 functions as the cathode. The cathode is preferably formed using a metal, an alloy, an electrically conductive compound, or a mixture thereof each having a low work function (specifically, lower than or equal to 3.8 eV), for example. Specific examples of such a cathode material include elements belonging to Group 1 or 2 of the periodic table, such as alkali metals (e.g., lithium (Li) and cesium (Cs)), magnesium (Mg), calcium (Ca), and strontium (Sr), alloys containing these elements (e.g., MgAg and AlLi), compounds containing these elements (e.g., lithium fluoride (LiF), cesium fluoride (CsF), and calcium fluoride (CaF₂)), rare earth metals such as europium (Eu) and ytterbium (Yb), and alloys containing these rare earth metals. However, when the electron-injection layer 115 or a thin film formed using any of the above materials having a low work function is provided between the second electrode 102 and the electron-transport layer, a variety of conductive materials such as Al, Ag, ITO, or indium oxide-tin oxide containing silicon or silicon oxide can be used for the cathode regardless of the work function.

When the second electrode 102 is formed using a material that transmits visible light, the light-emitting device can emit light from the second electrode 102 side.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed.

The EL layer 103 can be formed by any of a variety of methods, including a dry process and a wet process. For example, a vacuum evaporation method, a gravure printing method, an offset printing method, a screen printing method, an ink-jet method, a spin coating method, or the like may be used.

Different film formation methods may be used to form the electrodes or the layers described above.

Next, an embodiment of a light-emitting device with a structure in which a plurality of light-emitting units are stacked (this type of light-emitting device is also referred to as a stacked or tandem element) is described with reference to FIG. 7B. This light-emitting device includes a plurality of light-emitting units between an anode and a cathode. One light-emitting unit has substantially the same structure as the EL layer 103 illustrated in FIGS. 1A to 2B. In other words, the light-emitting device illustrated in FIG. 7B includes a plurality of light-emitting units, and the light-emitting device illustrated in FIGS. 1A to 2B includes a single light-emitting unit.

In FIG. 7B, a first light-emitting unit 511 and a second light-emitting unit 512 are stacked between a first electrode 501 and a second electrode 502, and a charge-generation layer 513 is provided between the first light-emitting unit 511 and the second light-emitting unit 512. The first electrode 501 and the second electrode 502 correspond, respectively, to the first electrode 101 and the second electrode 102 illustrated in FIGS. 1A to 2B, and can be formed using the materials given in the description for FIGS. 1A to 2B. Furthermore, the first light-emitting unit 511 and the second light-emitting unit 512 may have the same structure or different structures.

The charge-generation layer 513 has a function of injecting electrons into one of the light-emitting units and injecting holes into the other of the light-emitting units when voltage is applied between the first electrode 501 and the second electrode 502. That is, in FIG. 7B, the charge-generation layer 513 injects electrons into the first light-emitting unit 511 and holes into the second light-emitting unit 512 when voltage is applied such that the potential of the anode becomes higher than the potential of the cathode.

The charge-generation layer 513 preferably has a structure similar to that of the charge-generation layer 116 described with reference to FIG. 7A. A composite material of an organic compound and a metal oxide enables low-voltage driving and low-current driving because of having an excellent carrier-injection property and an excellent carrier-transport property.

In the case where the anode-side surface of a light-emitting unit is in contact with the charge-generation layer 513, the charge-generation layer 513 can also function as a hole-injection layer of the light-emitting unit; therefore, a hole-injection layer is not necessarily provided in the light-emitting unit.

In the case where the electron-injection buffer layer 119 is provided in the charge-generation layer 513, the electron-injection buffer layer 119 functions as an electron-injection layer in the light-emitting unit on the anode side; thus, an electron-injection layer is not necessarily formed in the light-emitting unit on the anode side.

The light-emitting device having two light-emitting units is described with reference to FIG. 7B; however, one embodiment of the present invention can also be applied to a light-emitting device in which three or more light-emitting units are stacked. With a plurality of light-emitting units partitioned by the charge-generation layer 513 between a pair of electrodes as in the light-emitting device of this embodiment, it is possible to provide a long-life element that can emit light with high luminance at a low current density. A light-emitting apparatus that can be driven at a low voltage and has low power consumption can also be provided.

When the emission colors of the light-emitting units are different, light emission of a desired color can be obtained from the light-emitting device as a whole. For example, in a light-emitting device having two light-emitting units, the emission colors of the first light-emitting unit may be red and green and the emission color of the second light-emitting unit may be blue, so that the light-emitting device can emit white light as the whole.

The EL layer 103, the first light-emitting unit 511, the second light-emitting unit 512, the layers such as the charge-generation layer, and the electrodes that are described above can be formed by a method such as an evaporation method (including a vacuum evaporation method), a droplet discharge method (also referred to as an inkjet method), a coating method, or a gravure printing method. A low molecular material, a middle molecular material (including an oligomer and a dendrimer), or a high molecular material may be included in the above components.

### Embodiment 3

Described in this embodiment is an example in which the light-emitting device of one embodiment of the present invention is used as a display element of a display device. Note that although a light-emitting device shown in this embodiment is formed by a photolithography method, the light-emitting device may be formed by a method using a fine metal mask or the like.

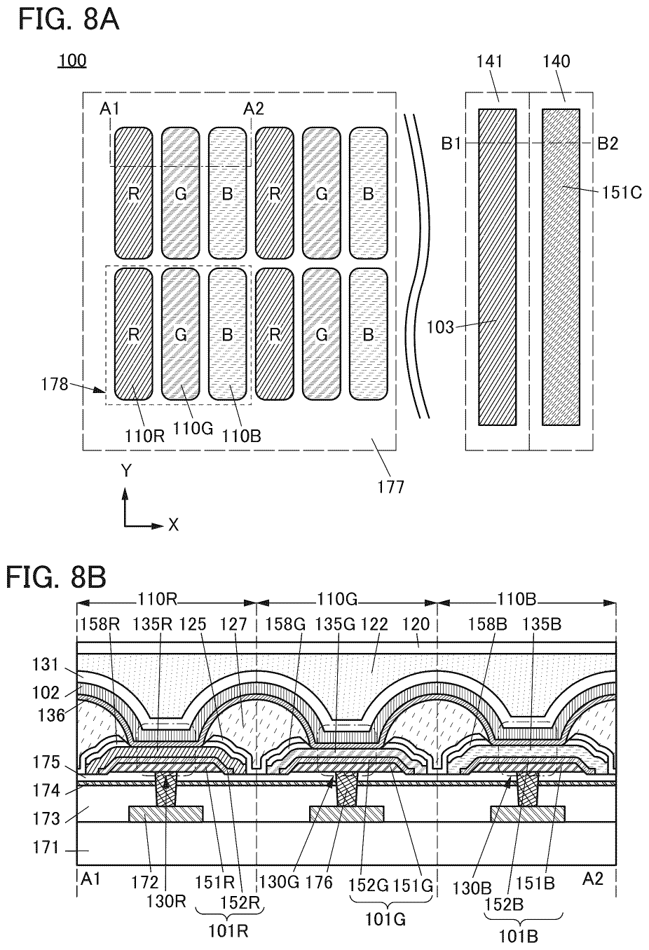

As illustrated in FIGS. 8A and 8B, a plurality of light-emitting devices 130 are formed over an insulating layer 175 to constitute a display device.

A display device 100 includes a pixel portion 177 in which a plurality of pixels 178 are arranged in a matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals without the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and maybe four or more. Examples of four subpixels include subpixels emitting light of four colors of R, G, B, and white (W), subpixels emitting light of four colors of R, G, B, and yellow (Y), and four subpixels emitting light of R, G, and B and infrared light (IR).

In this specification and the like, the row direction and the column direction are sometimes referred to as the X direction and the Y direction, respectively. The X direction and the Y direction intersect with each other and are perpendicular to each other, for example.

FIG. 8A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. The region 141 is provided between the pixel portion 177 and the connection portion 140. The EL layer 103 is provided in the region 141. A conductive layer 151C is provided in the connection portion 140.

Although FIG. 8A illustrates an example where the region 141 and the connection portion 140 are positioned on the right side of the pixel portion 177, the positions of the region 141 and the connection portion 140 are not particularly limited. The number of the regions 141 and the number of the connection portions 140 can each be one or more.

FIG. 8B is an example of a cross-sectional view along the dashed-dotted line A1-A2 in FIG. 8A. As illustrated in FIG. 8B, the display device includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is bonded to the protective layer 131 with a resin layer 122. An inorganic insulating layer 125 and an insulating layer 127 over the inorganic insulating layer 125 are preferably provided between the adjacent light-emitting devices 130.

Although FIG. 8B illustrates cross sections of a plurality of inorganic insulating layers 125 and a plurality of insulating layers 127, the inorganic insulating layers 125 are preferably connected to each other and the insulating layers 127 are preferably connected to each other when the display device is seen from above. That is, the inorganic insulating layer 125 and the insulating layer 127 preferably include opening portions over first electrodes.

In FIG. 8B, a light-emitting device 130R, a light-emitting device 130G, and a light-emitting device 130B are each illustrated as the light-emitting device 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, the light-emitting device 130G, or the light-emitting device 130B may emit visible light of another color or infrared light. It can be said that in FIG. 8B, the light-emitting devices 130R and 130G are adjacent light-emitting devices and the light-emitting devices 130G and 130B are adjacent light-emitting devices.

The display device of one embodiment of the present invention can be, for example, a top-emission display device where light is emitted in the direction opposite to a substrate over which light-emitting devices are formed. Note that the display device of one embodiment of the present invention may be of a bottom emission type.

The light-emitting device 130R emits red light (preferably phosphorescent light), and preferably has the structure shown in Embodiment 2. The light-emitting device 130R includes a first electrode (pixel electrode) 101R including a conductive layer 151R and a conductive layer 152R, a first layer 135R over the first electrode 101R, a common layer 136 over the first layer 135R, and the second electrode (common electrode) 102 over the common layer 136. The common layer 136 is preferably an electron-injection layer.

The light-emitting device 130G emits green light (preferably phosphorescent light), and preferably has the structure shown in Embodiment 2. The light-emitting device 130G includes a first electrode (pixel electrode) 101G including a conductive layer 151G and a conductive layer 152G, a first layer 135G over the first electrode 101G, the common layer 136 over the first layer 135G, and the second electrode (common electrode) 102 over the common layer 136. The common layer 136 is preferably an electron-injection layer.

The light-emitting device 130B emits blue light (preferably fluorescent light), and preferably has the structure shown in Embodiment 2. The light-emitting device 130B includes a first electrode (pixel electrode) 101B including a conductive layer 151B and a conductive layer 152B, a first layer 135B over the first electrode 101B, the common layer 136 over the first layer 135B, and the second electrode (common electrode) 102 over the common layer 136. The common layer 136 is preferably an electron-injection layer.

In the light-emitting device, one of the pixel electrode (first electrode) and the common electrode (second electrode) functions as an anode and the other functions as a cathode. In this embodiment, description is made on the assumption that the pixel electrode functions as the anode and the common electrode functions as the cathode unless otherwise specified.

The first layers 135R, 135G, and 135B are island-shaped layers that are independent of each other on a light-emitting device basis or on an emission color basis. It is preferable that the first layers 135R, 135G, and 135B not overlap with one another. The first layers included in the plurality of light-emitting devices 130 formed in the light-emitting apparatus, such as the first layers 135R, 135G, and 135B, are collectively referred to as a first layer group 135A in some cases. Providing the island-shaped first layer group 135A in the light-emitting devices 130 can inhibit leakage current between the adjacent light-emitting devices 130 even in a high-resolution display device. This can prevent crosstalk, so that a display device with extremely high contrast can be obtained. Specifically, a display device having high current efficiency at low luminance can be obtained.

The island-shaped first layer group 135A is formed by forming an EL film for each emission color and processing the EL film by a photolithography method.

The first layer 135 is preferably provided to cover the top surface and the side surface of the first electrode 101 (pixel electrode) of the light-emitting device 130. In this case, the aperture ratio of the display device can be easily increased as compared to the structure where an end portion of the first layer 135 is positioned inward from an end portion of the pixel electrode. Covering the side surface of the pixel electrode of the light-emitting device 130 with the first layer 135 can inhibit the first electrode 101 from being in contact with the second electrode 102; hence, a short circuit of the light-emitting device 130 can be inhibited.

In the display device of one embodiment of the present invention, the first electrode 101 (pixel electrode) of the light-emitting device preferably has a stacked-layer structure. For example, in the example illustrated in FIG. 8B, the first electrode 101 of the light-emitting device 130 has a stacked-layer structure of the conductive layer 151 provided on the insulating layer 171 side and the conductive layer 152 provided on the organic compound layer side.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a work function higher than or equal to 4.0 eV, for example.

The conductive layer 151 and the conductive layer 152 may each be a stack of a plurality of layers containing different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

Note that the conductive layer 151 preferably has a tapered end portion. Specifically, the conductive layer 151 preferably has a tapered end portion with a taper angle of less than 90°. In that case, the conductive layer 152 provided along the side surface of the conductive layer 151 also has a tapered shape. When the side surface of the conductive layer 152 has a tapered shape, coverage with the first layer 135 provided along the side surface of the conductive layer 152 can be improved.

### Embodiment 4

In this embodiment, a display device of one embodiment of the present invention will be described.

The display device in this embodiment can be a high-resolution display device. Thus, the display device in this embodiment can be used for display portions of information terminals (wearable devices) such as watch-type and bracelet-type information terminals and display portions of wearable devices capable of being worn on a head, such as a VR device like a head mounted display (HMD) and a glasses-type AR device.

The display device in this embodiment can be a high-definition display device or a large-sized display device. Accordingly, the display device in this embodiment can be used for display portions of a digital camera, a digital video camera, a digital photo frame, a mobile phone, a portable game console, a portable information terminal, and an audio reproducing device, in addition to display portions of electronic appliances with a relatively large screen, such as a television device, desktop and notebook personal computers, a monitor of a computer and the like, digital signage, and a large game machine such as a pachinko machine.

### [Display Module]

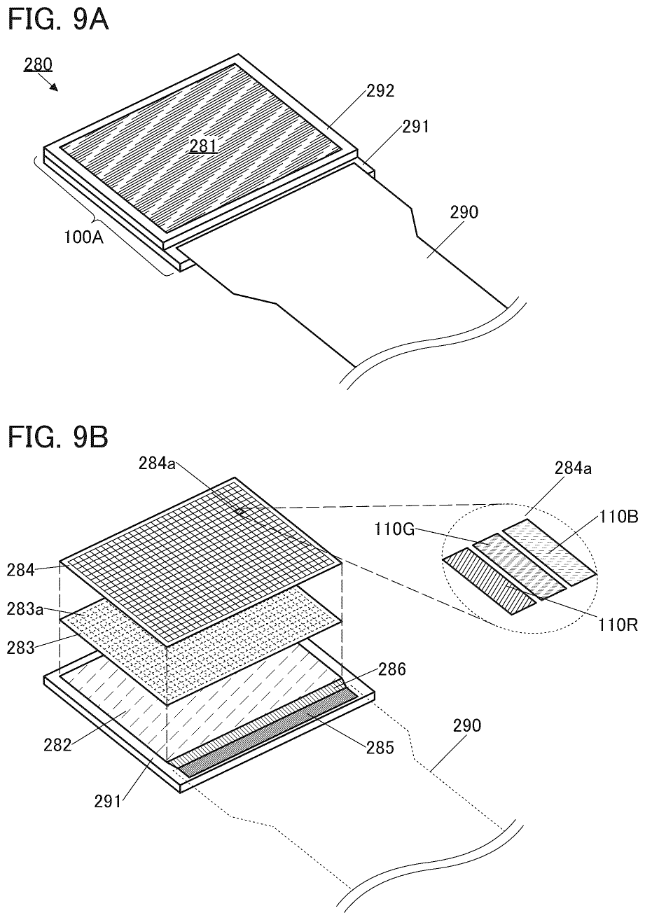

FIG. 9A is a perspective view of a display module 280. The display module 280 includes a display device 100A and an FPC 290. Note that the display device included in the display module 280 is not limited to the display device 100A and may be any of display devices 100B to 100E described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 9B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 9B. The pixels 284a can employ any of the structures described in the above embodiments. FIG. 9B illustrates an example where the pixel 284a has a structure similar to that of the pixel 178 illustrated in FIG. 8A.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion.

### [Display Device 100A]

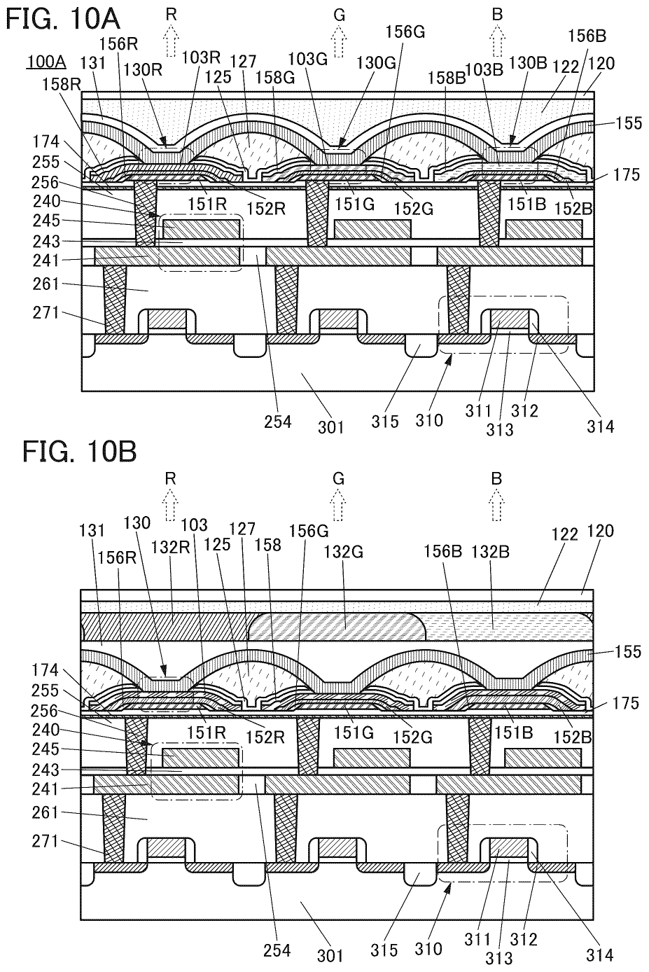

The display device 100A illustrated in FIG. 10A includes a substrate 301, the light-emitting devices 130R, 130G, and 130B, a capacitor 240, and a transistor 310.

The substrate 301 corresponds to the substrate 291 in FIGS. 9A and 9B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as agate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between adjacent light-emitting devices.

An insulating layer 156R is provided to include a region overlapping with the side surface of the conductive layer 151R. An insulating layer 156G is provided to include a region overlapping with the side surface of the conductive layer 151G. An insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. A sacrificial layer 158R is positioned over the first layer 135R. A sacrificial layer 158G is positioned over the first layer 135G. A sacrificial layer 158B is positioned over the first layer 135B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The protective layer 131 is provided over the light-emitting devices 130R, 130G, and 130B. The substrate 120 is bonded to the protective layer 131 with the resin layer 122. Embodiment 3 can be referred to for the details of the light-emitting device 130 and the components thereover up to the substrate 120. The substrate 120 corresponds to the substrate 292 in FIG. 9A.

FIG. 10B illustrates a variation example of the display device 100A illustrated in FIG. 10A. The display device illustrated in FIG. 10B includes a coloring layer 132R, a coloring layer 132G, and a coloring layer 132B, and each of the light-emitting devices 130 includes a region overlapping with one of the coloring layers 132R, 132G, and 132B. In the display device illustrated in FIG. 10B, the light-emitting device 130 can emit white light, for example. The coloring layer 132R, the coloring layer 132G, and the coloring layer 132B can transmit red light, green light, and blue light, respectively, for example.

### [Display Device 100B]

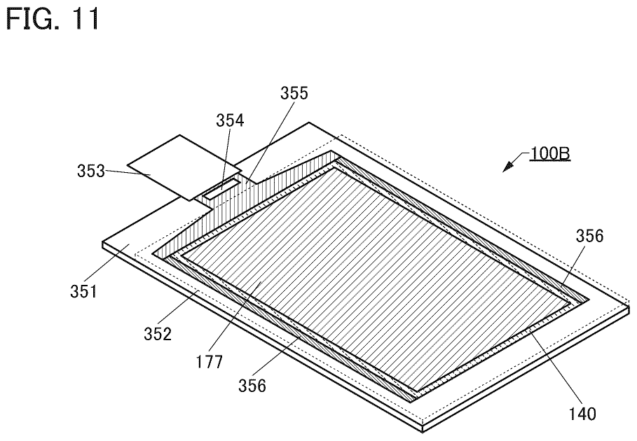

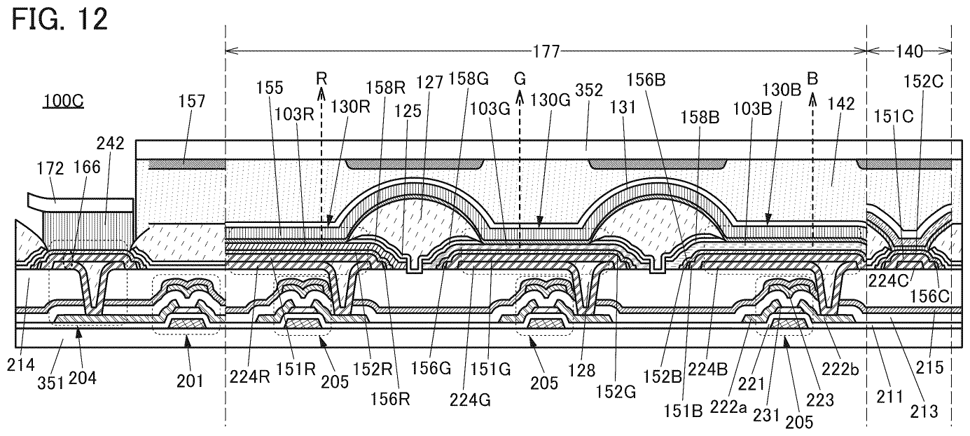

FIG. 11 is a perspective view of the display device 100B, and FIG. 12 is a cross-sectional view of the display device 100C.

In the display device 100B, a substrate 352 and a substrate 351 are bonded to each other. In FIG. 11, the substrate 352 is denoted by a dashed line.

The display device 100B includes the pixel portion 177, the connection portion 140, a circuit 356, a wiring 355, and the like. FIG. 11 illustrates an example where an IC 354 and an FPC 353 are mounted on the display device 100B. Thus, the structure illustrated in FIG. 11 can be regarded as a display module including the display device 100B, the IC (integrated circuit), and the FPC. Here, a display device in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 11 illustrates an example where the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display device 100B and the display module are not necessarily provided with an IC. Alternatively, the IC may be mounted on the FPC by a COF method, for example.

FIG. 12 illustrates an example of cross sections of part of a region including the FPC 353, part of the circuit 356, part of the pixel portion 177, part of the connection portion 140, and part of a region including an end portion of the display device 100C.

### [Display Device 100C]

The display device 100C illustrated in FIG. 12 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiment 1 can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through an opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151B, and 152B and the insulating layer 156B in the light-emitting device 130B.

The conductive layers 224R, 224G, and 224B each have a depressed portion covering the opening provided in the insulating layer 214. A layer 128 is embedded in the depressed portion.

The layer 128 has a function of filling the depressed portions of the conductive layers 224R, 224G, and 224B to obtain planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depressed portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting devices 130R, 130G, and 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 12, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided in a frame shape not to overlap with the light-emitting device. Furthermore, the space may be filled with a resin other than the frame-shaped adhesive layer 142.

FIG. 12 illustrates an example where the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and a conductive layer 152C obtained by processing the same conductive film as the conductive layers 152R, 152G, and 152B. In the example illustrated in FIG. 12, an insulating layer 156C is provided to include a region overlapping with the side surface of the conductive layer 151C.

The display device 100C has a top-emission structure. Light from the light-emitting device is emitted toward the substrate 352. For the substrate 352, a material with a high visible-light-transmitting property is preferably used. In the case where the light-emitting device emits infrared or near-infrared light, a material having a high transmitting property with respect to infrared or near-infrared light is preferably used. The first electrode (pixel electrode) contains a material that reflects visible light, and the second electrode (counter electrode) contains a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

An inorganic insulating film is preferably used as each of the insulating layers 211, 213, and 215.

An organic insulating layer is suitable as the insulating layer 214 functioning as a planarization layer.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 not overlapping with the substrate 352. In the connection portion 204, the wiring 355 is electrically connected to the FPC 353 through a conductive layer 166 and a connection layer 242. An example is described in which the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Device 100D]

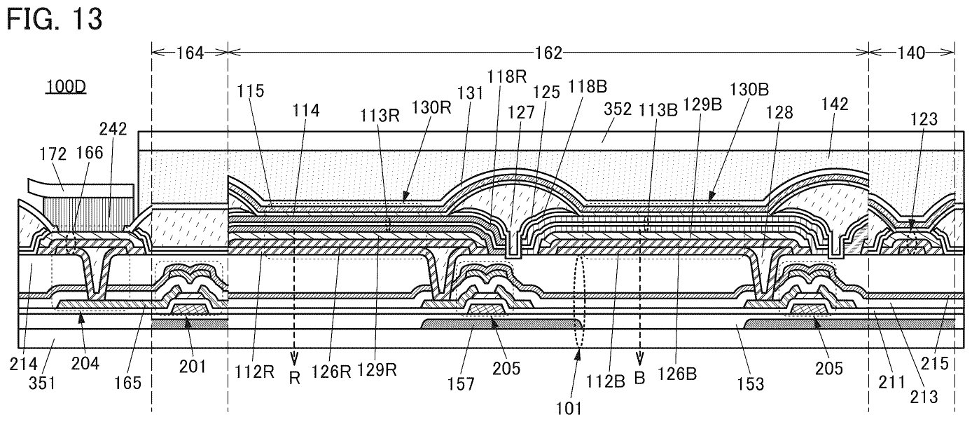

The display device 100D illustrated in FIG. 13 differs from the display device 100C illustrated in FIG. 12 mainly in having a bottom-emission structure.

Light from the light-emitting device is emitted toward the substrate 351. For the substrate 351, a material with a high visible-light-transmitting property is preferably used. By contrast, there is no limitation on the light-transmitting property of a material used for the substrate 352.

The light-blocking layer 157 is preferably formed between the substrate 351 and the transistor 201 and between the substrate 351 and the transistor 205. FIG. 13 illustrates an example where the light-blocking layer 157 is provided over the substrate 351, an insulating layer 153 is provided over the light-blocking layer 157, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material with a high visible-light-transmitting property is used for each of the conductive layers 112R, 112B, 126R, 126B, 129R, and 129B. A material that reflects visible light is preferably used for the second electrode.

Although not illustrated in FIG. 13, the light-emitting device 130G is also provided.

Although FIG. 13 and the like illustrate an example where the top surface of the layer 128 includes a flat portion, the shape of the layer 128 is not particularly limited.

### [Display Device 100E]

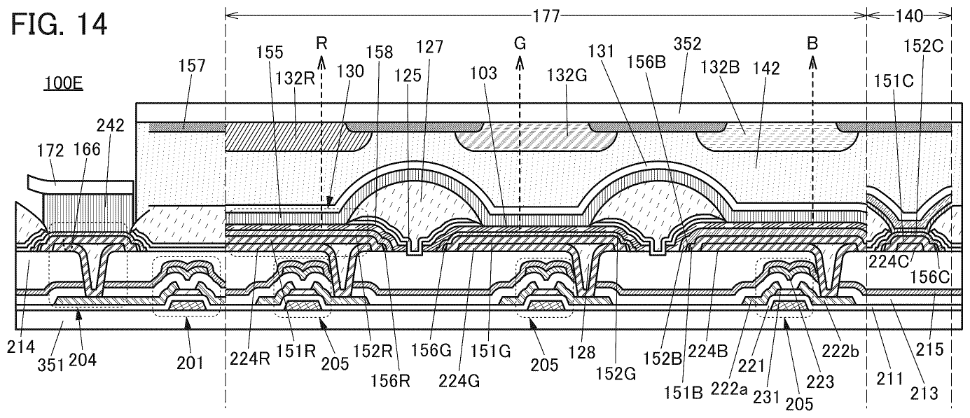

The display device 100E illustrated in FIG. 14 is a variation example of the display device 100C illustrated in FIG. 12 and differs from the display device 100C mainly in including the coloring layers 132R, 132G, and 132B.

In the display device 100E, the light-emitting device 130 includes a region overlapping with one of the coloring layers 132R, 132G, and 132B. The coloring layers 132R, 132G, and 132B can be provided on a surface of the substrate 352 on the substrate 351 side. End portions of the coloring layers 132R, 132G, and 132B can overlap with the light-blocking layer 157.

In the display device 100E, the light-emitting device 130 can emit white light, for example. The coloring layer 132R, the coloring layer 132G, and the coloring layer 132B can transmit red light, green light, and blue light, respectively, for example. Note that in the display device 100E, the coloring layers 132R, 132G, and 132B may be provided between the protective layer 131 and the adhesive layer 142.

Although FIG. 12, FIG. 14, and the like illustrate an example in which the top surface of the layer 128 includes a flat portion, the shape of the layer 128 is not particularly limited.

This embodiment can be combined as appropriate with the other embodiments or the examples. In this specification, in the case where a plurality of structure examples are shown in one embodiment, the structure examples can be combined as appropriate.

### Embodiment 5

In this embodiment, electronic appliances of embodiments of the present invention will be described.

Electronic appliances in this embodiment each include the display device of one embodiment of the present invention in a display portion. The display device of one embodiment of the present invention has low power consumption. Thus, the display device of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

In particular, the display device of one embodiment of the present invention has low power consumption, and thus can be suitably used for a relatively small electronic appliance. Examples of such an electronic appliance include watch-type and bracelet-type information terminals (wearable devices) and wearable devices capable of being worn on a head, such as a VR device like a head-mounted display, a glasses-type AR device, and an MR device.

The electronic appliance in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

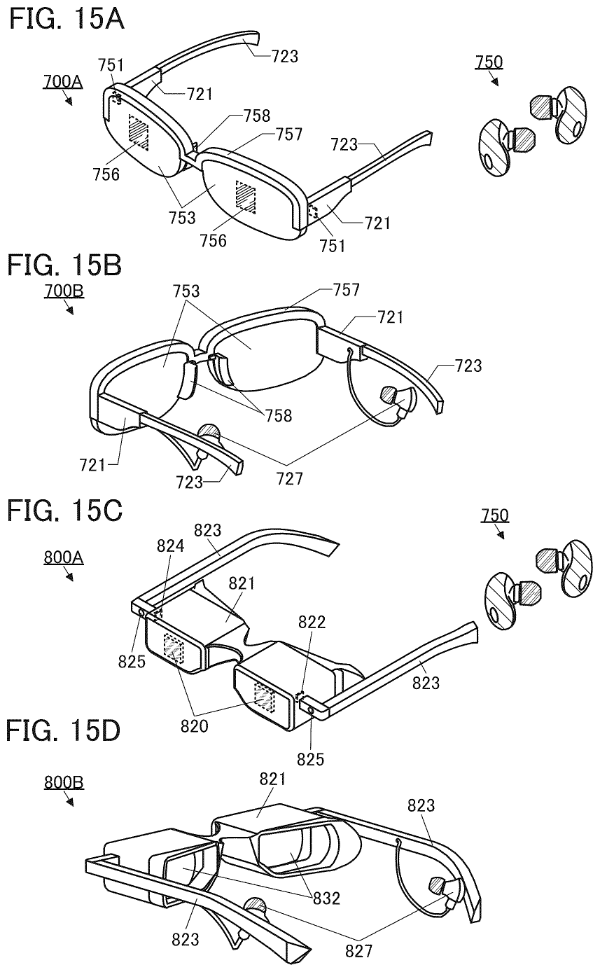

Examples of wearable devices capable of being worn on a head are described with reference to FIGS. 15A to 15D.

An electronic appliance 700A illustrated in FIG. 15A and an electronic appliance 700B illustrated in FIG. 15B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic appliance can have low power consumption and be driven for a long time.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic appliance 800A illustrated in FIG. 15C and an electronic appliance 800B illustrated in FIG. 15D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic appliance can have low power consumption and be driven for a long time.

The display portions 820 are positioned inside the housing 821 so as to be seen through the lenses 832. When the pair of display portions 820 display different images, three-dimensional display using parallax can be performed.

The electronic appliances 800A and 800B preferably include a mechanism for adjusting the lateral positions of the lenses 832 and the display portions 820 so that the lenses 832 and the display portions 820 are positioned optimally in accordance with the positions of the user's eyes.

The electronic appliance 800A or the electronic appliance 800B can be mounted on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

The electronic appliance 800A may include a vibration mechanism that functions as bone-conduction earphones.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750.

The electronic appliance may include an earphone portion. The electronic appliance 700B illustrated in FIG. 15B includes earphone portions 727. Part of a wiring that connects the earphone portion 727 and the control portion may be positioned inside the housing 721 or the wearing portion 723.

Similarly, the electronic appliance 800B illustrated in FIG. 15D includes earphone portions 827. For example, the earphone portion 827 can be connected to the control portion 824 by wire.

As described above, both the glasses-type device (e.g., the electronic appliances 700A and 700B) and the goggles-type device (e.g., the electronic appliances 800A and 800B) are preferable as the electronic appliance of one embodiment of the present invention.

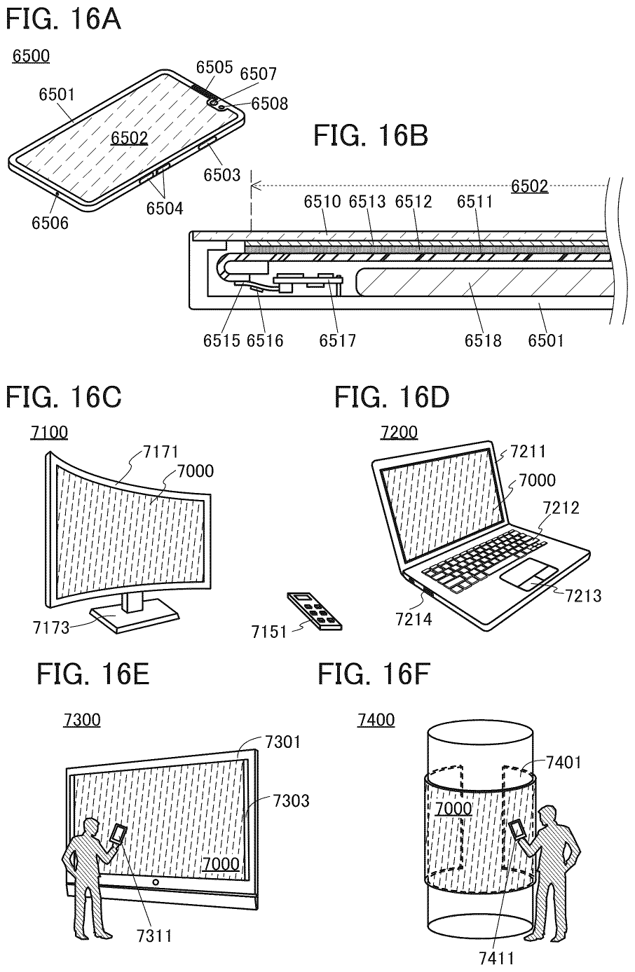

An electronic appliance 6500 illustrated in FIG. 16A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, the electronic appliance can have low power consumption and be driven for a long time.

FIG. 16B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with a bonding layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used in the display panel 6511. Thus, an extremely lightweight electronic appliance can be obtained. Since the display panel 6511 is extremely thin, the battery 6518 with high capacity can be mounted without an increase in the thickness of the electronic appliance. Moreover, part of the display panel 6511 is folded back so that a connection portion with the FPC 6515 is provided on the back side of the pixel portion, whereby an electronic appliance with a narrow bezel can be obtained.

FIG. 16C illustrates an example of a television device. In a television device 7100, a display portion 7000 is incorporated in a housing 7171. Here, the housing 7171 is supported by a stand 7173.

The display device of one embodiment of the present invention can be used in the display portion 7000. Thus, the electronic appliance can have low power consumption and be driven for a long time.

Operation of the television device 7100 illustrated in FIG. 16C can be performed with an operation switch provided in the housing 7171 and a separate remote control 7151.

FIG. 16D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000. Thus, the electronic appliance can have low power consumption and be driven for a long time.

FIGS. 16E and 16F illustrate examples of digital signage.

Digital signage 7300 illustrated in FIG. 16E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 16F illustrates digital signage 7400 attached to a cylindrical pillar 7401. The digital signage 7400 includes the display portion 7000 provided along a curved surface of the pillar 7401.

In FIGS. 16E and 16F, the display device of one embodiment of the present invention can be used in the display portion 7000. Thus, a highly reliable electronic appliance can be obtained.

A larger area of the display portion 7000 can increase the amount of information that can be provided at a time. The larger display portion 7000 attracts more attention, so that the effectiveness of the advertisement can be increased, for example.

As illustrated in FIGS. 16E and 16F, it is preferable that the digital signage 7300 or the digital signage 7400 can work with an information terminal 7311 or an information terminal 7411, such as a smartphone that a user has, through wireless communication.

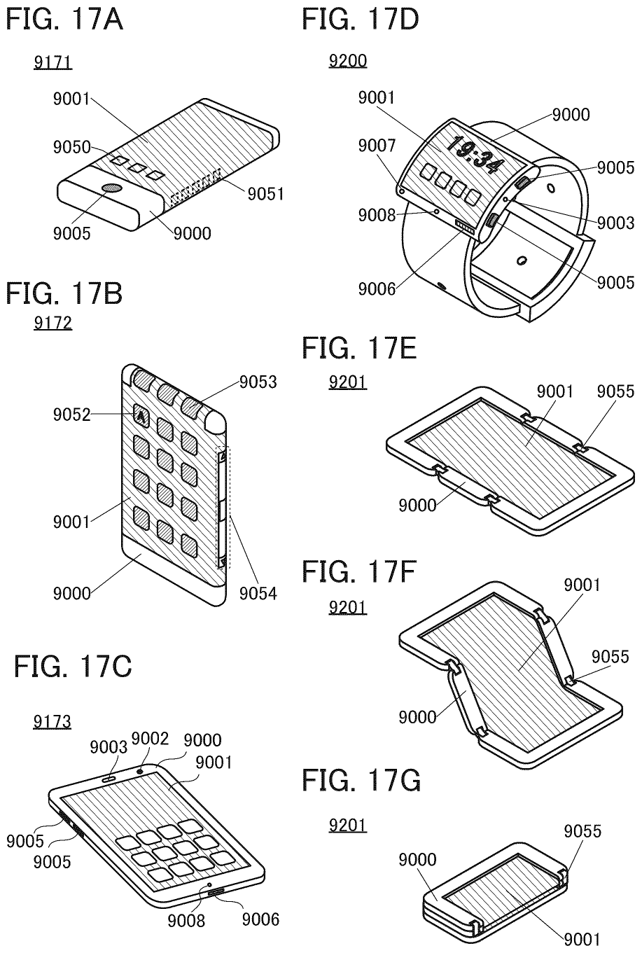

Electronic appliances illustrated in FIGS. 17A to 17G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIGS. 17A to 17G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with use of a variety of software (programs), a wireless communication function, and a function of reading out and processing a program or data stored in a recording medium.

The electronic appliances illustrated in FIGS. 17A to 17G are described in detail below.

FIG. 17A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 17A illustrates an example where three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 17B is a perspective view of a portable information terminal 9172. The portable information terminal 9172 has a function of displaying information on three or more surfaces of the display portion 9001. In the example illustrated here, information 9052, information 9053, and information 9054 are displayed on different surfaces. For example, the user of the portable information terminal 9172 can check the information 9053 displayed such that it can be seen from above the portable information terminal 9172, with the portable information terminal 9172 put in a breast pocket of his/her clothes.

FIG. 17C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 17D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 17E to 17G are perspective views of a foldable portable information terminal 9201. FIG. 17E is a perspective view illustrating the portable information terminal 9201 that is opened. FIG. 17G is a perspective view illustrating the portable information terminal 9201 that is folded. FIG. 17F is a perspective view illustrating the portable information terminal 9201 that is shifted from one of the states in FIGS. 17E and 17G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined as appropriate with the other embodiments or the examples. In this specification, in the case where a plurality of structure examples are shown in one embodiment, the structure examples can be combined as appropriate.

### Example 1

Described in this example are specific methods for fabricating light-emitting devices 1-1 and 1-2 and comparative light-emitting devices 1-1 to 1-3, and characteristics of the light-emitting devices. Structural formulae of main compounds used in this example are shown below.

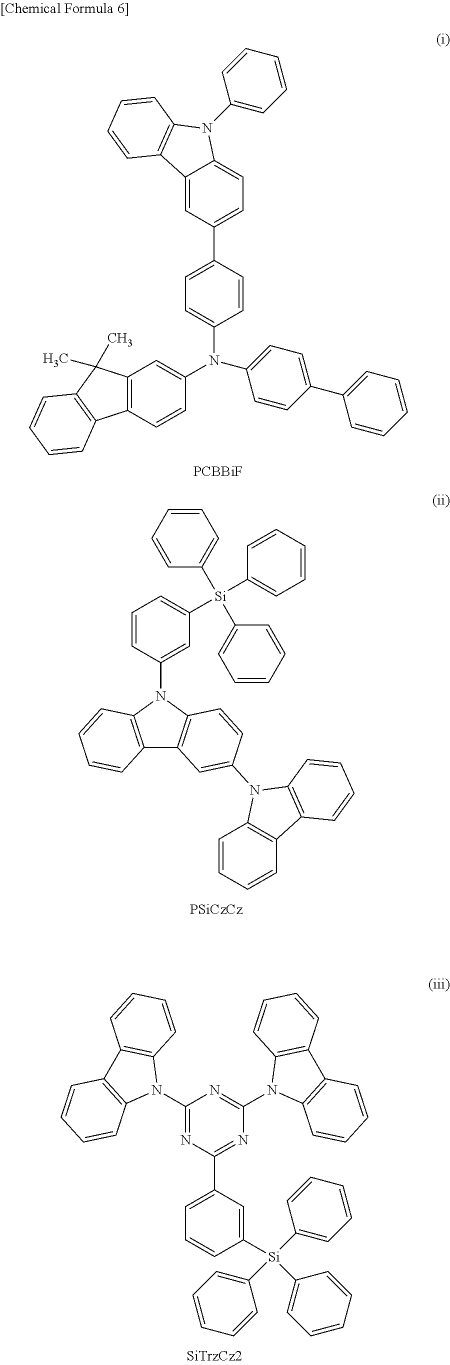

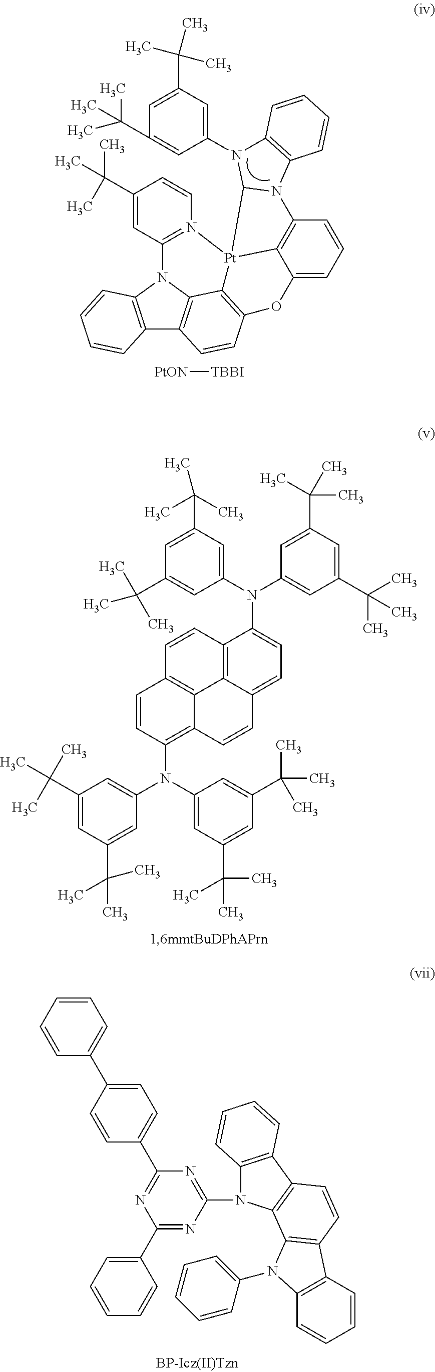

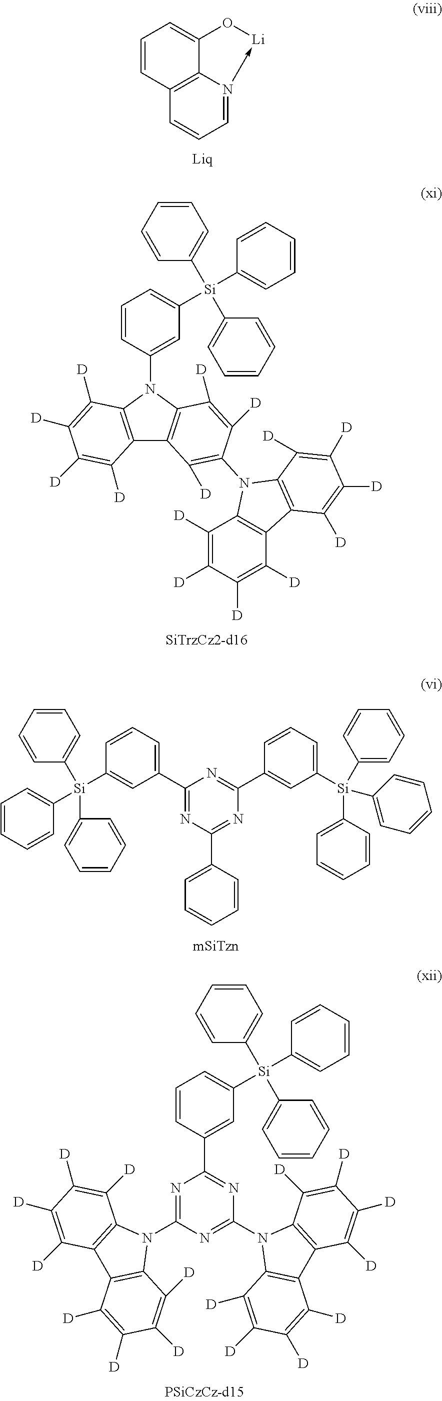

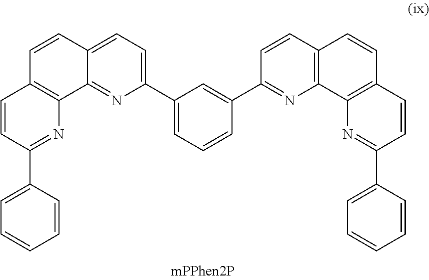 [SMILES: c1ccc(-c2ccc3ccc4ccc(-c5cccc(-c6ccc7ccc8ccc(-c9ccccc9)nc8c7n6)c5)nc4c3n2)cc1]

### (Method for Fabricating Light-Emitting Device 1-1)

First, indium tin oxide containing silicon oxide (ITSO) was deposited over a glass substrate to a thickness of 55 nm by a sputtering method, so that the first electrode 101 having a size of 2 mm×2 mm was formed. Note that the ITSO serves as an anode.

Next, as pretreatment for formation of the light-emitting device over the substrate, the substrate surface was washed with water.

Then, the substrate was transferred into a vacuum evaporation apparatus where the pressure was reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Next, the substrate was fixed to a holder provided in the vacuum evaporation apparatus such that the surface on which the first electrode 101 was formed faced downward. Over the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron acceptor material with a molecular weight of 672 (OCHD-003) were deposited by co-evaporation to a thickness of 10 nm at a weight ratio of PCBBiF to OCHD-003 of 1:0.03, so that the hole-injection layer 111 was formed.

Over the hole-injection layer 111, PCBBiF was deposited by evaporation to a thickness of 45 nm, and then 9-[3-(triphenylsilyl)phenyl]-3,9′-bi-9H-carbazole (abbreviation: PSiCzCz) represented by Structural Formula (ii) above was deposited by evaporation to a thickness of 5 nm, so that the hole-transport layer 112 was formed. Note that the PSiCzCz layer is an organic compound having a π-electron rich heteroaromatic ring and also functions as an electron-blocking layer.

Subsequently, over the hole-transport layer, 9,9′-{6-[3-(triphenylsilyl)phenyl]-1,3,5-triazine-2,4-diyl}bis(9H-carbazole) (abbreviation: SiTrzCz2) represented by Structural Formula (iii) above, PSiCzCz, (2-{3-[3-(3,5-di-tert-butylphenyl)benzimidazol-1-yl-2-ylidene-κC²]phenoxy-κC²}-9-(4-tert-butyl-2-pyridinyl-κN)carbazole-2,1-diyl-κC¹)platinum(II) (abbreviation: PtON-TBBI) represented by Structural Formula (iv) above, and N,N,N′,N′-tetrakis(3,5-di-tert-butylphenyl)pyrene-1,6-diamine (abbreviation: 1,6mmtBuDPhAPrn) represented by Structural Formula (v) above were deposited by co-evaporation to a thickness of 40 nm at a weight ratio of SiTrzCz2 to PSiCzCz to PtON-TBBI to 1,6mmtBuDPhAPrn of 0.35:0.53:0.12:0.015, so that the light-emitting layer 113 was formed.

Note that PtON-TBBI is an organometallic complex that exhibits blue phosphorescence, and 1,6mmtBuDPhAPrn is an organic compound that exhibits blue fluorescence. Furthermore, PtON-TBBI includes a tert-butyl group, which is an alkyl group having 4 carbon atoms. Furthermore, 1,6mmtBuDPhAPrn is an organic compound having a pyrene skeleton, which is a fused aromatic ring, as a luminophore and eight tert-butyl groups, which are each an alkyl group having 4 carbon atoms.

Note that SiTrzCz2 is an organic compound having a π-electron deficient heteroaromatic ring, and PSiCzCz is an organic compound having a π-electron rich heteroaromatic ring.

After that, 2-phenyl-4,6-bis[3-(triphenylsilyl)phenyl]-1,3,5-triazine (abbreviation: mSiTrz) represented by Structural Formula (vi) above was deposited by evaporation to a thickness of 5 nm to form a first electron-transport layer, and then 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn) represented by Structural Formula (vii) above and 8-quinolinolato-lithium (abbreviation: Liq) represented by Structural Formula (viii) above were deposited by co-evaporation to a thickness of 30 nm at a weight ratio of BP-Icz(II)Tzn to Liq of 1:4 to form a second electron-transport layer. Note that mSiTrz and BP-Icz(II)Tzn are each an organic compound having a π-electron deficient heteroaromatic ring, and Liq is an organometallic complex containing an alkali metal. The first electron-transport layer also functions as a hole-blocking layer.

After the electron-transport layers were formed, lithium fluoride (abbreviation: LiF) was deposited by evaporation to a thickness of 1 nm to form the electron-injection layer 115, and then aluminum (abbreviation: Al) was deposited by evaporation to a thickness of 200 nm to form the second electrode 102 (cathode).

Then, the light-emitting device was sealed using a glass substrate in a glove box including a nitrogen atmosphere so as not to be exposed to the air. Specifically, a UV curable sealing material was applied to surround the device, only the sealing material was irradiated with UV such that the light-emitting device was not irradiated with the UV, and heat treatment was performed at 80° C. under an atmospheric pressure for one hour. In this manner, the light-emitting device 1-1 was fabricated.

### (Method for Fabricating Light-Emitting Device 1-2)

The light-emitting device 1-2 was fabricated in a manner similar to that of the light-emitting device 1-1 except that SiTrzCz2 in the light-emitting layer of the light-emitting device 1-1 was replaced with 9,9′-{6-[3-(triphenylsilyl)phenyl]-1,3,5-triazine-2,4-diyl}bis(9H-carbazole-1,2,3,4,5,6,7,8,1′,2′,3′,4′,5′,6′,7′,8′-d₁₆) (abbreviation: SiTrzCz2-d16) represented by Structural Formula (xi) above and PSiCzCz was replaced with 9-[3-(triphenylsilyl)phenyl]-3,9′-(bi-9H-carbazole-d₁₅) (abbreviation: PSiCzCz-d15) represented by Structural Formula (xii) above.

### (Method for Fabricating Comparative Light-Emitting Device 1-1)

The comparative light-emitting device 1-1 was fabricated in a manner similar to that of the light-emitting device 1-1 except that the second electron-transport layer was formed of 2,2′-(1,3-phenylene)bis(9-phenyl-1,10-phenanthroline) (abbreviation: mPPhen2P) represented by Structural Formula (ix) above.

### (Method for Fabricating Comparative Light-Emitting Device 1-2)

The comparative light-emitting device 1-2 was fabricated in a manner similar to that of the comparative light-emitting device 1-1 except that the light-emitting layer was formed at a weight ratio of SiTrzCz2 to PSiCzCz to PtON-TBBI to 1,6mmtBuDPhAPrn of 0.35:0.53:0.12:0, that is, without using 1,6mmtBuDPhAPrn.

### (Method for Fabricating Comparative Light-Emitting Device 1-3)

The comparative light-emitting device 1-3 was fabricated in a manner similar to that of the light-emitting device 1-1 except that the light-emitting layer was formed at a weight ratio of SiTrzCz2 to PSiCzCz to PtON-TBBI to 1,6mmtBuDPhAPrn of 0.35:0.53:0.12:0, that is, without using 1,6mmtBuDPhAPrn.

Device structures of the light-emitting devices 1-1 and 1-2 and the comparative light-emitting devices 1-1, 1-2, and 1-3 are shown in the table below.

TABLE 3

| | | Thickness | Light-emitting devices | | Comparative light-emitting devices | | |
|---|---|---|---|---|---|---|---|
| | | (nm) | 1-1 | 1-2 | 1-1 | 1-2 | 1-3 |
| Second electrode | | 200 | Al | | | | |
| Electron- | | 1 | LiF | | | | |
| injection layer | | | | | | | |
| Electron- | 2 | 30 | BP-Icz(II)Tzn:Liq | | mPPhen2P | | BP-Icz(II)Tzn:Liq |
| transport | | | (1:4) | | | | (1:4) |
| layers | 1 | 5 | mSiTrz | | | | |
| Light-emitting | | 40 | *1:*2:PtON-TBBI:1,6mmtBuDPhAPrn | | | | |
| layer | | | (0.35:0.53:0.12:0.015) | | | (0.35:0.53:0.12:0) | |
| Hole- | 2 | 5 | PSiCzCz | | | | |
| transport | 1 | 45 | PCBBiF | | | | |
| layers | | | | | | | |

| Hole-injection | 10 | PCBBiF:OCHD-003 (1:0.03) |
|---|---|---|
| layer | | |

| | | |
|---|---|---|
| First electrode | 55 | ITSO |

Light-emitting device 1-1: *1 SiTrzCz2, *2 PSiCzCz
Light-emitting device 1-2: *1 SiTrzCz2-d16, *2 PSiCzCz-d15
Comparative light-emitting devices 1-1 to 1-3: *1 SiTrzCz2, *2 PSiCzCz

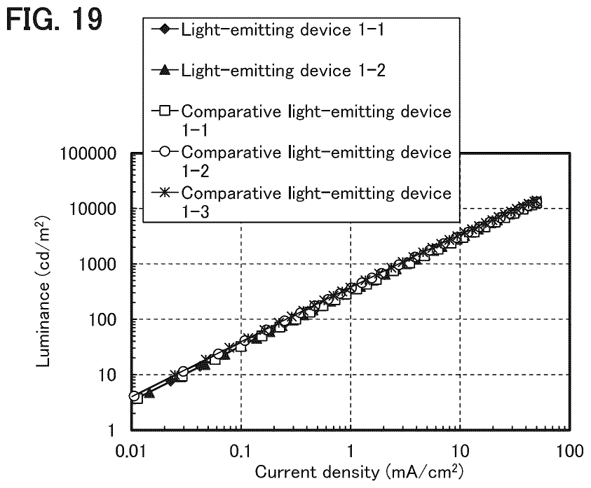

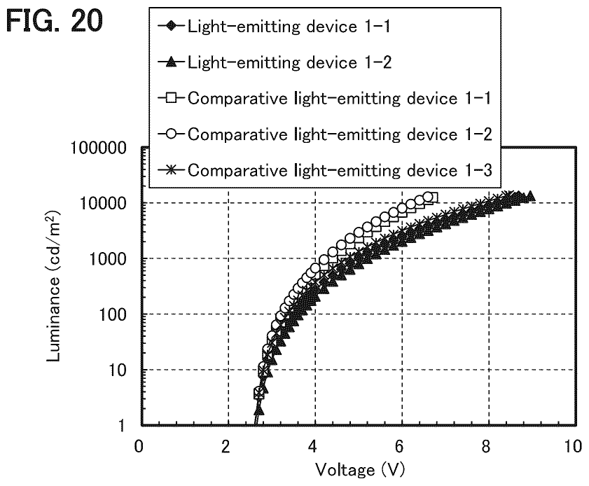

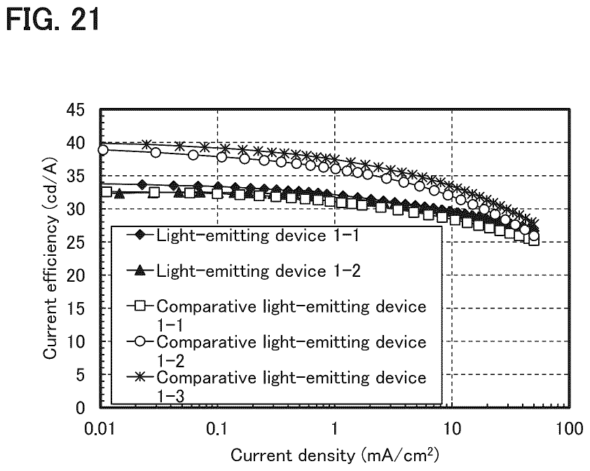

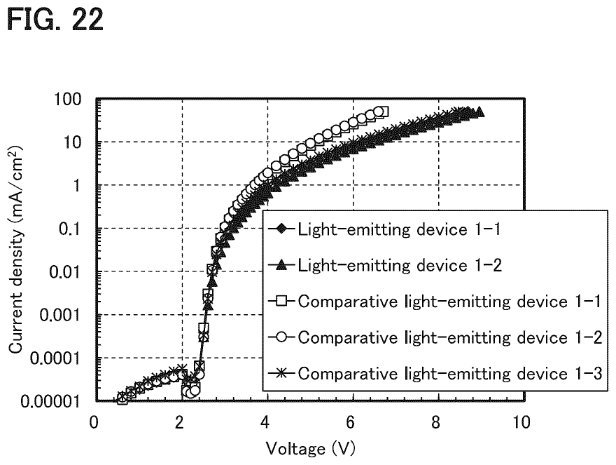

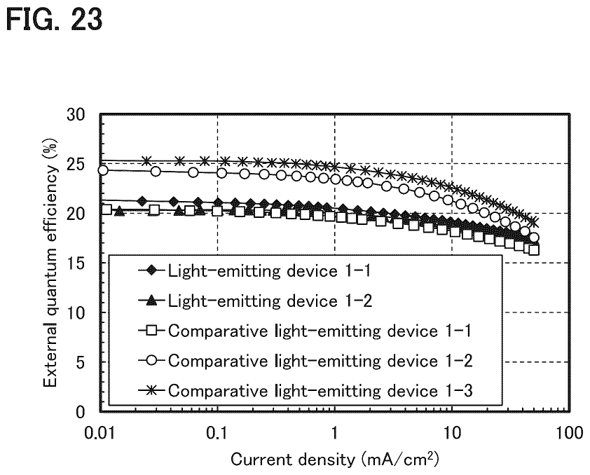

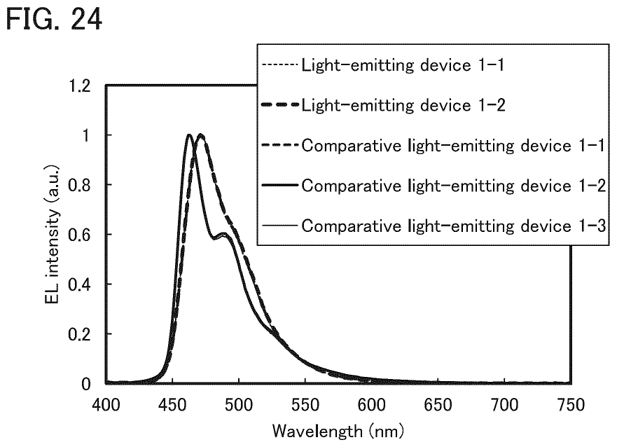

FIG. 19 shows the luminance-current density characteristics of the light-emitting devices 1-1 and 1-2 and the comparative light-emitting devices 1-1, 1-2, and 1-3. FIG. 20 shows the luminance-voltage characteristics thereof. FIG. 21 shows the current efficiency-current density characteristics thereof. FIG. 22 shows the current density-voltage characteristics thereof. FIG. 23 shows the external quantum efficiency-current density characteristics thereof. FIG. 24 shows the electroluminescence spectra thereof. Table 4 shows the main characteristics at a current density of 10 mA/cm². The luminance, CIE chromaticity, and electroluminescence spectra were measured at normal temperature with a spectroradiometer SR-UL1R (TOPCON TECHNOHOUSE). The external quantum efficiency was calculated from the measured luminance and emission spectrum, on the assumption that the light-emitting device had Lambertian light-distribution characteristics.

Note that the blue index (BI) is a value obtained by dividing current efficiency (cd/A) by they value of CIE chromaticity (x, y), and is one of the indicators of characteristics of blue light emission. As they chromaticity value of blue light emission becomes smaller, the color purity thereof tends to be higher. Blue light emission having a small y chromaticity value and high color purity enables expression of blue with a wide range of chromaticity on a display and reduces luminance of blue light emission necessary for a display to express white, leading to lower power consumption of the display. Thus, the BI, which is current efficiency based on they chromaticity value as one of the indicators of color purity of blue, is suitably used as a means for showing efficiency of blue light emission in some cases. The light-emitting device with a higher BI can be regarded as a blue-light-emitting device having higher efficiency for a display.

TABLE 4

| | | | | | | | | External |
|---|---|---|---|---|---|---|---|---|
| | | | | | Current | | Power | quantum |
| | Voltage | Luminance | Chromaticity | Chromaticity | efficiency | BI | efficiency | efficiency |
| | (V) | (cd/m²) | CIEx | CIEy | (cd/A) | (cd/A/CIEy) | (lm/W) | (%) |
| Light-emitting | 6.24 | 2957 | 0.129 | 0.234 | 29.6 | 126 | 14.9 | 19.1 |
| device 1-1 | | | | | | | | |
| Light-emitting | 6.48 | 2954 | 0.129 | 0.237 | 29.5 | 124 | 14.3 | 18.9 |
| device 1-2 | | | | | | | | |
| Comparative | 5.15 | 2841 | 0.129 | 0.237 | 28.4 | 120 | 17.4 | 18.2 |
| light-emitting | | | | | | | | |
| device 1-1 | | | | | | | | |
| Comparative | 5.06 | 3184 | 0.143 | 0.209 | 31.9 | 153 | 19.8 | 21.2 |
| light-emitting | | | | | | | | |
| device 1-2 | | | | | | | | |
| Comparative | 6.07 | 3336 | 0.142 | 0.205 | 33.4 | 163 | 17.3 | 22.6 |
| light-emitting | | | | | | | | |
| device 1-3 | | | | | | | | |

According to FIG. 24, the electroluminescence spectra of the light-emitting devices 1-1 and 1-2 and the comparative light-emitting device 1-1 each have a peak wavelength at 471 nm and a full width at half maximum of 47 nm. The electroluminescence spectra of the comparative light-emitting devices 1-2 and 1-3 each have a peak wavelength at 463 nm and a full width at half maximum of 45 nm. The emission spectra of the light-emitting devices 1-1 and 1-2 and the comparative light-emitting device 1-1 are different from those of the comparative light-emitting devices 1-2 and 1-3. In the light-emitting devices 1-1 and 1-2 and the comparative light-emitting device 1-1, 1,6mmtBuDPhAPrn, which is a fluorescent substance, emits light.

As shown in FIG. 23, the light-emitting devices 1-1 and 1-2 and the comparative light-emitting device 1-1 each had a maximum external quantum efficiency exceeding 20% even though 1,6mmtBuDPhAPrn, which is a fluorescent substance, emits light as described above. Thus, when PtON-TBBI, which is a phosphorescent substance, serves as an energy donor in the light-emitting devices 1-1 and 1-2 and the comparative light-emitting device 1-1, the fluorescent devices were able to exhibit high external quantum efficiencies exceeding 20%.

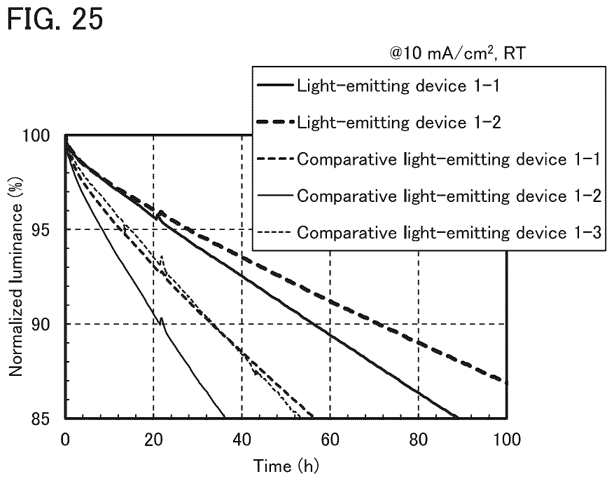

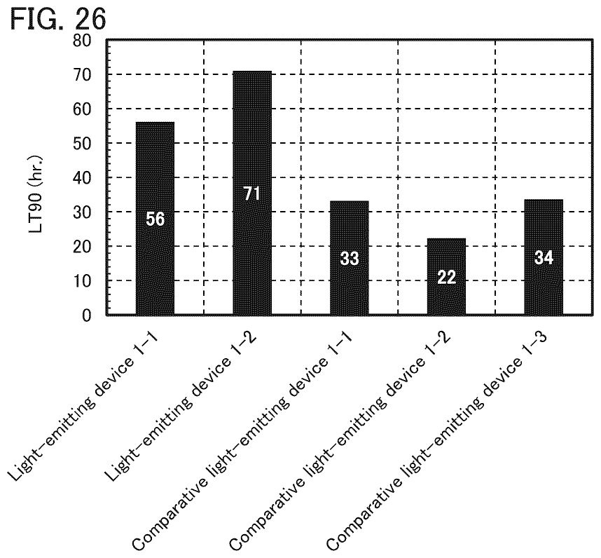

Next, FIG. 25 shows the time dependence of normalized luminance of the light-emitting devices 1-1 and 1-2 and the comparative light-emitting devices 1-1, 1-2, and 1-3 driven at a current density of 10 mA/cm², and FIG. 26 shows the time taken for the luminance of each of the light-emitting devices to decrease to 90% of the initial luminance (LT90) in the measurement. Note that the initial luminance is shown as 100% in the measurement of the time dependence of normalized luminance.

As shown in FIG. 25 and FIG. 26, the light-emitting device 1-1 of one embodiment of the present invention, which includes the second electron-transport layer with a high GSP_Slope and the light-emitting layer including both PtON-TBBI (phosphorescent substance) and 1,6mmtBuDPhAPrn (fluorescent substance), exhibited excellent LT90 that was approximately 1.7 times as long as that of the comparative light-emitting devices 1-1 and 1-3 and approximately 2.5 times as long as that of the comparative light-emitting device 1-2. The light-emitting device 1-2 exhibited excellent LT90 that was approximately 2.1 times as long as that of the comparative light-emitting devices 1-1 and 1-3 and approximately 3.2 times as long as that of the comparative light-emitting device 1-2.

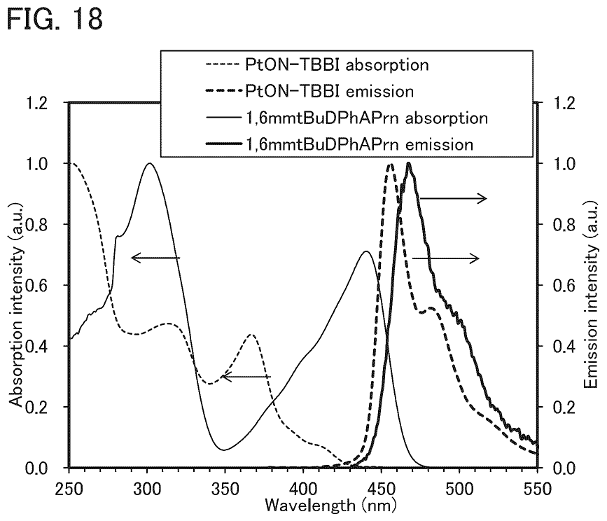

FIG. 18 shows measurement results of the emission spectra (PL spectra) and the absorption spectra of PtON-TBBI, which is a substance capable of converting triplet excitation energy into light emission, and 1,6mmtBuDPhAPrn, which is a fluorescent substance, in the fabricated light-emitting device 1 and the fabricated comparative light-emitting device 1-1. Note that the emission spectrum and the absorption spectrum of PtON-TBBI in a dichloromethane solution of PtON-TBBI were measured, respectively, with a spectrofluorometer (FP-8600DS, manufactured by JASCO Corporation) and an ultraviolet-visible spectrofluorometer (V-770DS, manufactured by JASCO Corporation). In addition, the emission spectrum and the absorption spectrum of 1,6mmtBuDPhAPrn in a toluene solution of 1,6mmtBuDPhAPrn were measured, respectively, with a fluorescence spectrophotometer (FS920, manufactured by Hamamatsu Photonics K.K.) and an ultraviolet-visible spectrofluorometer (V550DS, manufactured by JASCO Corporation).

As shown in FIG. 18, the peak wavelength (456 nm) of the emission spectrum of PtON-TBBI is shorter than the peak wavelength (467 nm) of the emission spectrum of 1,6mmtBuDPhAPrn. The absorption edge on the long wavelength side (465 nm) of the absorption spectrum of 1,6mmtBuDPhAPrn is positioned at a longer wavelength than the emission edge on the short wavelength side (441 nm) of the emission spectrum of PtON-TBBI. The absorption edge on the long wavelength side (465 nm) of the absorption spectrum of 1,6mmtBuDPhAPrn is positioned at a longer wavelength than the absorption edge on the long wavelength side (457 nm) of the absorption spectrum of PtON-TBBI.

The light-emitting device 1 and the comparative light-emitting device 1-1 having such a structure can have high emission efficiency even though the fluorescent substance emits light because energy can be efficiently transferred from PtON-TBBI, which is the substance capable of converting triplet excitation energy into light emission, to 1,6mmtBuDPhAPrn, which is the fluorescent substance, in the light-emitting layer.

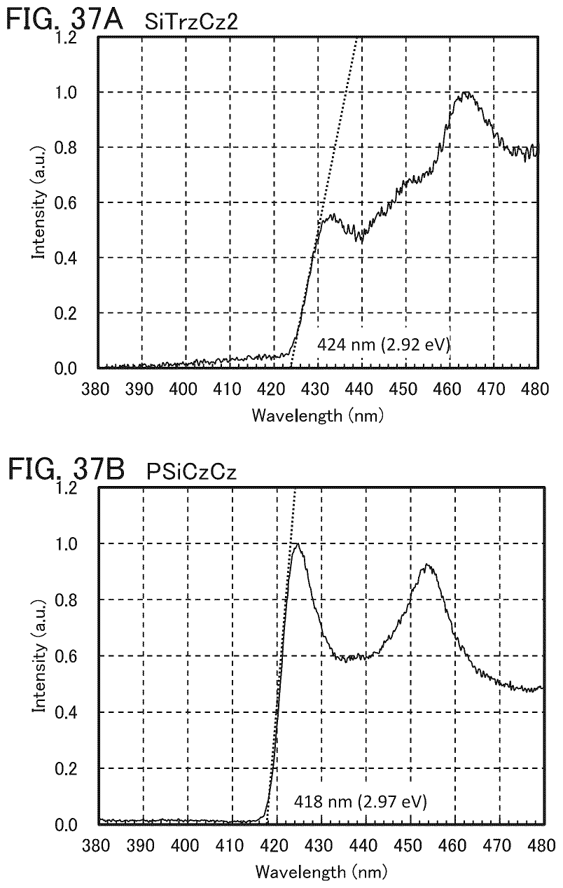

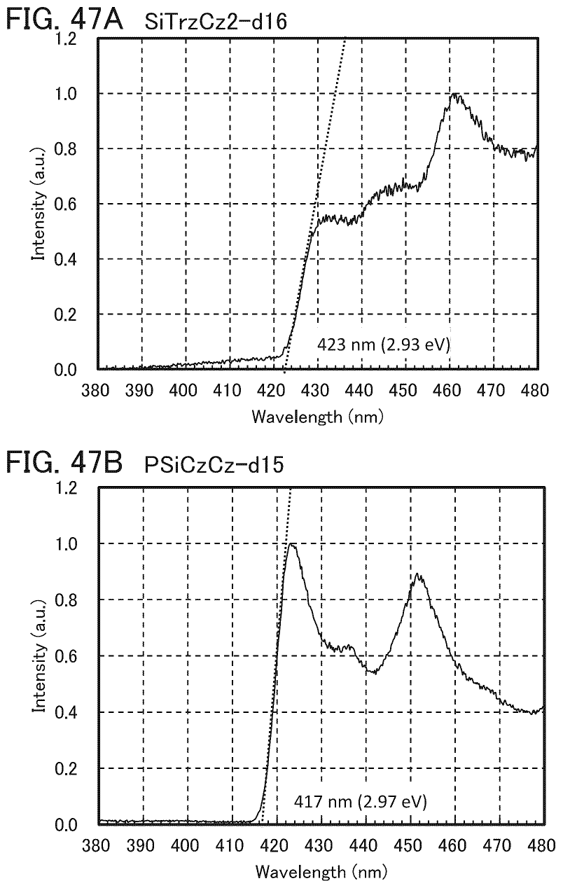

FIGS. 37A and 37B show the results of the low-temperature PL measurement of SiTrzCz2 and PSiCzCz, which are the host materials of the fabricated light-emitting devices, and FIGS. 47A and 47B show the results of the low-temperature PL measurement of SiTrzCz2-d16 and PSiCzCz-d15. The measurement was performed by using a PL microscope, LabRAM HR-PL (HORIBA, Ltd.), a He—Cd laser (wavelength: 325 nm) as excitation light, and a CCD detector at a measurement temperature of 10 K. Note that the measurement sample was a thin film deposited over a quartz substrate to a thickness of 50 nm, and the sample was subjected to measurement after another quartz substrate was attached to the quartz substrate from the deposited film's surface side in a nitrogen atmosphere.

As shown in FIG. 37A and FIG. 37B, since the wavelengths of the emission edges on the short wavelength side of the emission spectra (the emission edges on the short wavelength side of the phosphorescence spectra) of SiTrzCz2 and PSiCzCz in the low-temperature PL measurement are 424 nm and 418 nm, respectively, the T₁ levels of SiTrzCz2 and PSiCzCz are 2.92 eV and 2.97 eV, respectively. The energy difference is 0.05 eV. Note that when such materials are used as the host materials, since the energy difference between the T₁ levels of the host materials is lower than 0.20 eV, the light-emitting device fabricated in this example has a small deviation in triplet excitation energy between the host materials and thus has high reliability.

As shown in FIG. 47A and FIG. 47B, since the wavelengths of the emission edges on the short wavelength side of the emission spectra of SiTrzCz2-d16 and PSiCzCz-d15 in the low-temperature PL measurement are 423 nm and 417 nm, respectively, the T₁ levels of SiTrzCz2-d16 and PSiCzCz-d15 are 2.93 eV and 2.97 eV, respectively. The energy difference is 0.05 eV. Note that when such materials are used as the host materials, since the energy difference between the T₁ levels of the host materials is lower than 0.20 eV, the light-emitting device fabricated in this example has a small deviation in triplet excitation energy between the host materials and thus has high reliability. In the light-emitting device of this example, the deuterated materials are used as the host materials. When the host materials are deuterated materials, the reliability of the light-emitting device is improved. The improvement in reliability in the case of using deuterated host materials relates to an extension of the lifetime of triplet excitons of the host materials. The extension of the lifetime of triplet excitons is caused by inhibited non-radiative deactivation of the triplet excitation energy, which is due to inhibited vibration owing to deuteration. In that case, the energy difference between the T₁ levels of SiTrzCz2-d16 and PSiCzCz-d15 is preferably small, in which case uneven distribution of excitation energy in the compounds is less likely to occur and significant deterioration of either one of the compounds can be prevented; accordingly, the reliability of the light-emitting device is increased.

According to FIG. 18, the wavelength of the emission edge on the short wavelength side of the emission spectrum of PtON-TBBI is 441 nm, and the T₁ level of PtON-TBBI is estimated to be 2.81 eV. Since the T₁ levels of SiTrzCz2 and PSiCzCz, which are host materials, are respectively 2.92 eV and 2.97 eV as described above, the T₁ level of PtON-TBBI is lower than the T₁ levels of SiTrzCz2 and PSiCzCz. The light-emitting device 1-1 and the comparative light-emitting devices 1-1 to 1-3 fabricated in this example each having such a structure can have high emission efficiency and high reliability because energy can be efficiently transferred from the host materials to the substance capable of converting triplet excitation energy into light emission.

Furthermore, since the T₁ levels of SiTrzCz2-d16 and PSiCzCz-d15, which are host materials, are respectively 2.93 eV and 2.97 eV, the T₁ level of PtON-TBBI is lower than the T₁ levels of SiTrzCz2-d16 and PSiCzCz-d15. The light-emitting device 1-2 fabricated in this example having such a structure can have high emission efficiency and high reliability because energy can be efficiently transferred from the host materials to the substance capable of converting triplet excitation energy into light emission.

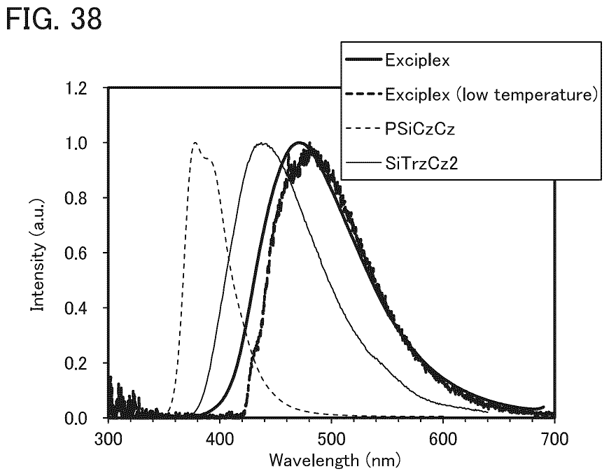

FIG. 38 shows emission spectra (PL spectra) of a single film of SiTrzCz2, a single film of PSiCzCz, and a mixed film of SiTrzCz2 and PSiCzCz at a weight ratio of 1:1. The PL spectra were measured with a spectrofluorometer (FP-8600DS, manufactured by JASCO Corporation). As shown in FIG. 38, the mixed film of SiTrzCz2 and PSiCzCz exhibits an emission spectrum shifted toward the long wavelength side, which is different from each of the emission spectra of the single films. This indicates that SiTrzCz2 and PSiCzCz form an exciplex in combination.

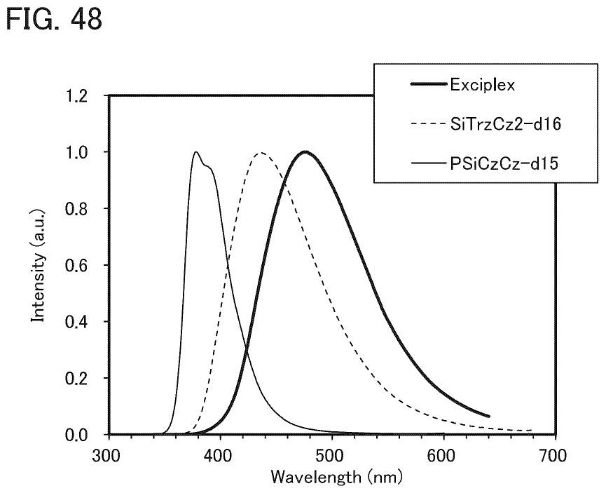

FIG. 48 shows emission spectra of a single film of SiTrzCz2-d16, a single film of PSiCzCz-d15, and a mixed film of SiTrzCz2-d16 and PSiCzCz-d15 at a weight ratio of 1:1. As shown in FIG. 48, the mixed film of SiTrzCz2-d16 and PSiCzCz-d15 exhibits an emission spectrum shifted toward the long wavelength side, which is different from each of the emission spectra of the single films. This indicates that SiTrzCz2-d16 and PSiCzCz-d15 form an exciplex in combination.

Table 5 shows the GSP_Slopes of vapor deposited films of an organic compound having a π-electron deficient heteroaromatic ring used in the first electron-transport layer, organic compounds having a π-electron deficient heteroaromatic ring used in the second electron-transport layer, organic compounds having a π-electron rich heteroaromatic ring or an aromatic amine used in the hole-transport layer, and host materials used in the light-emitting layer in the light-emitting devices 1-1 and 1-2 and the comparative light-emitting devices 1-1, 1-2, and 1-3. The GSP_Slopes in Table 5 were measured by the method described in Embodiment 1.

TABLE 5

| Abbreviation of material | GSP_Slope |
|---|---|
| of vapor-deposited film | (mV/nm) |
| mSiTrz | 10.3 |
| BP-Icz(II)Tzn | 92.1 |
| mPPhen2P | 1.50 |
| SiTrzCz2 | 22.4 |
| PSiCzCz | 34.7 |
| PCBBiF | 17.3 |

As shown above, in the comparative light-emitting devices 1-1 and 1-2, the GSP_Slope of the film of the organic compound having a π-electron deficient heteroaromatic ring included in the second electron-transport layer is smaller than the GSP_Slope of the film of the organic compound having a π-electron deficient heteroaromatic ring included in the first electron-transport layer. In this structure, electrons are favorably injected from the electrode or the electron-injection layer to the interface with the first electron-transport layer. Meanwhile, in the light-emitting devices 1-1 and 1-2 and the comparative light-emitting device 1-3, the GSP_Slope of the film of the organic compound having a π-electron deficient heteroaromatic ring included in the second electron-transport layer is larger than the GSP_Slope of the film of the organic compound having a π-electron deficient heteroaromatic ring included in the first electron-transport layer. This inhibits injection of electrons from the electrode or the electron-injection layer to the second electron-transport layer in the light-emitting devices 1 and the comparative light-emitting device 1-3.

In general, in a light-emitting layer containing a blue phosphorescent substance, the HOMO level and the LUMO level of the blue phosphorescent substance are respectively higher than the HOMO level and the LUMO level of a host material; thus, holes are trapped but electrons are not trapped and therefore the recombination region tends to be deviated toward the anode side in the light-emitting layer. When the recombination region is deviated toward the anode side, the density of excitons generated after the recombination also increases on the anode side in the light-emitting layer; thus, an interaction between excitons or an interaction between excitons and holes in the electron-blocking layer is likely to occur, so that excitons or holes with extremely high energy are likely to be generated. The high-energy excitons or holes promote deterioration of the light-emitting layer and the electron-blocking layer adjacent to the light-emitting layer.

In the light-emitting device of one embodiment of the present invention, electron injection is inhibited by the high GSP_Slope of the second electron-transport layer as described above; accordingly, the recombination region that tends to be deviated toward the anode side in the light-emitting layer can be extended toward the cathode side in the light-emitting layer, so that the deterioration of the hole-transport layer functioning as an electron-blocking layer can be inhibited. As a result, the comparative light-emitting device 1-3 has higher reliability than the comparative light-emitting device 1-2, and the light-emitting device 1 has higher reliability than the comparative light-emitting device 1-1.

In each of the light-emitting device 1-1 and the comparative light-emitting devices 1-1, 1-2, and 1-3 fabricated in this example, the HOMO level and the LUMO level of PSiCzCz used as the host material in the light-emitting layer are respectively −5.7 eV and −2.06 eV, the HOMO level of SiTrzCz2 used as the host material in the light-emitting layer is lower than that of PSiCzCz and the LUMO level of SiTrzCz2 is −2.98 eV, and the HOMO level and the LUMO level of PtON-TBBI added in a slight amount of (12 wt %) in the light-emitting layer as a blue phosphorescent substance are respectively −5.50 eV and −2.3 eV. Consequently, the HOMO level of PtON-TBBI is higher than those of the host materials and this structure facilitates trap of holes.

In the light-emitting device 1-2, the HOMO level and the LUMO level of PSiCzCz-d16 used as the host material in the light-emitting layer are respectively −5.7 eV and −2.05 eV, the HOMO level of SiTrzCz2-d16 used as the host material in the light-emitting layer is lower than that of PSiCzCz-d16 and the LUMO level of SiTrzCz2-d16 is −2.98 eV, and the HOMO level and the LUMO level of PtON-TBBI added in a slight amount (12 wt %) in the light-emitting layer as a blue phosphorescent substance are respectively −5.50 eV and −2.3 eV. Consequently, the HOMO level of PtON-TBBI is higher than those of the host materials and this structure facilitates trap of holes.

Note that the HOMO level of 1,6mmtBuDPhAPrn added in a slight amount (1.5 wt %) as a fluorescent substance in the light-emitting devices 1-1 and 1-2 and the comparative light-emitting device 1-1 is −5.30 eV; thus, 1,6mmtBuDPhAPrn is also likely to trap holes. Note that since the HOMO level of the fluorescent substance is higher than that of the phosphorescent substance and the addition amount of the fluorescent substance is smaller than that of the phosphorescent substance, the fluorescent substance in the light-emitting layer further traps holes which have been trapped by the phosphorescent substance. Thus, the light-emitting layer has a structure in which holes are highly likely to be trapped and the hole-transport property is likely to be low. Therefore, with the use of the structure of one embodiment of the present invention that inhibits electron injection, a reduction in reliability can be significantly inhibited and a light-emitting device with high reliability can be provided.

The values of the HOMO levels and the LUMO levels were obtained through a cyclic voltammetry (CV) measurement.

In the cyclic voltammetry (CV) measurement, the values (E) of the HOMO and LUMO levels were calculated on the basis of an oxidation peak potential (Eₚₐ) and a reduction peak potential (E_{pc}), which were obtained by changing the potential of a working electrode with respect to a reference electrode. In the measurement, a HOMO level and a LUMO level were obtained by potential scanning in the positive direction and potential scanning in the negative direction, respectively. The scanning speed in the measurement was 0.1 V/s.

Specifically, a standard oxidation-reduction potential (Eₒ) (=Eₚₐ+E_{pc})/2) was calculated from an oxidation peak potential (Eₚₐ) and a reduction peak potential (E_{pc}), which were obtained by the cyclic voltammogram of a material. Then, the standard oxidation-reduction potential (Eₒ) was subtracted from the potential energy (Eₓ) of the reference electrode with respect to a vacuum level, whereby each of the values (E) (=Eₓ−Eₒ) of HOMO and LUMO levels was obtained.

Note that the reversible oxidation-reduction wave is obtained in the above case; in the case where an irreversible oxidation-reduction wave is obtained, the HOMO level is calculated as follows: a value obtained by subtracting a predetermined value (0.1 eV) from an oxidation peak potential (Eₚₐ) is assumed to be a reduction peak potential (E_{pc}), and a standard oxidation-reduction potential (Eₒ) is calculated to one decimal place. To calculate the LUMO level, a value obtained by adding a predetermined value (0.1 eV) to a reduction peak potential (E_{pc}) was assumed to be an oxidation peak potential (Eₚₐ), and a standard oxidation-reduction potential (Eₒ) was calculated to one decimal place.

Here, the transient EL measurement results of the light-emitting device 1-1, the comparative light-emitting device 1-3, and the light-emitting device 1-3 are described. The light-emitting device 1-3 was fabricated using N,N,N′,N′-tetra(3-methylphenyl)pyrene-1,6-diamine (abbreviation: 1,6mMeDPhAPrn) represented by Structural Formula (xviii) below instead of 1,6mmtBuDPhAPrn used in the light-emitting device 1-1.

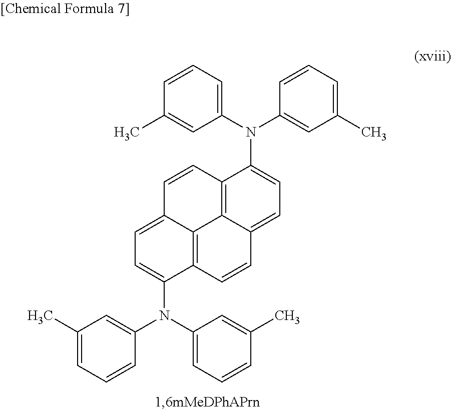

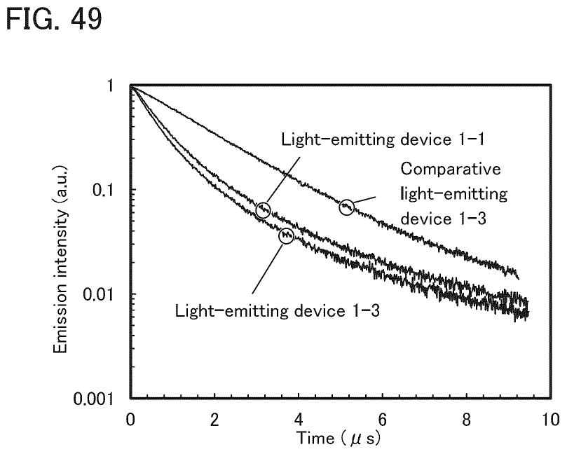

A picosecond fluorescence lifetime measurement system (manufactured by Hamamatsu Photonics K.K.) was used for the measurement. In the measurement, a square wave pulse voltage of 101.5 μs was applied to the light-emitting device, and time-resolved measurement of light emission, which started decaying from the falling of the voltage, was performed with a streak camera. The measurement was performed at room temperature (300 K) under the following conditions: a pulse voltage of around 6.8 V to 8.2 V was applied so that the luminance of the light-emitting device became close to 2500 cd/m², the pulse time width was 101.5 μsec, a negative bias voltage was −5 V (at the time when the element was not driven), and the measurement time was 10 μsec. FIG. 49 shows the measurement results. Note that in FIG. 49, the vertical axis represents intensity normalized by maximum emission intensity. The horizontal axis represents time elapsed after the falling of the pulse voltage.

In a decay curve shown in FIG. 49, the emission decay times of the light-emitting devices 1-1 and 1-3 were shorter than that of the comparative light-emitting device 1-3. Since the light-emitting devices 1-1 and 1-3 have a structure in which the fluorescent substance emits light, the emission decay time was able to be shortened.

As well as the light-emitting device 1-1, the light-emitting device 1-2 and the comparative light-emitting device 1-1 each have a structure in which the fluorescent substance emits light. A fluorescent substance has a higher emission rate constant and a shorter lifetime in an excited state than a phosphorescent substance and thus is highly stable to deterioration. Furthermore, the energy transfer rate at the time when excitation energy of the phosphorescent substance is transferred to the fluorescent substance exceeds the emission rate of the phosphorescent substance and the stability to deterioration is enhanced. Thus, the comparative light-emitting device 1-1 having a structure in which the fluorescent substance emits light has higher reliability than the comparative light-emitting device 1-2, and the light-emitting device 1-1 has higher reliability than the comparative light-emitting device 1-3. In the light-emitting devices 1-1, 1-2, and 1-3 and the comparative light-emitting device 1-1, energy transfer from the phosphorescent substance causes light emission of the fluorescent substance. In this case, the fluorescent substance has a protecting group particularly in the light-emitting devices 1-1 and 1-2 and the comparative light-emitting device 1-1; accordingly, energy transfer by the Dexter mechanism is inhibited and energy transfer by the Forster mechanism is dominant. Since transfer of triplet excitation energy from the T₁ level of the phosphorescent substance to the T₁ level of the fluorescent substance by the Dexter mechanism (non-radiative) is inhibited, a reduction in emission efficiency is inhibited. As a result, the light-emitting device has favorable characteristics with an external quantum efficiency exceeding 20% although the light-emitting device emits light from the fluorescent substance.

Here, in consideration of the results in FIG. 26 that LT90 of each of the comparative light-emitting devices 1-1 and 1-3 is approximately 1.5 times as long as that of the comparative light-emitting device 1-2, it can be estimated that an increase of the GSP_Slope of the second electron-transport layer or inclusion of the phosphorescent substance and the fluorescent substance in the light-emitting layer each improves LT90 by approximately 1.5 times. Meanwhile, LT90 of the light-emitting device 1-1 was approximately 1.7 times that of the comparative light-emitting device 1-1 or the comparative light-emitting device 1-3. This means that employing both the structure of increasing the GSP_Slope of the second electron-transport layer and the structure of including the phosphorescent substance and the fluorescent substance in the light-emitting layer further improves the reliability. Thus, it was found that the combination of these structures had synergistic effects.

Furthermore, the light-emitting device 1-2 using the deuterated materials as the host materials in the light-emitting layer was found to have higher reliability. A reason for this is that a compound including deuterium is more stabilized and less likely to deteriorate than a non-deuterated compound because the bond dissociation energy of a bond between carbon and deuterium is higher than the bond dissociation energy of a bond between carbon and protium and thus the bond between carbon and deuterium is stable and difficult to break.

In addition to the organic compound having a π-electron deficient heteroaromatic ring, Liq, which is a metal complex containing an alkali metal, is included in the second electron-transport layer in each of the light-emitting device 1-1, the light-emitting device 1-2, and the comparative light-emitting device 1-3. When the weight ratio of the organic compound having a π-electron deficient heteroaromatic ring to Liq in the second electron-transport layer is x:y, the value obtained by multiplying the GSP_Slope of the film of the organic compound having a π-electron deficient heteroaromatic ring included in the first electron-transport layer by (x+y)/x is 51.5 (mV/nm). That is, in the light-emitting device 1-1, the light-emitting device 1-2, and the comparative light-emitting device 1-3, the GSP_Slope of the film of the organic compound having a π-electron deficient heteroaromatic ring included in the second electron-transport layer is larger than the value obtained by multiplying the GSP_Slope of the film of the organic compound having a π-electron deficient heteroaromatic ring included in the first electron-transport layer by (x+y)/x.

As described above, when the weight ratio of the organic compound having a π-electron deficient heteroaromatic ring to Liq in the second electron-transport layer is x:y and the GSP_Slope of the film of the organic compound having a π-electron deficient heteroaromatic ring included in the second electron-transport layer is larger than the value obtained by multiplying the GSP_Slope of the film of the organic compound having a π-electron deficient heteroaromatic ring included in the first electron-transport layer by (x+y)/x, the light-emitting device can have high reliability.

Note that in the above-described light-emitting devices, the GSP_Slope of the film of the host materials (SiTrzCz2 and PSiCzCz) is larger than that of the film of the first organic compound. The GSP_Slope of the light-emitting layer is larger than that of the first electron-transport layer.

With this structure, positive interface charge can be provided at the interface between the light-emitting layer and the first electron-transport layer; thus, a barrier against electron injection from the second electron-transport layer to the first electron-transport layer is inhibited in the light-emitting device. Thus, the light-emitting device does not cause a significant increase in driving voltage even when electron injection to the second electron-transport layer is inhibited; accordingly, the light-emitting device can have favorable characteristics.

Furthermore, the film of BP-Icz(II)Tzn, which is the organic compound having a π-electron deficient heteroaromatic ring, included in the second electron-transport layer in each of the light-emitting devices 1-1 and 1-2 and the comparative light-emitting device 1-3 has a larger GSP_Slope than the film of the host materials (e.g., SiTrzCz2 and PSiCzCz). The GSP_Slope of the second electron-transport layer is larger than that of the light-emitting layer.

Accordingly, in the light-emitting devices 1-1 and 1-2 and the comparative light-emitting device 1-3, charge at the interface between the first electron-transport layer and the second electron-transport layer has a negative value and is smaller than the charge at the interface between the light-emitting layer and the first electron-transport layer. This effect causes an inhibition of electron injection from the second electrode or the electron-injection layer to the second electron-transport layer. In addition, hole injection to the light-emitting layer is promoted. Consequently, the recombination region that generally tends to be deviated toward the anode side in the light-emitting layer of the light-emitting device using a blue phosphorescent substance can be extended, so that a deterioration of the hole-transport layer functioning as an electron-blocking layer can be further reduced.

In the above-described light-emitting devices, the GSP_Slope of the light-emitting layer (the co-vapor deposited film of SiTrzCz2, PSiCzCz, PtON-TBBI, and 1,6mmtBuDPhAPrn or the co-vapor deposited film of SiTrzCz2-d15, PSiCzCz-d16, and PtON-TBBI) or the GSP_Slope of the film of the host materials (the co-vapor deposited film of SiTrzCz2 and PSiCzCz or the co-vapor deposited film of SiTrzCz2-d15 and PSiCzCz-d16) is larger than that of the hole-transport layer (the vapor deposited film of PCBBiF). Such a relation between the GSP_Slopes of the hole-transport layer and the light-emitting layer can set negative charge at at least any one of the interfaces existing between the hole-transport layer and the light-emitting layer. This facilitates hole injection from the anode or the hole-injection layer to the vicinity of the interface with the light-emitting layer, so that the light-emitting device can have a low driving voltage.

Thus, the light-emitting device of one embodiment of the present invention can have high reliability and favorable characteristics.

### Example 2

Described in this example are specific methods for fabricating a light-emitting device 2 and a comparative light-emitting device 2, and characteristics of the light-emitting devices. Structural formulae of main compounds used in this example are shown below.

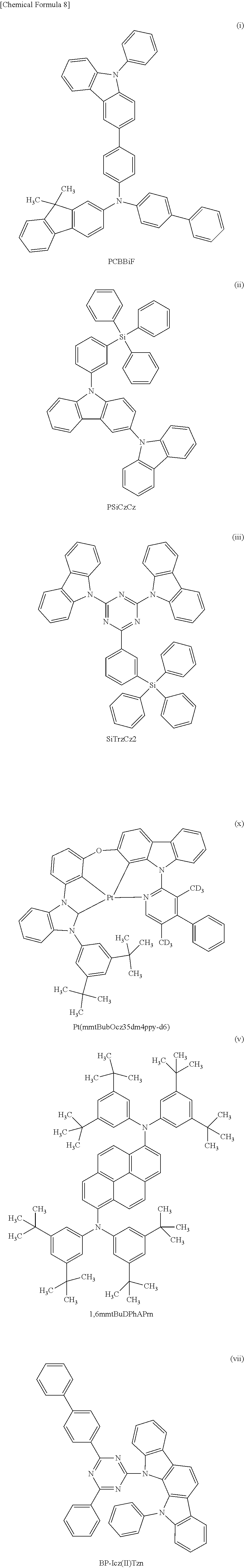

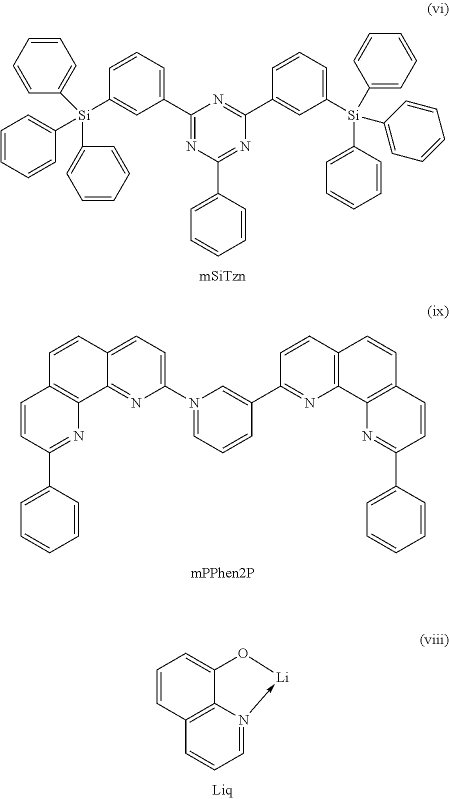

### (Method for Fabricating Light-Emitting Device 2)

First, a layer of indium tin oxide containing silicon oxide (ITSO) with a thickness of 55 nm was stacked over a glass substrate to by a sputtering method, so that the first electrode 101 having a size of 2 mm×2 mm was formed. Note that the ITSO serves as an anode.

Next, as pretreatment for formation of the light-emitting device over the substrate, the substrate surface was washed with water.

Then, the substrate was transferred into a vacuum evaporation apparatus where the pressure was reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Next, the substrate was fixed to a holder provided in the vacuum evaporation apparatus such that the surface on which the first electrode 101 was formed faced downward. Over the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron acceptor material with a molecular weight of 672 (OCHD-003) were deposited by co-evaporation to a thickness of 10 nm at a weight ratio of PCBBiF to OCHD-003 of 1:0.03, so that the hole-injection layer 111 was formed.

Over the hole-injection layer 111, PCBBiF was deposited by evaporation to a thickness of 45 nm, and then 9-[3-(triphenylsilyl)phenyl]-3,9′-bi-9H-carbazole (abbreviation: PSiCzCz) represented by Structural Formula (ii) above was deposited by evaporation to a thickness of 5 nm, so that the hole-transport layer 112 was formed. Note that the PSiCzCz layer is an organic compound having a π-electron rich heteroaromatic ring and also functions as an electron-blocking layer.

Subsequently, over the hole-transport layer, 9,9′-{6-[3-(triphenylsilyl)phenyl]-1,3,5-triazine-2,4-diyl}bis(9H-carbazole) (abbreviation: SiTrzCz2) represented by Structural Formula (iii) above, PSiCzCz, 2-{3-[3-(3,5-di-tert-butylphenyl)benzimidazol-1-yl-2-ylidene-κC²]phenoxy-κC²}-9-[3,5-di(methyl-d₃)-4-phenyl-2-pyridinyl-κN]carbazole-2,1-diyl-κC)platinum(II) (abbreviation: Pt(mmtBubOcz35dm4ppy-d₆)) represented by Structural Formula (x) above, and N,N,N′,N′-tetrakis(3,5-di-tert-butylphenyl)pyrene-1,6-diamine (abbreviation: 1,6mmtBuDPhAPrn) represented by Structural Formula (v) above were deposited by co-evaporation to a thickness of 40 nm at a weight ratio of SiTrzCz2 to PSiCzCz to Pt(mmtBubOcz35dm4ppy-d₆) to 1,6mmtBuDPhAPrn of 0.35:0.53:0.12:0.015, so that the light-emitting layer 113 was formed.

Note that Pt(mmtBubOcz35dm4ppy-d6) is an organometallic complex that exhibits blue phosphorescence, and 1,6mmtBuDPhAPrn is an organic compound that exhibits blue fluorescence. Furthermore, Pt(mmtBubOcz35dm4ppy-d6) includes a tert-butyl group, which is an alkyl group having 4 carbon atoms. Furthermore, 1,6mmtBuDPhAPrn is an organic compound having a pyrene skeleton, which is a fused aromatic ring, as a luminophore and eight tert-butyl groups, which are each an alkyl group having 4 carbon atoms.

Note that SiTrzCz2 is an organic compound having a π-electron deficient heteroaromatic ring, and PSiCzCz is an organic compound having a π-electron rich heteroaromatic ring.

After that, 2-phenyl-4,6-bis[3-(triphenylsilyl)phenyl]-1,3,5-triazine (abbreviation: mSiTrz) represented by Structural Formula (vi) above was deposited by evaporation to a thickness of 5 nm to form a first electron-transport layer, and then 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn) represented by Structural Formula (vii) above and 8-quinolinolato-lithium (abbreviation: Liq) represented by Structural Formula (viii) above were deposited by co-evaporation to a thickness of 30 nm at a weight ratio of BP-Icz(II)Tzn to Liq of 1:4 to form a second electron-transport layer. Note that mSiTrz and BP-Icz(II)Tzn are each an organic compound having a π-electron deficient heteroaromatic ring, and Liq is an organometallic complex containing an alkali metal. The first electron-transport layer also functions as a hole-blocking layer.

After the electron-transport layers were formed, lithium fluoride (abbreviation: LiF) was deposited by evaporation to a thickness of 1 nm to form the electron-injection layer 115, and then aluminum (abbreviation: Al) was deposited by evaporation to a thickness of 200 nm to form the second electrode 102 (cathode).

Then, the light-emitting device was sealed using a glass substrate in a glove box including a nitrogen atmosphere so as not to be exposed to the air. Specifically, a UV curable sealing material was applied to surround the device, only the sealing material was irradiated with UV such that the light-emitting device was not irradiated with the UV, and heat treatment was performed at 80° C. under an atmospheric pressure for one hour. In this manner, the light-emitting device 2 was fabricated.

### (Method for Fabricating Comparative Light-Emitting Device 2)

The comparative light-emitting device 2 was fabricated in a manner similar to that of the light-emitting device 2 except that the second electron-transport layer was formed of 2,2′-(1,3-phenylene)bis(9-phenyl-1,10-phenanthroline) (abbreviation: mPPhen2P) represented by Structural Formula (ix) above.

Device structures of the light-emitting device 2 and the comparative light-emitting device 2 are shown in the table below.

TABLE 6

| | | Thickness | Light-emitting | Comparative light- |
|---|---|---|---|---|
| | | (nm) | device 2 | emitting device 2 |
| Second | | 200 | Al | |
| electrode | | | | |
| Electron- | | 1 | LiF | |
| injection layer | | | | |
| Electron- | 2 | 30 | BP-Icz(II)Tzn:Liq (1:4) | mPPhen2P |
| transport | 1 | 5 | mSiTrz | |
| layers | | | | |
| Light-emitting | | 40 | SiTrzCz2:PSiCzCz:Pt(mmtBubOcz35dm4ppy-d₆):1,6mmtBuDPhAPrn | |
| layer | | | (0.35:0.53:0.12:0.015) | |
| Hole- | 2 | 5 | PSiCzCz | |
| transport | 1 | 45 | PCBBiF | |
| layers | | | | |

| Hole-injection | 10 | PCBBiF:OCHD-003 (1:0.03) |
|---|---|---|
| layer | | |

| | | |
|---|---|---|
| First electrode | 55 | ITSO |

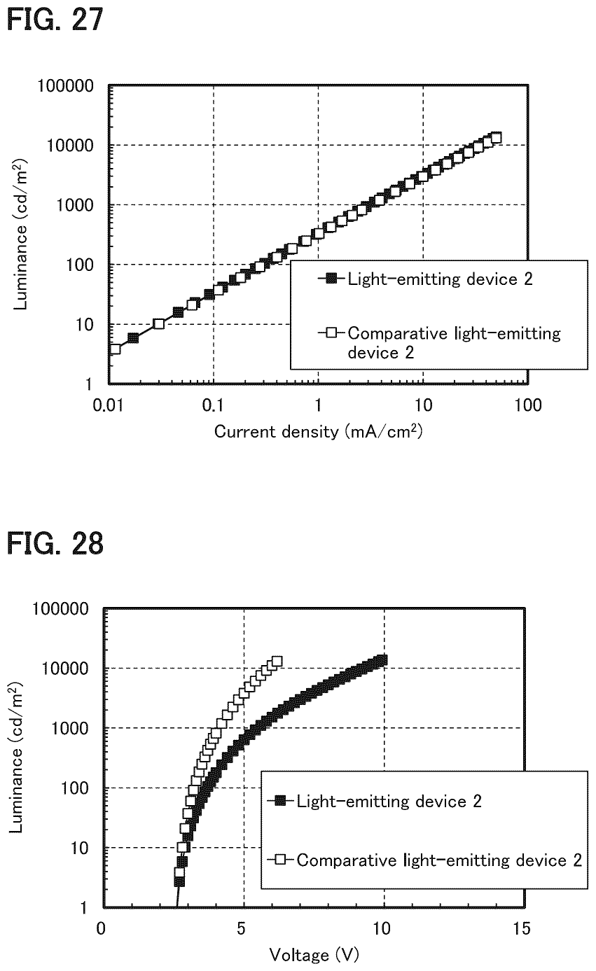

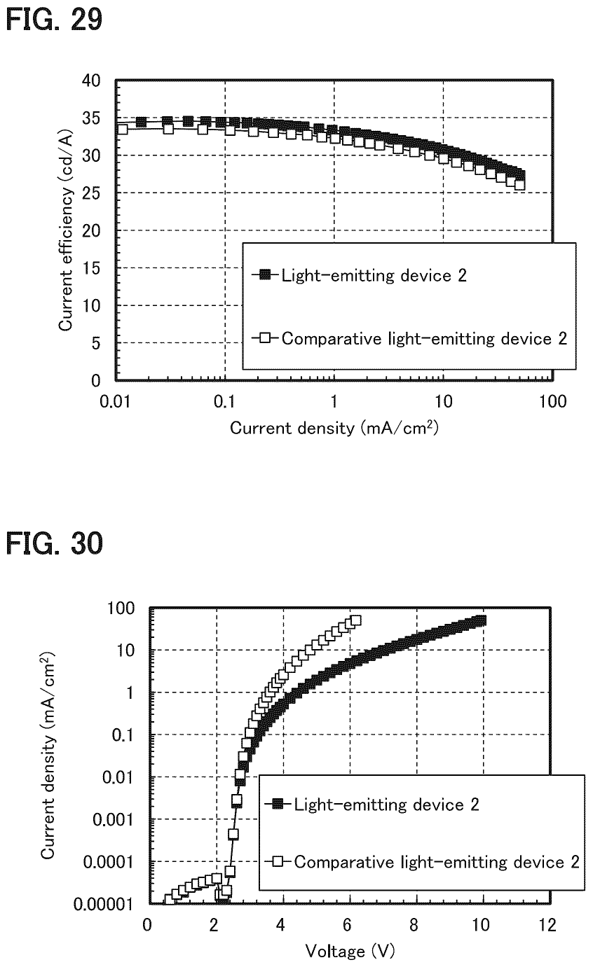

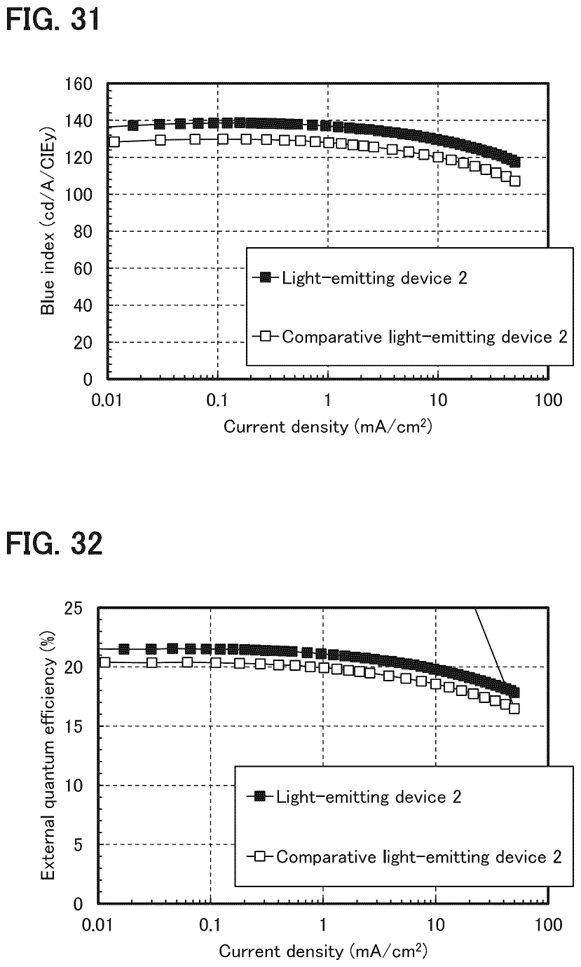

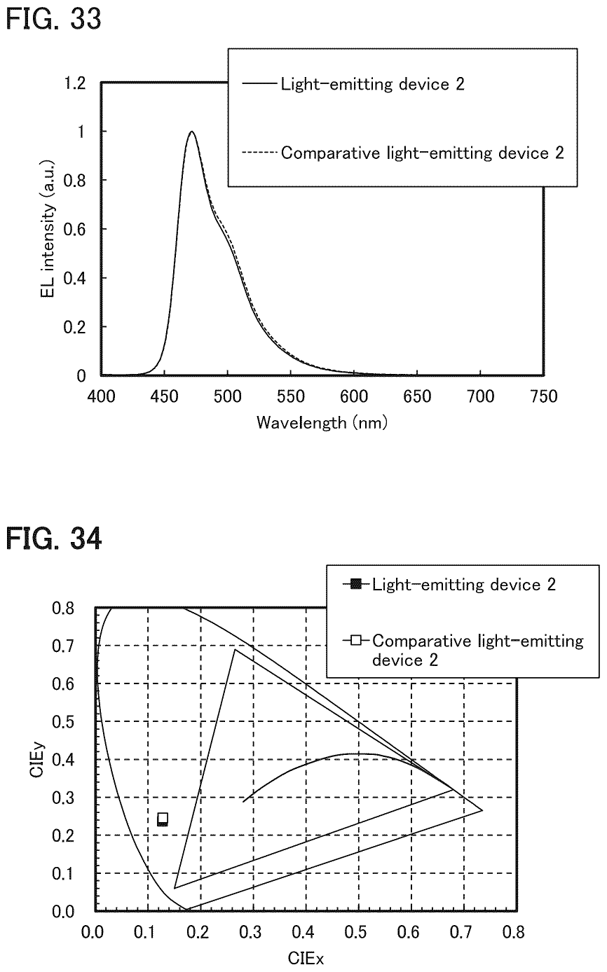

FIG. 27 shows the luminance-current density characteristics of the light-emitting device 2 and the comparative light-emitting device 2. FIG. 28 shows the luminance-voltage characteristics thereof. FIG. 29 shows the current efficiency-current density characteristics thereof. FIG. 30 shows the current density-voltage characteristics thereof. FIG. 31 shows the blue index-current density characteristics thereof. FIG. 32 shows the external quantum efficiency-current density characteristics thereof. FIG. 33 shows the electroluminescence spectra thereof. FIG. 34 and Table 7 respectively show a chromaticity diagram and the main characteristics at a current density of 10 mA/cm². The luminance, CIE chromaticity, and electroluminescence spectra were measured at normal temperature with a spectroradiometer SR-UL1R (TOPCON TECHNOHOUSE). The external quantum efficiency was calculated from the measured luminance and emission spectrum, on the assumption that the light-emitting device had Lambertian light-distribution characteristics.

TABLE 7

| | | | | | | | | External |
|---|---|---|---|---|---|---|---|---|
| | | | | | Current | | Power | quantum |
| | Voltage | Luminance | Chromaticity | Chromaticity | efficiency | BI | efficiency | efficiency |
| | (V) | (cd/m²) | CIEX | CIEy | (cd/A) | (cd/A/CIEy) | (lm/W) | (%) |
| Light-emitting | 7.05 | 3070 | 0.127 | 0.237 | 30.7 | 130 | 13.7 | 19.8 |
| device 2 | | | | | | | | |
| Comparative | 4.80 | 2955 | 0.128 | 0.246 | 29.6 | 120 | 19.3 | 18.5 |
| light-emitting | | | | | | | | |
| device 2 | | | | | | | | |

As shown in FIG. 32, the light-emitting device 2 and the comparative light-emitting device 2 each had an external quantum efficiency exceeding 20% even though 1,6mmtBuDPhAPrn, which is a fluorescent substance, emits light. Thus, when Pt(mmtBubOcz35dm4ppy-d₆), which is a phosphorescent substance, serves as an energy donor and 1,6mmtBuDPhAPrn, which is a fluorescent substance having a protecting group, emits light in the light-emitting device 2 and the comparative light-emitting device 2, the fluorescent devices were able to exhibit high external quantum efficiencies exceeding 20%.

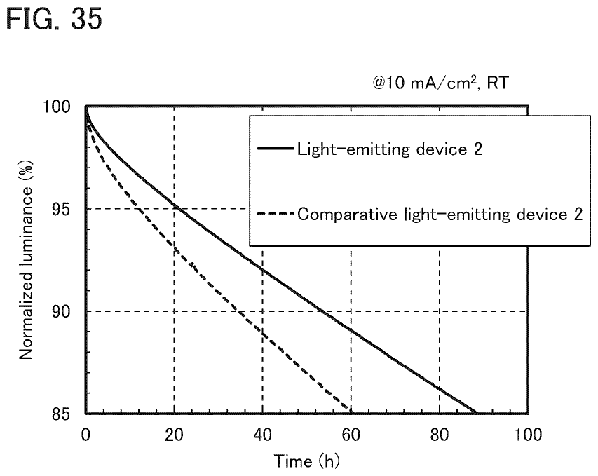

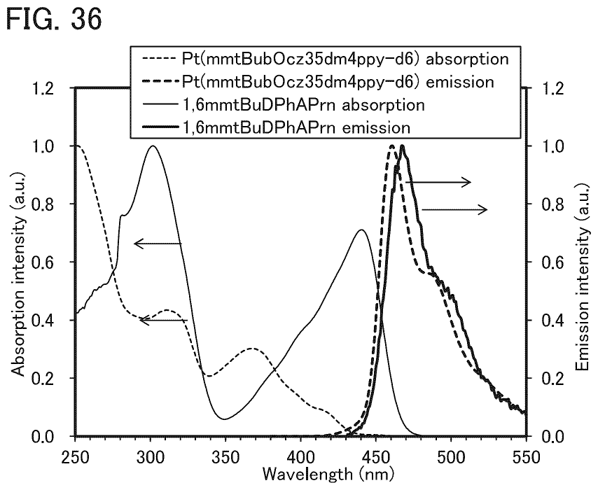

FIG. 35 shows the time dependence of normalized luminance of the light-emitting device 2 and the comparative light-emitting device 2 driven at 10 mA/cm². In this measurement, the time taken for the luminance to decrease to 90% of the initial luminance (LT90) was 54 hours for the light-emitting device 2 and 35 hours for the comparative light-emitting device 2. Note that the initial luminance is shown as 100% in the measurement of the time dependence of normalized luminance.

FIG. 36 shows measurement results of the emission spectra (PL spectra) and the absorption spectra of Pt(mmtBubOcz35dm4ppy-d₆), which is a substance capable of converting triplet excitation energy into light emission, and 1,6mmtBuDPhAPrn, which is a fluorescent substance, in the fabricated light-emitting device 2 and the fabricated comparative light-emitting device 2. Note that the emission spectrum and the absorption spectrum of Pt(mmtBubOcz35dm4ppy-d₆) in a dichloromethane solution of Pt(mmtBubOcz35dm4ppy-d₆) were measured, respectively, with a spectrofluorometer (FP-8600DS, manufactured by JASCO Corporation) and an ultraviolet-visible spectrofluorometer (V-770DS, manufactured by JASCO Corporation). In addition, the emission spectrum and the absorption spectrum of 1,6mmtBuDPhAPrn in a toluene solution of 1,6mmtBuDPhAPrn were measured, respectively, with a fluorescence spectrophotometer (FS920, manufactured by Hamamatsu Photonics K.K.) and an ultraviolet-visible spectrofluorometer (V550DS, manufactured by JASCO Corporation).

As shown in FIG. 36, the peak wavelength (461 nm) of the emission spectrum of Pt(mmtBubOcz35dm4ppy-d₆) is shorter than the peak wavelength (467 nm) of the emission spectrum of 1,6mmtBuDPhAPrn. The absorption edge on the long wavelength side (465 nm) of the absorption spectrum of 1,6mmtBuDPhAPrn is positioned at a longer wavelength than the emission edge on the short wavelength side (445 nm) of the emission spectrum of Pt(mmtBubOcz35dm4ppy-d₆). The absorption edge on the long wavelength side (465 nm) of the absorption spectrum of 1,6mmtBuDPhAPrn is positioned at a longer wavelength than the absorption edge on the long wavelength side (463 nm) of the absorption spectrum of Pt(mmtBubOcz35dm4ppy-d₆).

The light-emitting device 2 and the comparative light-emitting device 2 having such a structure can have high emission efficiency even though the fluorescent substance emits light because energy can be efficiently transferred from Pt(mmtBubOcz35dm4ppy-d₆), which is the substance capable of converting triplet excitation energy into light emission, to 1,6mmtBuDPhAPrn, which is the fluorescent substance, in the light-emitting layer.

FIGS. 37A and 37B show the results of the low-temperature PL measurement of SiTrzCz2 and PSiCzCz, which are the host materials of the fabricated light-emitting devices. The measurement was performed by using a PL microscope, LabRAM HR-PL (HORIBA, Ltd.), a He—Cd laser (wavelength: 325 nm) as excitation light, and a CCD detector at a measurement temperature of 10 K. Note that the measurement sample was a thin film formed over a quartz substrate to a thickness of 50 nm, and the sample was subjected to measurement after another quartz substrate was attached to the quartz substrate from the deposited film's surface side in a nitrogen atmosphere.

As shown in FIG. 37A and FIG. 37B, since the wavelengths of the emission edges on the short wavelength side of the emission spectra (the emission edges on the short wavelength side of the phosphorescence spectra) of SiTrzCz2 and PSiCzCz in the low-temperature PL measurement are 424 nm and 418 nm, respectively, the T₁ levels of SiTrzCz2 and PSiCzCz are 2.92 eV and 2.97 eV, respectively. The energy difference is 0.05 eV. Since the energy difference between the T₁ levels of the host materials is lower than 0.20 eV, the light-emitting device fabricated in this example has a small deviation in triplet excitation energy between the host materials and thus has high reliability.

According to FIG. 36, the wavelength of the emission edge on the short wavelength side of the emission spectrum of Pt(mmtBubOcz35dm4ppy-d₆) is 445 nm, and the T₁ level of Pt(mmtBubOcz35dm4ppy-d₆) is estimated to be 2.78 eV. Since the T₁ levels of SiTrzCz2 and PSiCzCz, which are host materials, are respectively 2.92 eV and 2.97 eV as described above, the T₁ level of Pt(mmtBubOcz35dm4ppy-d₆) is lower than the T₁ levels of SiTrzCz2 and PSiCzCz. The light-emitting device fabricated in this example having such a structure can have high emission efficiency and high reliability because energy can be efficiently transferred from the host materials to the substance capable of converting triplet excitation energy into light emission.

FIG. 38 shows emission spectra (PL spectra) of a single film of SiTrzCz2, a single film of PSiCzCz, and a mixed film of SiTrzCz2 and PSiCzCz at a weight ratio of 1:1. The PL spectra were measured with a spectrofluorometer (FP-8600DS, manufactured by JASCO Corporation). As shown in FIG. 38, the mixed film of SiTrzCz2 and PSiCzCz exhibits an emission spectrum shifted toward the long wavelength side, which is different from each of the emission spectra of the single films. This indicates that SiTrzCz2 and PSiCzCz form an exciplex in combination.

FIG. 35 shows that the light-emitting device 2 of one embodiment of the present invention, which includes the second electron-transport layer with a high GSP_Slope and the light-emitting layer including both Pt(mmtBubOcz35dm4ppy-d₆) (phosphorescent substance) and 1,6mmtBuDPhAPrn (fluorescent substance), has higher reliability than the comparative light-emitting device 2.

Here, Table 8 shows the GSP_Slopes of vapor deposited films of an organic compound having a π-electron deficient heteroaromatic ring used in the first electron-transport layer, organic compounds having a π-electron deficient heteroaromatic ring used in the second electron-transport layer, organic compounds having a π-electron rich heteroaromatic ring or an aromatic amine used in the hole-transport layer, and host materials used in the light-emitting layer in the light-emitting device 2 and the comparative light-emitting device 2. The GSP_Slopes in Table 8 were measured by the method described in Embodiment 1.

TABLE 8

| Abbreviation of material | GSP_Slope |
|---|---|
| of vapor-deposited film | (mV/nm) |
| mSiTrz | 10.3 |
| BP-Icz(II)Tzn | 92.1 |
| mPPhen2P | 1.50 |
| SiTrzCz2 | 22.4 |
| PSiCzCz | 34.7 |
| PCBBiF | 17.3 |

As shown above, in the comparative light-emitting device 2, the GSP_Slope of the film of the organic compound having a π-electron deficient heteroaromatic ring included in the second electron-transport layer is smaller than the GSP_Slope of the film of the organic compound having a π-electron deficient heteroaromatic ring included in the first electron-transport layer. In this structure, electrons are favorably injected from the electrode or the electron-injection layer to the interface with the first electron-transport layer. Meanwhile, in the light-emitting device 2, the GSP_Slope of the film of the organic compound having a π-electron deficient heteroaromatic ring included in the second electron-transport layer is larger than the GSP_Slope of the film of the organic compound having a π-electron deficient heteroaromatic ring included in the first electron-transport layer. This inhibits injection of electrons from the electrode or the electron-injection layer into the second electron-transport layer in the light-emitting device 2.

In general, in a light-emitting layer containing a blue phosphorescent substance, the HOMO level and the LUMO level of the blue phosphorescent substance are respectively higher than the HOMO level and the LUMO level of a host material; thus, holes are trapped but electrons are not trapped and therefore the recombination region tends to be deviated toward the anode side in the light-emitting layer. When the recombination region is deviated toward the anode side, the density of excitons generated after the recombination also increases on the anode side in the light-emitting layer; thus, an interaction between excitons or an interaction between excitons and holes in the electron-blocking layer is likely to occur, so that excitons or holes with extremely high energy are likely to be generated. The high-energy excitons or holes promote deterioration of the light-emitting layer and the electron-blocking layer adjacent to the light-emitting layer.

In the light-emitting device 2 of one embodiment of the present invention, electron injection is inhibited by the high GSP_Slope of the second electron-transport layer as described above; accordingly, the recombination region that tends to be deviated toward the anode side in the light-emitting layer can be extended toward the cathode side in the light-emitting layer, so that the deterioration of the hole-transport layer functioning as an electron-blocking layer can be inhibited. As a result, the light-emitting device 2 has higher reliability than the comparative light-emitting device 2.

Also in the light-emitting device fabricated in this example, the HOMO level and the LUMO level of PSiCzCz used as the host material in the light-emitting layer are respectively −5.7 eV and −2.06 eV, the HOMO level of SiTrzCz2 used as the host material in the light-emitting layer is lower than that of PSiCzCz and the LUMO level of SiTrzCz2 is −2.98 eV, and the HOMO level and the LUMO level of Pt(mmtBubOcz35dm4ppy-d₆) added in a slight amount (12 wt %) in the light-emitting layer as a blue phosphorescent substance are respectively −5.50 eV and −2.47 eV. This structure facilitates trap of holes. Note that the HOMO level of 1,6mmtBuDPhAPrn added in a slight amount (1.5 wt %) as a fluorescent substance in the light-emitting device 2 is −5.30 eV; thus, 1,6mmtBuDPhAPrn is also likely to trap holes like the phosphorescent substance. Note that since the HOMO level of the fluorescent substance is higher than that of the phosphorescent substance and the addition amount of the fluorescent substance is smaller than that of the phosphorescent substance, the fluorescent substance in the light-emitting layer further traps holes which have been trapped by the phosphorescent substance. Thus, the light-emitting layer has a structure in which holes are highly likely to be trapped and the hole-transport property is likely to be low.

The values of the HOMO levels and the LUMO levels were calculated in a manner similar to that in Example 1.

In addition to the organic compound having a π-electron deficient heteroaromatic ring, Liq, which is a metal complex containing an alkali metal, is included in the second electron-transport layer in the light-emitting device 2. When the weight ratio of the organic compound having a π-electron deficient heteroaromatic ring to Liq in the second electron-transport layer is x:y, the value obtained by multiplying the GSP_Slope of the film of the organic compound having a π-electron deficient heteroaromatic ring included in the first electron-transport layer by (x+y)/x is 51.5 (mV/nm). That is, in the light-emitting device 2, the GSP_Slope of the film of the organic compound having a π-electron deficient heteroaromatic ring included in the second electron-transport layer is larger than the value obtained by multiplying the GSP_Slope of the film of the organic compound having a π-electron deficient heteroaromatic ring included in the first electron-transport layer by (x+y)/x.

As described above, when the weight ratio of the organic compound having a π-electron deficient heteroaromatic ring to Liq in the second electron-transport layer is x:y and the GSP_Slope of the film of the organic compound having a π-electron deficient heteroaromatic ring included in the second electron-transport layer is larger than the value obtained by multiplying the GSP_Slope of the film of the organic compound having a π-electron deficient heteroaromatic ring included in the first electron-transport layer by (x+y)/x, the light-emitting device can have high reliability.

Note that in the light-emitting device 2 and the comparative light-emitting device 2, the GSP_Slope of the film of the host materials (SiTrzCz2 and PSiCzCz) is larger than that of the film of the first organic compound. The GSP_Slope of the light-emitting layer is larger than that of the first electron-transport layer.

With this structure, positive interface charge can be provided at the interface between the light-emitting layer and the first electron-transport layer; thus, a barrier against electron injection from the second electron-transport layer to the first electron-transport layer is inhibited in the light-emitting device. Thus, the light-emitting device 2 does not cause a significant increase in driving voltage even when electron injection to the second electron-transport layer is inhibited; accordingly, the light-emitting device can have favorable characteristics.

Furthermore, the film of BP-Icz(II)Tzn, which is the organic compound having a π-electron deficient heteroaromatic ring, included in the second electron-transport layer in the light-emitting device 2 has a larger GSP_Slope than the film of the host materials (SiTrzCz2 and PSiCzCz). The GSP_Slope of the second electron-transport layer is larger than that of the light-emitting layer.

Accordingly, in the light-emitting device 2, charge at the interface between the first electron-transport layer and the second electron-transport layer has a negative value and is smaller than the charge at the interface between the light-emitting layer and the first electron-transport layer. This effect causes an inhibition of electron injection from the second electrode or the electron-injection layer into the second electron-transport layer. In addition, the hole-injection property to the light-emitting layer is promoted. Consequently, the recombination region that generally tends to be deviated toward the anode side in the light-emitting layer of the light-emitting device using a blue phosphorescent substance can be extended, so that a deterioration of the hole-transport layer functioning as an electron-blocking layer can be further reduced.

In the above-described light-emitting device, the GSP_Slope of the light-emitting layer (the co-vapor deposited film of SiTrzCz2, PSiCzCz, Pt(mmtBubOcz35dm4ppy-d₆), and 1,6mmtBuDPhAPrn) or the GSP_Slope of the film of the host materials (the co-vapor deposited film of SiTrzCz2 and PSiCzCz) is larger than that of the hole-transport layer (the vapor deposited film of PCBBiF). Such a relation between the GSP_Slopes of the hole-transport layer and the light-emitting layer can set negative charge at at least any one of the interfaces existing between the hole-transport layer and the light-emitting layer. This facilitates hole injection from the anode or the hole-injection layer to the vicinity of the interface with the light-emitting layer, so that the light-emitting device can have a low driving voltage.

Thus, the light-emitting device of one embodiment of the present invention can have high reliability and favorable characteristics.

### Example 3

Described in this example are specific methods for fabricating a light-emitting device 3 and a comparative light-emitting device 3, and characteristics of the light-emitting devices. Structural formulae of main compounds used in this example are shown below.

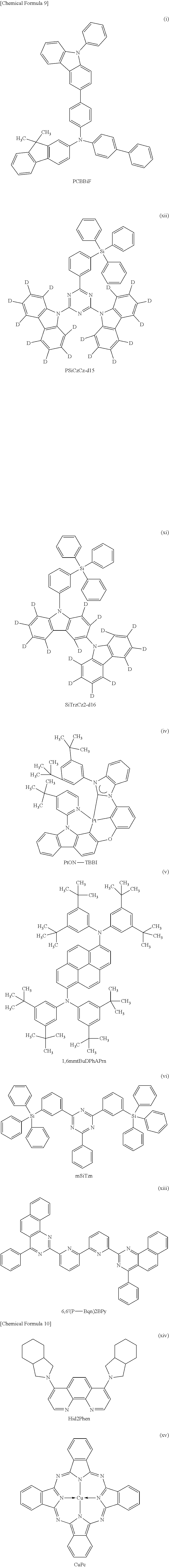

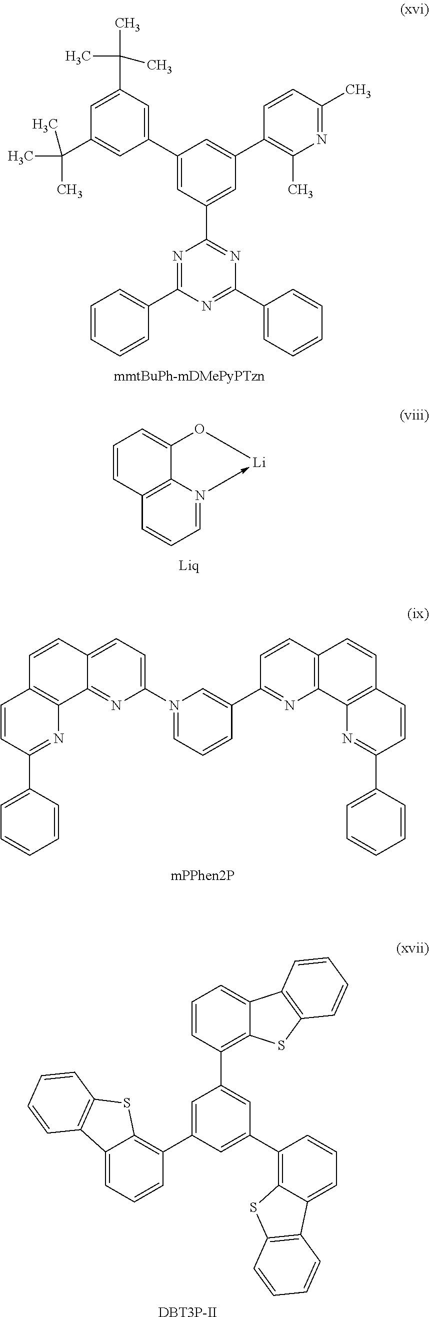

### (Method for Fabricating Light-Emitting Device 3)

First, 100-nm-thick silver (Ag) serving as a reflective electrode and 85-nm-thick indium tin oxide including silicon oxide (ITSO) serving as a transparent electrode were stacked sequentially over a glass substrate from the substrate side by a sputtering method, whereby the first electrode 101 with a size of 2 mm×2 mm was formed. Note that the transparent electrode functions as an anode, and the transparent electrode and the reflective electrode are collectively regarded as the first electrode 101.

Next, as pretreatment for formation of the light-emitting device over the substrate, the substrate surface was washed with water.

Then, the substrate was transferred into a vacuum evaporation apparatus where the pressure was reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Next, the substrate was fixed to a holder provided in the vacuum evaporation apparatus such that the surface on which the first electrode 101 was formed faced downward. Over the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron acceptor material with a molecular weight of 672 (OCHD-003) were deposited by co-evaporation to a thickness of 10 nm at a weight ratio of PCBBiF to OCHD-003 of 1:0.03, so that the hole-injection layer 111 was formed.

Over the hole-injection layer 111, PCBBiF was deposited by evaporation to a thickness of 40 nm, and then 9-[3-(triphenylsilyl)phenyl]-3,9′-(bi-9H-carbazole-dis) (abbreviation: PSiCzCz-d15) represented by Structural Formula (xii) above was deposited by evaporation to a thickness of 5 nm, so that the hole-transport layer of a first light-emitting unit was formed. Note that the PSiCzCz-d15 layer is an organic compound having a π-electron rich heteroaromatic ring and also functions as an electron-blocking layer.

Subsequently, over the hole-transport layer of the first light-emitting unit, 9,9′-{6-[3-(triphenylsilyl)phenyl]-1,3,5-triazine-2,4-diyl}bis(9H-carbazole-1,2,3,4,5,6,7,8,1′,2′,3′,4′,5′,6′,7′,8′-d₁₆) (abbreviation: SiTrzCz2-d16) represented by Structural Formula (xi) above, PSiCzCz-d15, (2-{3-[3-(3,5-di-tert-butylphenyl)benzimidazol-1-yl-2-ylidene-κC²]phenoxy-κC²}-9-(4-tert-butyl-2-pyridinyl-κN)carbazole-2,1-diyl-κC¹)platinum(II) (abbreviation: PtON-TBBI) represented by Structural Formula (iv) above, and N,N,N′,N′-tetrakis(3,5-di-tert-butylphenyl)pyrene-1,6-diamine (abbreviation: 1,6mmtBuDPhAPrn) represented by Structural Formula (v) above were deposited by co-evaporation to a thickness of 60 nm at a weight ratio of SiTrzCz2-d16 to PSiCzCz-d15 to PtON-TBBI to 1,6mmtBuDPhAPrn of 0.35:0.53:0.12:0.015, so that the light-emitting layer of the first light-emitting unit was formed.

Note that PtON-TBBI is an organometallic complex that exhibits blue phosphorescence, and 1,6mmtBuDPhAPrn is an organic compound that exhibits blue fluorescence. Furthermore, PtON-TBBI includes a tert-butyl group, which is an alkyl group having 4 carbon atoms. Furthermore, 1,6mmtBuDPhAPrn is an organic compound having a pyrene skeleton, which is a fused aromatic ring, as a luminophore and eight tert-butyl groups, which are each an alkyl group having 4 carbon atoms.

Note that SiTrzCz2-d16 is an organic compound having a π-electron deficient heteroaromatic ring, and PSiCzCz-d15 is an organic compound having a π-electron rich heteroaromatic ring.

Then, 2-phenyl-4,6-bis[3-(triphenylsilyl)phenyl]-1,3,5-triazine (abbreviation: mSiTrz) represented by Structural Formula (vi) above was deposited by evaporation to a thickness of 5 nm to form an electron-transport layer of the first light-emitting unit.

After the electron-transport layer of the first light-emitting unit was formed, 2,2′-([2,2′-bipyridine]-6,6′-diyl)bis(4-phenylbenzo[h]quinazoline) (abbreviation: 6,6′(P-Bqn)2BPy) represented by Structural Formula (xiii) above, 4,7-di(2,3,3a,4,5,6,7,7a-octahydro-1H-isoindol-2-yl)-1,10-phenanthroline (abbreviation: Hid2Phen) represented by Structural Formula (xiv) above, and lithium oxide (Li₂O) were deposited by co-evaporation to a thickness of 5 nm at a volume ratio of 6,6′(P-Bqn)2BPy to Hid2Phen to Li₂O of 0.5:0.5:0.02 to form a first layer. Then, copper phthalocyanine (abbreviation: CuPc) represented by Structural Formula (xv) above was deposited by evaporation to a thickness of 2 nm to form a third layer. Furthermore, PCBBiF and OCHD-003 were deposited by co-evaporation to a thickness of 10 nm at a weight ratio of PCBBiF to OCHD-003 of 1:0.15 to form a second layer. Thus, an intermediate layer was formed.

Over the intermediate layer, PCBBiF was deposited by evaporation to a thickness of 20 nm, and then PSiCzCz-d15 was deposited by evaporation to a thickness of 5 nm, whereby a hole-transport layer of a second light-emitting unit was formed. Note that the layer PSiCzCz-d15 also functions as an electron-blocking layer.

Then, over the hole-transport layer of the second light-emitting unit, SiTrzCz2-d16, PSiCzCz-d15, PtON-TBBI, and 1,6mmtBuDPhAPrn were deposited by co-evaporation to a thickness of 60 nm at a weight ratio of SiTrzCz2-d16 to PSiCzCz-d15 to PtON-TBBI to 1,6mmtBuDPhAPrn of 0.35:0.53:0.12:0.015, so that a light-emitting layer of the second light-emitting unit was formed.

After that, mSiTrz was deposited by evaporation to a thickness of 5 nm to form a first electron-transport layer of the second light-emitting unit, and then 2-{3-(2,6-dimethylpyridine-3-yl)-5-[(3,5-di-tert-butyl)phenyl]phenyl}-4,6-diphenyl-1,3,5-triazine (abbreviation: mmtBuPh-mDMePyPTzn) represented by Structural Formula (xvi) above and 8-quinolinolato-lithium (abbreviation: Liq) represented by Structural Formula (viii) above were deposited by co-evaporation to a thickness of 10 nm at a weight ratio of mmtBuPh-mDMePyPTzn to Liq of 1:4 to form a second electron-transport layer of the second light-emitting unit. Note that mSiTrz and mmtBuPh-mDMePyPTzn are each an organic compound having a π-electron deficient heteroaromatic ring, and Liq is an organometallic complex containing an alkali metal. The first electron-transport layer also functions as a hole-blocking layer.

After the formation of the electron-transport layers, lithium fluoride (abbreviation: LiF) and ytterbium (Yb) were deposited by co-evaporation to a thickness of 1.5 nm at a volume ratio of LiF to Yb of 2:1 to form an electron-injection layer. Subsequently, silver (Ag) and magnesium (Mg) were deposited by co-evaporation to a thickness of 15 nm at a volume ratio of Ag to Mg of 1:0.1 to form the second electrode 102 (cathode).

Next, 4,4′,4″-(benzene-1,3,5-triyl)tri(dibenzothiophene) (abbreviation: DBT3P-II) represented by Structural Formula (xvii) above was deposited by evaporation to a thickness of 70 nm to form a cap layer. Then, the light-emitting device was sealed using a glass substrate in a glove box including a nitrogen atmosphere so as not to be exposed to the air. Specifically, a UV curable sealing material was applied to surround the device, only the sealing material was irradiated with UV such that the light-emitting device was not irradiated with the UV, and heat treatment was performed at 80° C. under an atmospheric pressure for one hour. In this manner, the light-emitting device 3 was fabricated.

### (Method for Fabricating Comparative Light-Emitting Device 3)

The comparative light-emitting device 3 was fabricated in a manner similar to that of the light-emitting device 3 except that the second electron-transport layer was formed of 2,2′-(1,3-phenylene)bis(9-phenyl-1,10-phenanthroline) (abbreviation: mPPhen2P) represented by Structural Formula (ix) above.

Device structures of the light-emitting device 3 and the comparative light-emitting device 3 are shown in the table below.

TABLE 9

| | | Thickness | Light-emitting | Comparative light- |
|---|---|---|---|---|
| | | (nm) | device 3 | emitting device 3 |
| Cap layer | | 70 | DBT3P-II | |
| Second electrode | | 15 | Ag:Mg (1:0.1) | |
| | | 1.5 | LiF:Yb (1:0.5) | |
| Electron-transport | 2 | 10 | mmtBuPh-mDMePyPTzn:Liq | mPPhen2P |
| layers | | | (1:4) | |

| | 1 | 5 | mSiTrz |
|---|---|---|---|
| Light-emitting layer | | 60 | SiTrzCz2-d16:PSiCzCz-d15:PtON-TBBI:1,6mmtBuDPhAPrn |
| | | | (0.35:0.53:0.12:0.015) |
| Hole-transport | 2 | 5 | PSiCzCz-d15 |
| layers | 1 | 20 | PCBBiF |
| Intermediate | Second layer | 10 | PCBBiF:OCHD-003 |
| layers | | | (1:0.15) |
| | Third layer | 2 | CuPc |
| | First layer | 5 | 6,6′(P-Bqn)2BPy:Hid2Phen:Li₂O |
| | | | (0.5:0.5:0.02) |
| Electron-transport layer | | 5 | mSiTrz |
| Light-emitting layer | | 60 | SiTrzCz2-d16:PSiCzCz-d15:PtON-TBBI:1,6mmtBuDPhAPrn |
| | | | (0.35:0.53:0.12:0.015) |
| Hole-transport | 2 | 5 | PSiCzCz-d15 |
| layers | 1 | 40 | PCBBiF |

| Hole-injection layer | 10 | PCBBiF:OCHD-003 |
|---|---|---|
| | | (1:0.03) |
| First electrode | 85 | ITSO |
| | 100 | Ag |

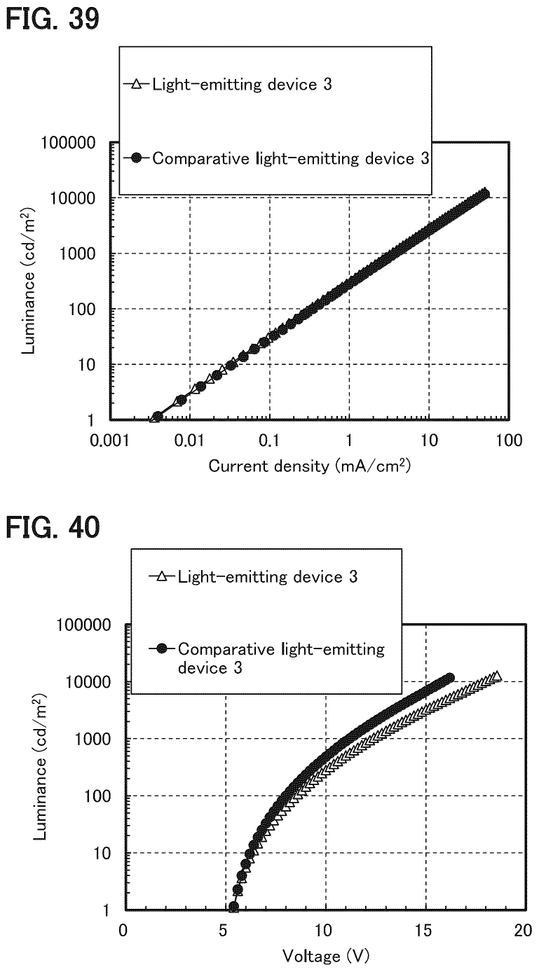

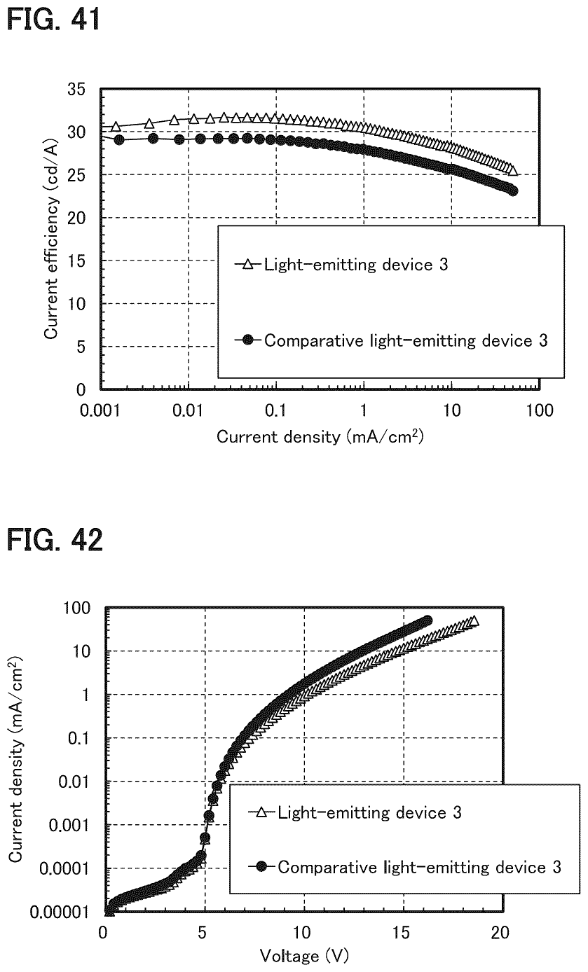

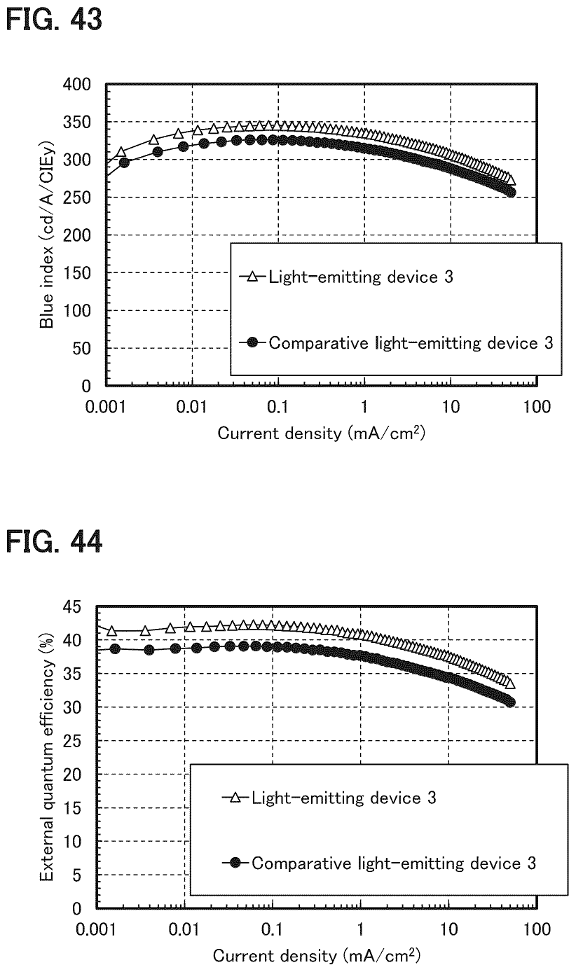

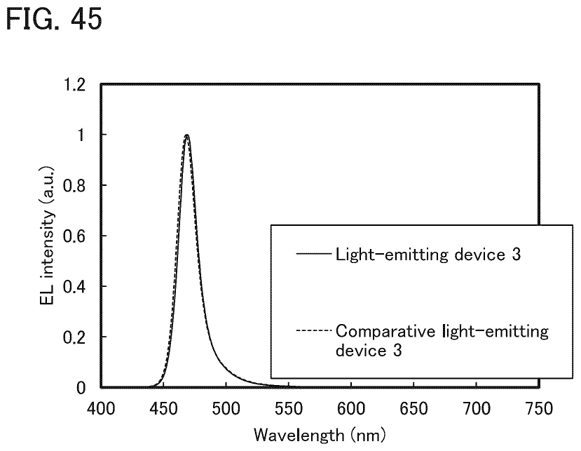

FIG. 39 shows the luminance-current density characteristics of the light-emitting device 3 and the comparative light-emitting device 3. FIG. 40 shows the luminance-voltage characteristics thereof. FIG. 41 shows the current efficiency-current density characteristics thereof. FIG. 42 shows the current density-voltage characteristics thereof. FIG. 43 shows the blue index-current density characteristics thereof. FIG. 44 shows the external quantum efficiency-current density characteristics thereof. FIG. 45 shows the electroluminescence spectra thereof. Table 10 shows the main characteristics at approximately 1000 cd/m². The luminance, CIE chromaticity, and electroluminescence spectra were measured at normal temperature with a spectroradiometer SR-UL1R (TOPCON TECHNOHOUSE). The external quantum efficiency was calculated from the measured luminance and emission spectrum, on the assumption that the light-emitting device had Lambertian light-distribution characteristics.

TABLE 10

| | | | | | | Current | | Power |
|---|---|---|---|---|---|---|---|---|
| | Voltage | Current | Current density | Chromaticity | Chromaticity | efficiency | BI | efficiency |
| | (V) | (mA) | (mA/cm²) | CIEx | CIEy | (cd/A) | (cd/A/CIEy) | (lm/W) |
| Light-emitting | 11.2 | 0.152 | 3.80 | 0.126 | 0.0885 | 26.6 | 30 | 7.47 |
| device 3 | | | | | | | | |
| Comparative | 12.4 | 0.141 | 3.53 | 0.124 | 0.0911 | 29.3 | 321 | 7.42 |
| light-emitting | | | | | | | | |
| device 3 | | | | | | | | |

As shown in FIG. 44, the light-emitting device 3 and the comparative light-emitting device 3 each had an extremely high external quantum efficiency around 40% even though 1,6mmtBuDPhAPrn, which is a fluorescent substance, emits light. Thus, when PtON-TBBI, which is a phosphorescent substance, serves as an energy donor in the light-emitting device 3 and the comparative light-emitting device 3, the fluorescent devices were able to exhibit extremely high efficiency.

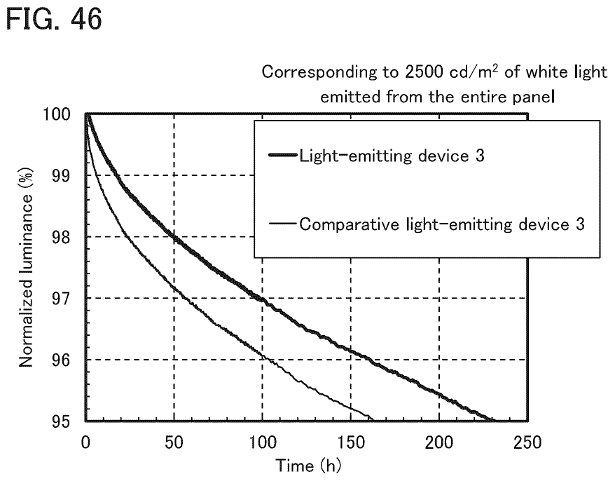

FIG. 46 shows the time dependence of normalized luminance of the light-emitting device 3 and the comparative light-emitting device 3 driven at 2 mA/cm². Note that the initial luminance is shown as 100% in the measurement of the time dependence of normalized luminance.

As shown in FIG. 46, the light-emitting device 3 of one embodiment of the present invention, which includes the second electron-transport layer with a high GSP_Slope and the light-emitting layer including both PtON-TBBI (phosphorescent substance) and 1,6mmtBuDPhAPrn (fluorescent substance), exhibited excellent LT95 that was approximately 1.5 times as long as that of the comparative light-emitting device 3.

FIG. 18 shows measurement results of the emission spectra (PL spectra) and the absorption spectra of PtON-TBBI, which is a substance capable of converting triplet excitation energy into light emission, and 1,6mmtBuDPhAPrn, which is a fluorescent substance, in the fabricated light-emitting device 3 and the fabricated comparative light-emitting device 3. Note that the emission spectrum and the absorption spectrum of PtON-TBBI in a dichloromethane solution of PtON-TBBI were measured, respectively, with a spectrofluorometer (FP-8600DS, manufactured by JASCO Corporation) and an ultraviolet-visible spectrofluorometer (V-770DS, manufactured by JASCO Corporation). In addition, the emission spectrum and the absorption spectrum of 1,6mmtBuDPhAPrn in a toluene solution of 1,6mmtBuDPhAPrn were measured, respectively, with a fluorescence spectrophotometer (FS920, manufactured by Hamamatsu Photonics K.K.) and an ultraviolet-visible spectrofluorometer (V550DS, manufactured by JASCO Corporation).

As shown in FIG. 18, the peak wavelength (456 nm) of the emission spectrum of PtON-TBBI is shorter than the peak wavelength (467 nm) of the emission spectrum of 1,6mmtBuDPhAPrn. The absorption edge on the long wavelength side (465 nm) of the absorption spectrum of 1,6mmtBuDPhAPrn is positioned at a longer wavelength than the emission edge on the short wavelength side (441 nm) of the emission spectrum of PtON-TBBI. The absorption edge on the long wavelength side (465 nm) of the absorption spectrum of 1,6mmtBuDPhAPrn is positioned at a longer wavelength than the absorption edge on the long wavelength side (457 nm) of the absorption spectrum of PtON-TBBI.

The light-emitting device 3 and the comparative light-emitting device 3 having such a structure can have high emission efficiency even though the fluorescent substance emits light because energy can be efficiently transferred from PtON-TBBI, which is the substance capable of converting triplet excitation energy into light emission, to 1,6mmtBuDPhAPrn, which is the fluorescent substance, in the light-emitting layer.

FIGS. 47A and 47B show the results of the low-temperature PL measurement of SiTrzCz2-d16 and PSiCzCz-d15, which are the host materials of the fabricated light-emitting devices. The measurement was performed by using a PL microscope, LabRAM HR-PL (HORIBA, Ltd.), a He—Cd laser (wavelength: 325 nm) as excitation light, and a CCD detector at a measurement temperature of 10 K. Note that the measurement sample was a thin film formed over a quartz substrate to a thickness of 50 nm, and the sample was subjected to measurement after another quartz substrate was attached to the quartz substrate from the deposited film's surface side in a nitrogen atmosphere.

As shown in FIG. 47A and FIG. 47B, since the wavelengths of the emission edges on the short wavelength side of the emission spectra of SiTrzCz2-d16 and PSiCzCz-d15 in the low-temperature PL measurement are 423 nm and 417 nm, respectively, the T₁ levels of SiTrzCz2-d16 and PSiCzCz-d15 are 2.93 eV and 2.97 eV, respectively. The energy difference is 0.05 eV. Note that when such materials are used as the host materials, since the energy difference between the T₁ levels of the host materials is lower than 0.20 eV, the light-emitting device fabricated in this example has a small deviation in triplet excitation energy between the host materials and thus has high reliability. In the light-emitting device of this example, the deuterated materials are used as the host materials. When the host materials are deuterated materials, the reliability of the light-emitting device is improved. The improvement in reliability in the case of using deuterated host materials relates to an extension of the lifetime of triplet excitons of the host materials. The extension of the lifetime of triplet excitons is caused by inhibited non-radiative deactivation of the triplet excitation energy, which is due to inhibited vibration owing to deuteration. In that case, the energy difference between the T₁ levels of SiTrzCz2-d16 and PSiCzCz-d15 is preferably small, in which case uneven distribution of excitation energy in the compounds is less likely to occur and significant deterioration of either one of the compounds can be prevented; accordingly, the reliability of the light-emitting device is increased.

According to FIG. 18, the wavelength of the emission edge on the short wavelength side of the emission spectrum of PtON-TBBI is 441 nm, and the T₁ level of PtON-TBBI is estimated to be 2.81 eV. Since the T₁ levels of SiTrzCz2-d16 and PSiCzCz-d15, which are host materials, are respectively 2.93 eV and 2.97 eV as described above, the T₁ level of PtON-TBBI is lower than the T₁ levels of SiTrzCz2-d16 and PSiCzCz-d15. The light-emitting device fabricated in this example having such a structure can have high emission efficiency and high reliability because energy can be efficiently transferred from the host materials to the substance capable of converting triplet excitation energy into light emission.

FIG. 48 shows emission spectra of a single film of SiTrzCz2-d16, a single film of PSiCzCz-d15, and a mixed film of SiTrzCz2-d16 and PSiCzCz-d15 at a weight ratio of 1:1. The measurement was performed with a spectrofluorometer (FP-8600DS, manufactured by JASCO Corporation). As shown in FIG. 48, the mixed film of SiTrzCz2-d16 and PSiCzCz-d15 exhibits an emission spectrum shifted toward the long wavelength side, which is different from each of the emission spectra of the single films. This indicates that SiTrzCz2-d16 and PSiCzCz-d15 form an exciplex in combination.

Table 11 shows the GSP_Slopes of vapor deposited films of an organic compound having a π-electron deficient heteroaromatic ring used in the first electron-transport layer, organic compounds having a π-electron deficient heteroaromatic ring used in the second electron-transport layer, and an organic compound having a π-electron rich heteroaromatic ring or an aromatic amine used in the hole-transport layer in the light-emitting device 3 and the comparative light-emitting device 3. The GSP_Slopes in Table 11 were measured by the method described in Embodiment 1.

TABLE 11

| Abbreviation of material | GSP_Slope |
|---|---|
| of vapor-deposited film | (mV/nm) |
| mSiTrz | 10.3 |
| mmtBuPh-mDMePyPTzn | 44.3 |
| mPPhen2P | 1.50 |
| PCBBiF | 17.3 |

As shown above, in the comparative light-emitting device 3, the GSP_Slope of the film of the organic compound having a π-electron deficient heteroaromatic ring included in the second electron-transport layer is smaller than the GSP_Slope of the film of the organic compound having a π-electron deficient heteroaromatic ring included in the first electron-transport layer. In this structure, electrons are favorably injected from the electrode or the electron-injection layer to the interface with the first electron-transport layer. Meanwhile, in the light-emitting device 3, the GSP_Slope of the film of the organic compound having a π-electron deficient heteroaromatic ring included in the second electron-transport layer is larger than the GSP_Slope of the film of the organic compound having a π-electron deficient heteroaromatic ring included in the first electron-transport layer. This inhibits injection of electrons from the electrode or the electron-injection layer into the second electron-transport layer in the light-emitting device 3.

In general, in a light-emitting layer containing a blue phosphorescent substance, the HOMO level and the LUMO level of the blue phosphorescent substance are respectively higher than the HOMO level and the LUMO level of a host material; thus, holes are trapped but electrons are not trapped and therefore the recombination region tends to be deviated toward the anode side in the light-emitting layer. When the recombination region is deviated toward the anode side, the density of excitons generated after the recombination also increases on the anode side in the light-emitting layer; thus, an interaction between excitons or an interaction between excitons and holes in the electron-blocking layer is likely to occur, so that excitons or holes with extremely high energy are likely to be generated. The high-energy excitons or holes promote deterioration of the light-emitting layer and the electron-blocking layer adjacent to the light-emitting layer.

In the light-emitting device of one embodiment of the present invention, electron injection is inhibited by the high GSP_Slope of the second electron-transport layer as described above; accordingly, the recombination region that tends to be deviated toward the anode side in the light-emitting layer can be extended toward the cathode side in the light-emitting layer, so that the deterioration of the hole-transport layer functioning as an electron-blocking layer can be inhibited. As a result, the light-emitting device 3 has higher reliability than the comparative light-emitting device 3.

Also in the light-emitting device fabricated in this example, the HOMO level and the LUMO level of PSiCzCz-d16 used as the host material in the light-emitting layer are respectively −5.7 eV and −2.05 eV, the HOMO level of SiTrzCz2-d16 used as the host material in the light-emitting layer is lower than that of PSiCzCz-d15 and the LUMO level of SiTrzCz2-d16 is −2.98 eV, and the HOMO level and the LUMO level of PtON-TBBI added in a slight amount (12 wt %) in the light-emitting layer as a blue phosphorescent substance are respectively −5.50 eV and −2.3 eV. This structure facilitates trap of holes. Note that the HOMO level of 1,6mmtBuDPhAPrn added in a slight amount (1.5 wt %) as a fluorescent substance in the light-emitting device 3 and the comparative light-emitting device 3 is −5.30 eV; thus, 1,6mmtBuDPhAPrn is also likely to trap holes like the phosphorescent substance. Note that since the HOMO level of the fluorescent substance is higher than that of the phosphorescent substance and the addition amount of the fluorescent substance is smaller than that of the phosphorescent substance, the fluorescent substance in the light-emitting layer further traps holes which have been trapped by the phosphorescent substance. Thus, the light-emitting layer has a structure in which holes are highly likely to be trapped and the hole-transport property is likely to be low.

The values of the HOMO levels and the LUMO levels were calculated by the method explained in Example 1.

The light-emitting device 3 and the comparative light-emitting device 3 each have a structure in which the fluorescent substance emits light. Since a fluorescent substance is more stable than a phosphorescent substance, a light-emitting device having a structure in which a fluorescent substance emits light has higher reliability than a light-emitting device having a structure in which a phosphorescent substance emits light. In the light-emitting device 3 and the comparative light-emitting device 3, energy transfer from the phosphorescent substance causes light emission of the fluorescent substance. In this case, since the fluorescent substance has a protecting group in the light-emitting device of this example, energy transfer by the Dexter mechanism is inhibited and energy transfer by the Forster mechanism is dominant, leading to higher emission efficiency. As a result, the light-emitting device has favorable characteristics with an external quantum efficiency exceeding 20% although the light-emitting device emits light from the fluorescent substance.

Thus, the light-emitting device of one embodiment of the present invention can have high reliability and favorable characteristics.

This application is based on Japanese Patent Application Serial No. 2024-207967 filed with Japan Patent Office on Nov. 29, 2024 and Japanese Patent Application Serial No. 2025-076887 filed with Japan Patent Office on May 2, 2025, the entire contents of which are hereby incorporated by reference.

What is claimed is:

1. A light-emitting device comprising:
a first electrode over an insulating surface;
a second electrode facing the first electrode; and
an EL layer between the first electrode and the second electrode,
wherein the EL layer includes a light-emitting layer, a hole-transport layer, a first electron-transport layer, and a second electron-transport layer,
wherein the first electron-transport layer is between the first electrode and the second electron-transport layer,
wherein the light-emitting layer is between the hole-transport layer and the first and the second electron-transport layers,
wherein the light-emitting layer includes a first light-emitting substance and a second light-emitting substance,
wherein the first light-emitting substance is a substance capable of converting triplet excitation energy into light emission,
wherein the second light-emitting substance is a fluorescent substance,
wherein a peak wavelength in an emission spectrum of the first light-emitting substance is shorter than a peak wavelength in an emission spectrum of the second light-emitting substance,
wherein a GSP_Slope (mV/nm) of the second electron-transport layer is larger than a GSP_Slope (mV/nm) of the first electron-transport layer, and
wherein the GSP_Slope (mV/nm) is represented by ΔV/Δd, where ΔV (mV) is an amount of change in surface potential and Δd (nm) is an amount of change in thickness.

2. A light-emitting device comprising:
a first electrode over an insulating surface;
a second electrode facing the first electrode; and
an EL layer between the first electrode and the second electrode,
wherein the EL layer includes a light-emitting layer, a hole-transport layer, a first electron-transport layer, and a second electron-transport layer,
wherein the first electron-transport layer is between the first electrode and the second electron-transport layer,
wherein the light-emitting layer is between the hole-transport layer and the first and the second electron-transport layers,
wherein the light-emitting layer includes a first light-emitting substance and a second light-emitting substance,
wherein the first light-emitting substance is a substance capable of converting triplet excitation energy into light emission,
wherein the second light-emitting substance is a fluorescent substance,
wherein a peak wavelength in an emission spectrum of the first light-emitting substance is shorter than a peak wavelength in an emission spectrum of the second light-emitting substance,
wherein the first electron-transport layer includes a first organic compound,
wherein the second electron-transport layer includes a second organic compound,
wherein each of the first organic compound and the second organic compound independently has a π-electron deficient heteroaromatic ring,
wherein a GSP_Slope (mV/nm) of a vapor deposited film of the second organic compound is larger than a GSP_Slope (mV/nm) of a vapor deposited film of the first organic compound, and
wherein the GSP_Slope (mV/nm) is represented by ΔV/Δd, where ΔV (mV) is an amount of change in surface potential and Δd (nm) is an amount of change in thickness.

3. A light-emitting device comprising:
a first electrode over an insulating surface;
a second electrode facing the first electrode; and
an EL layer between the first electrode and the second electrode,
wherein the EL layer includes a light-emitting layer, a hole-transport layer, a first electron-transport layer, and a second electron-transport layer,
wherein the first electron-transport layer is between the light-emitting layer and the second electron-transport layer,
wherein the second electron-transport layer is between the first electron-transport layer and the second electrode,
wherein the light-emitting layer is between the hole-transport layer and the first electron-transport layer,
wherein the light-emitting layer includes a first light-emitting substance and a second light-emitting substance,
wherein the first light-emitting substance is a substance capable of converting triplet excitation energy into light emission,
wherein the second light-emitting substance is a fluorescent substance,
wherein a peak wavelength in an emission spectrum of the first light-emitting substance is shorter than a peak wavelength in an emission spectrum of the second light-emitting substance,
wherein the first electron-transport layer includes a first organic compound,
wherein the second electron-transport layer includes a second organic compound and a first substance,
wherein each of the first organic compound and the second organic compound independently has a π-electron deficient heteroaromatic ring,
wherein a GSP_Slope (mV/nm) of a vapor deposited film of the second organic compound is larger than a GSP_Slope (mV/nm) of a vapor deposited film of the first organic compound, and
wherein the GSP_Slope (mV/nm) is represented by ΔV/Δd, where ΔV (mV) is an amount of change in surface potential and Δd (nm) is an amount of change in thickness.

4. The light-emitting device according to claim 3,
wherein in the case where a mixing ratio of the second organic compound to the first substance is x:y in the second electron-transport layer, the GSP_Slope (mV/nm) of the vapor deposited film of the second organic compound is larger than (x+y)/x times the GSP_Slope (mV/nm) of the vapor deposited film of the first organic compound.

5. The light-emitting device according to claim 4, wherein y is greater than or equal to x.

6. The light-emitting device according to claim 2,
wherein the second electron-transport layer is between the first electron-transport layer and the second electrode,
wherein the light-emitting layer includes a host material, and
wherein a GSP_Slope (mV/nm) of a vapor deposited film of the host material is larger than the GSP_Slope (mV/nm) of the vapor deposited film of the first organic compound.

7. The light-emitting device according to claim 6, wherein the GSP_Slope (mV/nm) of the vapor deposited film of the second organic compound is larger than the GSP_Slope (mV/nm) of the vapor deposited film of the host material.

8. The light-emitting device according to claim 6,
wherein the hole-transport layer includes a third organic compound, and
wherein a GSP_Slope (mV/nm) of the light-emitting layer is larger than or equal to a GSP_Slope (mV/nm) of a vapor deposited film of the third organic compound.

9. The light-emitting device according to claim 6,
wherein the hole-transport layer includes a third organic compound, and
wherein the GSP_Slope (mV/nm) of the vapor deposited film of the host material is larger than or equal to a GSP_Slope (mV/nm) of a vapor deposited film of the third organic compound.

10. The light-emitting device according to claim 6,
wherein the host material includes a first material and a second material, and
wherein the first material and the second material are organic compounds that form an exciplex in combination.

11. The light-emitting device according to claim 10,
wherein the first material is an organic compound including a π-electron deficient heteroaromatic ring, and
wherein the second material is an organic compound including a π-electron rich heteroaromatic ring or an aromatic amine.

12. The light-emitting device according to claim 10, wherein a HOMO level of the first material and a HOMO level of the second material are lower than a HOMO level of the first light-emitting substance.

13. The light-emitting device according to claim 12, wherein the HOMO level of the first material and the HOMO level of the second material are lower than a HOMO level of the second light-emitting substance.

14. The light-emitting device according to claim 3, wherein the first substance is a metal complex.

15. The light-emitting device according to claim 14, wherein the metal complex is an organic complex containing an alkali metal.

16. The light-emitting device according to claim 1, wherein the first light-emitting substance is a phosphorescent substance.

17. The light-emitting device according to claim 1, wherein the second light-emitting substance emits light by application of a voltage between the first electrode and the second electrode.

18. The light-emitting device according to claim 2, wherein the first light-emitting substance is a phosphorescent substance.

19. The light-emitting device according to claim 3, wherein the first light-emitting substance is a phosphorescent substance.
